(19) United States
(12) Patent Application Publication
(10) Pub. No.: US 2019/0196328 A1
(43) Pub. Date: Jun. 27, 2019

(54) PATTERN FORMING METHOD, METHOD FOR MANUFACTURING ELECTRONIC DEVICE, AND ACTINIC RAY-SENSITIVE OR RADIATION-SENSITIVE COMPOSITION

(71) Applicant: FUJIFILM Corporation, Tokyo (JP)

(72) Inventor: Fumihiro YOSHINO, Haibara-gun (JP)

(73) Assignee: FUJIFILM Corporation, Tokyo (JP)

(21) Appl. No.: 16/291,711

(22) Filed: Mar. 4, 2019

Related U.S. Application Data
(63) Continuation of application No. PCT/JP2017/029688, filed on Aug. 18, 2017.

(30) Foreign Application Priority Data
Sep. 30, 2016 (JP) 2016-194307

(51) Int. Cl. G03F 7/038; C08L 33/06; G03F 7/004; G03F 7/20

(52) U.S. Cl. CPC G03F 7/038; C08L 33/06; G03F 7/2065; G03F 7/2004; G03F 7/0045; G03F 7/0048

(57) ABSTRACT

A pattern forming method includes the following steps i), ii), and iii); i) a step of forming an actinic ray-sensitive or radiation-sensitive film having a film thickness of more than 9 μm and 20 μm or less, using an actinic ray-sensitive or radiation-sensitive composition including a solvent (S) satisfying specific conditions; ii) a step of irradiating the actinic ray-sensitive or radiation-sensitive film with actinic rays or radiation; and iii) a step of developing the actinic ray-sensitive or radiation-sensitive film irradiated with actinic rays or radiation, using a developer.

### CROSS-REFERENCE TO RELATED APPLICATIONS

This application is a Continuation of PCT International Application No. PCT/JP2017/029688, filed on Aug. 18, 2017, which claims priority under 35 U.S.C. § 119(a) to Japanese Patent Application No. 2016-194307, filed on Sep. 30, 2016. Each of the above application(s) is hereby expressly incorporated by reference, in its entirety, into the present application.

### BACKGROUND OF THE INVENTION

### 1. Field of the Invention

The present invention relates to a pattern forming method, a method for manufacturing an electronic device, and an actinic ray-sensitive or radiation-sensitive composition.

### 2. Description of the Related Art

A chemically amplified resist composition is a pattern forming material that generates an acid in an exposed area upon irradiation with active radiation such as far ultraviolet rays, and changes the solubility in a developer in an area irradiated with actinic radiation and an area not irradiated with actinic radiation by a reaction catalyzed by the acid, thereby forming a pattern on a substrate.

For example, a pattern forming method in which a resist film having a film thickness of 3 to 10 μm is formed using a resist composition containing a specific organic solvent, and the resist film is selectively exposed and then subjected to alkali development to form a resist pattern is known (see, for example, JP4954576B).

### SUMMARY OF THE INVENTION

On the other hand, various electronic devices have recently been required to have higher levels of functions, and as one aspect therefor, it has been investigated to increase the thickness of resist films. However, as a result of the studies conducted by the present inventors, it was found that in a case where the thickness of a resist film is increased to more than 9 μm in the pattern forming method described in JP4954576B, an unbalance in the film thickness of the resist film occurs and thus, the uniformity within the surface is not maintained.

The present invention has been made to solve the problem and has an object to provide a pattern forming method capable of forming a pattern having an excellent plane shape (uniformity of film thickness within the surface) in a case where an actinic ray-sensitive or radiation-sensitive film having a film thickness of more than 9 μm is formed; a method for manufacturing an electronic device; and an actinic ray-sensitive or radiation-sensitive composition.

That is, the present inventors have discovered that the problem can be solved by the following configurations.

<1>

A pattern forming method comprising the following steps i), ii), and iii):

i) forming an actinic ray-sensitive or radiation-sensitive film having a film thickness of more than 9 μm and 20 μm or less, using an actinic ray-sensitive or radiation-sensitive composition including a solvent (S) satisfying the following conditions (a) to (c):

(a) A>−0.026*B+5

(b) 0.9<A<2.5

(c) 120<B<160,

where A represents a viscosity (mPa·s) of the solvent (S) and B represents a boiling point (° C.) of the solvent (S),

in which in a case where the solvent (S) is formed of only one kind of solvent, A represents a viscosity (mPa·s) of the solvent (S), and B represents a boiling point (° C.) of the solvent (S),

in a case where the solvent (S) is a mixed solvent formed of two kinds of solvents, A is calculated by Formula (a1) and B is calculated by Formula (b1):

A=μ1̂X1*μ2̂X2 (a1)

B=T1*X1+T2*X2 (b1),

where μ1 represents a viscosity (mPa·s) of a first kind of the solvent, T1 represents a boiling point (° C.) of the first kind of the solvent, and X1 represents a mass proportion of the first kind of the solvent with respect to the total mass of the mixed solvent, and

μ2 represents a viscosity (mPa·s) of a second kind of the solvent, T2 represents a boiling point (° C.) of the second kind of the solvent, and X2 represents a mass proportion of the second kind of the solvent with respect to the total mass of the mixed solvent, and

in a case where the solvent (S) is a mixed solvent formed of n kinds of solvents, A is calculated by Formula (a2) and B is calculated by Formula (b2):

A=μ1̂X1*μ2̂X2* . . . μn̂Xn (a2)

B=T1*X1+T2*X2+ . . . Tn*Xn (b2),

where μ1 represents a viscosity (mPa·s) of a first kind of the solvent, T1 represents a boiling point (° C.) of the first kind of the solvent, and X1 represents a mass proportion of the first kind of the solvent with respect to the total mass of the mixed solvent,

μ2 represents a viscosity (mPa·s) of a second kind of the solvent, T2 represents a boiling point (° C.) of the second kind of the solvent, and X2 represents a mass proportion of the second kind of the solvent with respect to the total mass of the mixed solvent,

μn represents a viscosity (mPa·s) of an n^{th} kind of the solvent, Tn represents a boiling point (° C.) of the n^{th} kind of the solvent, and Xn represents a mass proportion of the n^{th} kind of the solvent with respect to the total mass of the mixed solvent, and

n represents an integer of 3 or more;

ii) irradiating the actinic ray-sensitive or radiation-sensitive film with actinic rays or radiation; and

iii) developing the actinic ray-sensitive or radiation-sensitive film irradiated with actinic rays or radiation, using a developer.

<2>

The pattern forming method as described in <1>,

in which B satisfies:

(c′) 136<B<160.

<3>

The pattern forming method as described in <1> or <2>,

in which in the step ii), the wavelength of the actinic rays or radiation to be irradiated is 248 nm.

<4>

The pattern forming method as described in any one of <1> to <3>, in which the solvent (S) includes at least one of an ether-based solvent, an ester-based solvent, or a ketone-based solvent.

<5>

The pattern forming method as described in any one of <1> to <4>, in which the solvent (S) includes at least one of propylene glycol monomethyl ether acetate, propylene glycol monomethyl ether, ethyl lactate, ethyl ethoxypropionate, cyclohexanone, or methyl methoxypropionate.

<6>

The pattern forming method as described in any one of <1> to <5>,

in which the actinic ray-sensitive or radiation-sensitive composition further includes a resin having a repeating unit represented by General Formula (AI).

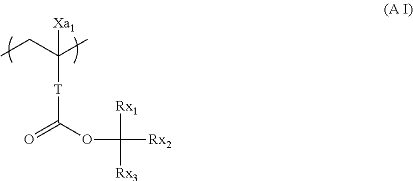

In the formula, Xa₁ represents a hydrogen atom or an alkyl group,

T represents a single bond or a divalent linking group,

Rx₁ to Rx₃ each independently represent an alkyl group or a cycloalkyl group, and two of Rx₁ to Rx₃ may be bonded to each other to form a cycloalkyl group.

<7> A method for manufacturing an electronic device, comprising the pattern forming method as described in any one of <1> to <6>.

<8>

An actinic ray-sensitive or radiation-sensitive composition for forming an actinic ray-sensitive or radiation-sensitive film having a film thickness of more than 9 μm and 20 or less, the actinic ray-sensitive or radiation-sensitive composition comprising a solvent (S) satisfying the following conditions (a) to (c):

(a) A>−0.026*B+5

(b) 0.9<A<2.5

(c) 120<B<160,

where A represents a viscosity (mPa·s) of the solvent (S) and B represents a boiling point (° C.) of the solvent (S),

in which in a case where the solvent (S) is formed of only one kind of solvent, A represents a viscosity (mPa·s) of the solvent (S), and B represents a boiling point (° C.) of the solvent (S),

in a case where the solvent (S) is a mixed solvent formed of two kinds of solvents, A is calculated by Formula (al) and B is calculated by Formula (b1):

A=μ1̂X1*μ2̂X2 (a1)

B=T1*X1+T2*X2 (b1),

where μ1 represents a viscosity (mPa·s) of a first kind of the solvent, T1 represents a boiling point (° C.) of the first kind of the solvent, and X1 represents a mass proportion of the first kind of the solvent with respect to the total mass of the mixed solvent, and

μ2 represents a viscosity (mPa·s) of a second kind of the solvent, T2 represents a boiling point (° C.) of the second kind of the solvent, and X2 represents a mass proportion of the second kind of the solvent with respect to the total mass of the mixed solvent, and

in a case where the solvent (S) is a mixed solvent formed of n kinds of solvents, A is calculated by Formula (a2) and B is calculated by Formula (b2):

A=μ1̂X1*μ2̂X2* . . . μn̂Xn (a2)

B=T1*X1+T2*X2+ . . . Tn*Xn (b2),

where μ1 represents a viscosity (mPa·s) of a first kind of the solvent, T1 represents a boiling point (° C.) of the first kind of the solvent, and X1 represents a mass proportion of the first kind of the solvent with respect to the total mass of the mixed solvent,

μ2 represents a viscosity (mPa·s) of a second kind of the solvent, T2 represents a boiling point (° C.) of the second kind of the solvent, and X2 represents a mass proportion of the second kind of the solvent with respect to the total mass of the mixed solvent,

μn represents a viscosity (mPa·s) of an n^{th} kind of the solvent, Tn represents a boiling point (° C.) of the n^{th} kind of the solvent, and Xn represents a mass proportion of the n^{th} kind of the solvent with respect to the total mass of the mixed solvent, and

n represents an integer of 3 or more.

According to the present invention, it is possible to provide a pattern forming method capable of forming a pattern having an excellent plane shape (uniformity in film thickness within the surface) in a case where an actinic ray-sensitive or radiation-sensitive film having a film thickness of more than 9 μm is formed; a method for manufacturing an electronic device; and an actinic ray-sensitive or radiation-sensitive composition.

### BRIEF DESCRIPTION OF THE DRAWINGS

FIG. 1 is a graph showing a viscosity A (mPa·s) and a boiling point B (° C.) of a solvent included in an actinic ray-sensitive or radiation-sensitive composition.

### DESCRIPTION OF THE PREFERRED EMBODIMENTS

Hereinafter, embodiments of the present invention will be described in detail.

In citations for a group (atomic group) in the present specification, in a case where the group (atomic group) is denoted without specifying whether it is substituted or unsubstituted, the group (atomic group) includes both a group (atomic group) not having a substituent and a group (atomic group) having a substituent. For example, an “alkyl group” which is not denoted about whether it is substituted or unsubstituted includes not only an alkyl group not having a substituent (unsubstituted alkyl group), but also an alkyl group having a substituent (substituted alkyl group).

“Actinic rays” or “radiation” in the present specification means, for example, a bright line spectrum of a mercury lamp, far ultraviolet rays typified by an excimer laser, extreme ultraviolet rays (EUV), X-rays, electron beams (EB), or the like. In addition, in the present invention, “light” means actinic rays or radiation.

In addition, “exposure” in the present specification includes, unless otherwise specified, not only exposure by a bright line spectrum of a mercury lamp, far ultraviolet rays typified by excimer laser, extreme ultraviolet rays, X-rays, or the like, but also writing by particle rays such as electron beams and ion beams.

Moreover, in the present specification, “(a value) to (a value)” means a range including the numerical values described before and after “to” as a lower limit value and an upper limit value, respectively.

In the present specification, (meth)acrylate represents acrylate and methacrylate, and (meth)acryl represents acryl and methacryl.

In the present specification, the weight-average molecular weight (Mw), the number-average molecular weight (Mn), and the dispersity (Mw/Mn) of a resin are defined as values in terms of polystyrene by means of gel permeation chromatography (GPC) measurement (solvent: tetrahydrofuran, flow amount (amount of a sample injected): 10 μL, columns: TSK gel Multipore HXL-M (×4) manufactured by Tosoh Corporation, column temperature: 40° C., flow rate: 1.0 mL/min, detector: differential refractive index (RI) detector) using a GPC apparatus (HLC-8120GPC manufactured by Tosoh Corporation).

[Actinic Ray-Sensitive or Radiation-Sensitive Composition]

The actinic ray-sensitive or radiation-sensitive composition of an embodiment of the present invention (hereinafter also referred to as “the composition of the embodiment of the present invention”) is an actinic ray-sensitive or radiation-sensitive composition for forming an actinic ray-sensitive or radiation-sensitive film having a film thickness of more than 9 μm and 20 μm or less, the actinic ray-sensitive or radiation-sensitive composition including a solvent (S) satisfying the following conditions (a) to (c).

(a) A>−0.026*B+5

(b) 0.9<A<2.5

(c) 120<B<160

A represents a viscosity (mPa·s) of the solvent (S) and B represents a boiling point (° C.) of the solvent (S).

In a case where the solvent (S) is formed of only one kind of solvent, A represents a viscosity (mPa·s) of the solvent (S), and B represents a boiling point (° C.) of the solvent (S).

In a case where the solvent (S) is a mixed solvent formed of two kinds of solvents, A is calculated by Formula (al) and B is calculated by Formula (b1).

A=μ1̂X1*μ2̂X2 (a1)

B=T1*X1+T2*X2 (b1),

μ1 represents a viscosity (mPa·s) of a first kind of the solvent, T1 represents a boiling point (° C.) of the first kind of the solvent, and X1 represents a mass proportion of the first kind of the solvent with respect to the total mass of the mixed solvent.

μ2 represents a viscosity (mPa·s) of a second kind of the solvent, T2 represents a boiling point (° C.) of the second kind of the solvent, and X2 represents a mass proportion of the second kind of the solvent with respect to the total mass of the mixed solvent.

In a case where the solvent (S) is a mixed solvent formed of n kinds of solvents, A is calculated by Formula (a2) and B is calculated by Formula (b2).

A=μ1̂X1*μ2̂X2* . . . μn̂Xn (a2)

B=T1*X1+T2*X2+ . . . Tn*Xn (b2),

μ1 represents a viscosity (mPa·s) of a first kind of the solvent, T1 represents a boiling point (° C.) of the first kind of the solvent, and X1 represents a mass proportion of the first kind of the solvent with respect to the total mass of the mixed solvent.

μ2 represents a viscosity (mPa·s) of a second kind of the solvent, T2 represents a boiling point (° C.) of the second kind of the solvent, and X2 represents a mass proportion of the second kind of the solvent with respect to the total mass of the mixed solvent.

μn represents a viscosity (mPa·s) of an n^{th} kind of the solvent, Tn represents a boiling point (° C.) of the n^{th} kind of the solvent, and Xn represents a mass proportion of the n^{th} kind of the solvent with respect to the total mass of the mixed solvent.

n represents an integer of 3 or more.

The viscosity A (mPa·s) is a value at a normal temperature and a normal pressure (25° C./1 atm). 1 atm is 1.013×10⁵ Pa.

In addition, the boiling point B (° C.) is a value at a normal pressure (1 atm), and in a case where, two or more kinds of the mixed solvents are used, and without consideration of the effect of variation in the boiling point by azeotropy, the boiling point only follows Formula (b 1) or (b2).

Further, in Formulae (a1) and (b1), X1+X2=1.

In Formulae (a2) and (b2), X1+X2+ . . . Xn=1.

The actinic ray-sensitive or radiation-sensitive composition of the embodiment of the present invention is preferably for use in exposure with light at a wavelength of 200 to 300 nm, and more preferably for exposure with KrF (wavelength of 248 nm).

The actinic ray-sensitive or radiation-sensitive composition of the embodiment of the present invention is preferably a resist composition. The resist composition may be a negative tone resist composition or a positive tone resist composition. Further, the composition of the embodiment of the present invention is typically a chemically amplified resist composition.

<Solvent (S)>

The present inventors have considered that it is preferable to select a solvent for use in an actinic ray-sensitive or radiation-sensitive composition so as to improve a plane shape (uniformity in film thickness within the surface) of a film formed in the formation of an actinic ray-sensitive or radiation-sensitive film having a high film thickness of more than 9 μm, and thus, have conducted studies in consideration of the viscosity and the boiling point of a solvent. As a result, have discovered that it is preferable to incorporate a solvent satisfying the conditions (a) to (c) (also referred to as a “solvent (S)”). Hereinafter, the solvent (S) used in the present invention will be specifically described.

The viscosity A (mPa·s) of the solvent (S) satisfies the following condition (b).

(b) 0.9<A<2.5

In a case where A is 0.9 or less, the viscosity of the actinic ray-sensitive or radiation-sensitive composition including the solvent is too low, and therefore, it is difficult to apply the actinic ray-sensitive or radiation-sensitive composition to a high thickness, which is thus not preferable in a case where an actinic ray-sensitive or radiation-sensitive film having a thickness of more than 9 μm is formed as in the present invention. On the other hand, in a case where A is 2.5 or more, the viscosity of the actinic ray-sensitive or radiation-sensitive composition including the solvent is increased, and therefore, the actinic ray-sensitive or radiation-sensitive composition cannot be sufficiently diffused on a substrate, deviation in a radiant shape occurs, and the plane shape of a film thus formed is deteriorated.

A preferably satisfies the following condition (b′), and more preferably satisfies the following condition (b″).

(b′) 1.0<A<2.0

(b″) 1.0<A<1.5

The boiling point B (° C.) of the solvent (S) satisfies the following condition (c).

(c) 120<B<160

In a case where B is 120 or less, the volatilization of the solvent proceeds during the application of the actinic ray-sensitive or radiation-sensitive composition, and thus, the applicability of the actinic ray-sensitive or radiation-sensitive composition is deteriorated. On the other hand, in a case where B is 160 or more, in a prebaking (PB) step or the like after applying the actinic ray-sensitive or radiation-sensitive composition, it becomes difficult to dry the actinic ray-sensitive or radiation-sensitive composition sufficiently.

B preferably satisfies the following condition (c′), and more preferably satisfies the following condition (c″).

(c′) 136<B<160

(c″) 140<B<150

The solvent (S) satisfies the following condition (a).

(a) A>−0.026*B+5

A relationship formula shown in the condition (a) is a relationship formula experimentally obtained as a result of further repetition of the studies conducted by the present inventors, based on a finding that a case where the solvent satisfies the conditions (b) and (c), but does not show a good plane shape is present, particularly in a region having a low viscosity as well as a low boiling point.

The solvent (S) is not particularly limited as long as it satisfies the conditions (a) to (c), and examples thereof include a lactone-based solvent, a ketone-based solvent, an ester-based solvent, an alcohol-based solvent, an ether-based solvent, and an aromatic organic solvent.

The solvent (S) may be only one kind of solvent or a mixed solvent of two or more kinds of solvents.

Examples of the lactone-based solvent include y-butyrolactone (GBL).

Examples of the ketone-based solvent include acetone, methyl ethyl ketone, cyclohexanone (CyHx), methyl-n-amyl ketone, methyl isoamyl ketone, and 2-heptanone (MAK).

Examples of the ester-based solvent include methyl lactate, ethyl lactate (EL), methyl acetate, ethyl acetate, butyl acetate (nBA), methyl pyruvate, ethyl pyruvate, methyl methoxypropionate (MMP), and ethyl ethoxypropionate (EEP). Other examples thereof include monomethyl ethers such as ethylene glycol monoacetate, diethylene glycol monoacetate, propylene glycol monoacetate, dipropylene glycol monoacetate, and 3-methoxybutyl acetate, monoalkyl ethers such as monoethyl ether, monopropyl ether, and monobutyl ether {for example, propylene glycol monomethyl ether acetate (PGMEA)}, and monophenyl ether.

Examples of the alcohol-based solvent include monovalent alcohols such as 4-methyl-2-pentanol (MIBC), benzyl alcohol, and 3-methoxybutanol, and polyhydric alcohols such as ethylene glycol, diethylene glycol, propylene glycol, and dipropylene glycol. Other examples thereof include monoalkyl ethers such as a monomethyl ether, a monoethyl ether, a monopropyl ether, and a monobutyl ether {for example, propylene glycol monomethyl ether (PGME)} and a monophenyl ether, of the polyhydric alcohol.

Examples of the ether-based solvent include cyclic ethers such as a dioxane, and solvents including an ether bond, among the solvents described for the ester-based solvent and the alcohol-based solvent.

Examples of the aromatic organic solvent include anisole, ethylbenzyl ether, cresylmethyl ether, diphenyl ether, dibenzyl ether, phenetole, butylphenyl ether, ethylbenzene, diethylbenzene, amylbenzene, isopropylbenzene, toluene, xylene, cymene, and mesitylene.

The solvent (S) preferably includes, among the solvents, at least one of an ether-based solvent, an ester-based solvent, or a ketone-based solvent, more preferably includes at least one of propylene glycol monomethyl ether acetate, propylene glycol monomethyl ether, ethyl lactate, ethyl ethoxypropionate, cyclohexanone, or methyl methoxypropionate, and still more preferably includes at least one of propylene glycol monomethyl ether acetate or propylene glycol monomethyl ether.

The mixing proportion of each of the solvents in a case of two or more kinds of solvents are used is preferably adjusted such that A calculated by Formulae (a1) and (a2) and B calculated by Formulae (b1) and (b2) each satisfy the conditions (a) to (c).

The content of the solvent (S) in the composition of the embodiment of the present invention is not particularly limited, and is preferably 40% to 80% by mass, more preferably 45% to 75% by mass, and still more preferably 50% to 70% by mass, with respect to the total mass of the composition.

<Resin (A)>

The composition of the embodiment of the present invention preferably contains a resin (A).

The resin (A) is typically a resin whose solubility in a developer changes through decomposition by the action of an acid, and preferably a resin whose solubility in an alkali developer increases by the action of an acid or whose solubility in a developer having an organic solvent as a main component decreases by the action of an acid. The resin (A) also preferably has a group (hereinafter also referred to as an “acid-decomposable group”) that decomposes by the action of an acid in the main chain or a side chain, or both the main chain and the side chain of the resin to generate a polar group.

The acid-decomposable group preferably has a structure in which a polar group is protected with a group capable of decomposing by the action of an acid to leave.

Examples of the polar group include an acidic group (a group that dissociates in a 2.38%-by-mass aqueous tetramethylammonium hydroxide solution which has been used as a developer in a resist in the related art) such as a phenolic hydroxyl group, a carboxyl group, a fluorinated alcohol group, a sulfonic acid group, a sulfonamido group, a sulfonylimido group, an (alkyl sulfonyl)(alkylcarbonyl)methylene group, an (alkyl sulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group, and an alcoholic hydroxyl group.

Preferred examples of the polar group include a carboxyl group, a fluorinated alcohol group (preferably a hexafluoroisopropanol group), and a sulfonic acid group.

A group which is preferable as the acid-decomposable group is a group in which a hydrogen atom of the polar group is substituted with a group that leaves by the action of an acid.

Examples of the group that leaves by the action of an acid include —C(R₃₆)(R₃₇)(R₃₈), —C(R₃₆)(R₃₇)(OR₃₉), —C(R₀₁)(R₀₂)(OR₃₉), —C(R₀₁)(R₀₂)—C(═O)—O—C(R₃₆)(R₃₇)(R₃₈), and —CH(R₃₆)(Ar).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

Ar represents an aryl group.

As the alkyl group as R₃₆ to R₃₉, R₀₁, or R₀₂, an alkyl group having 1 to 8 carbon atoms is preferable, and examples thereof include a methyl group, an ethyl group, a propyl group, an n-butyl group, a sec-butyl group, a hexyl group, and an octyl group.

A cycloalkyl group as R₃₆ to R₃₉, R₀₁, or R₀₂ may be a monocyclic cycloalkyl group or a polycyclic cycloalkyl group. As the monocyclic cycloalkyl group, a cycloalkyl group having 3 to 8 carbon atoms is preferable, and examples thereof include a cyclopropyl group, a cyclobutyl group, a cyclopentyl group, a cyclohexyl group, and a cyclooctyl group. As the polycyclic cycloalkyl group, a cycloalkyl group having 6 to 20 carbon atoms is preferable, and examples thereof include an adamantyl group, a norbornyl group, an isobornyl group, a camphonyl group, a dicyclopentyl group, an a-pinanyl group, a tricyclodecanyl group, a tetracyclododecyl group, and an androstanyl group. Further, some of the carbon atoms in the cycloalkyl group may be substituted with heteroatoms such as an oxygen atom.

An aryl group as R₃₆ to R₃₉, R₀₁, R₀₂, or Ar is preferably an aryl group having 6 to 10 carbon atoms, and examples thereof include a phenyl group, a naphthyl group, and an anthryl group.

An aralkyl group as R₃₆ to R₃₉, R₀₁, or R₀₂ is preferably an aralkyl group with 7 to 12 carbon atoms, and is preferably, for example, a benzyl group, a phenethyl group, and a naphthylmethyl group.

An alkenyl group as R₃₆ to R₃₉, R₀₁, or R₀₂ is preferably an alkenyl group with 2 to 8 carbon atoms, and examples thereof include a vinyl group, an allyl group, a butenyl group, and a cyclohexenyl group.

A ring which can be formed by mutual bonding of R₃₆ and R₃₇ may be monocyclic or polycyclic. The monocyclic ring is preferably a cycloalkyl structure having 3 to 8 carbon atoms, and examples thereof include a cyclopropane structure, a cyclobutane structure, a cyclopentane structure, a cyclohexane structure, a cycloheptane structure, and a cyclooctane structure. The polycyclic ring is preferably a cycloalkyl structure having 6 to 20 carbon atoms, and examples thereof include an adamantane structure, a norbornane structure, a dicyclopentane structure, a tricyclodecane structure, and a tetracyclododecane structure. Further, a part of carbon atoms in the ring structure may be substituted with the heteroatom such as an oxygen atom.

Each of the groups may have a substituent. Examples of the substituent include an alkyl group, a cycloalkyl group, an aryl group, an amino group, an amido group, an ureido group, a urethane group, a hydroxyl group, a carboxyl group, a halogen atom, an alkoxy group, a thioether group, an acyl group, an acyloxy group, an alkoxycarbonyl group, a cyano group, and a nitro group. Theses substituents preferably have 8 or less carbon atoms.

The acid-decomposable group is preferably a cumyl ester group, an enol ester group, an acetal group, an acetal ester group, a tertiary alkyl ester group, or the like, and more preferably a tertiary alkyl ester group.

As the repeating unit having an acid-decomposable group, which can be contained in the resin (A), a repeating unit represented by General Formula (AI) is preferable.

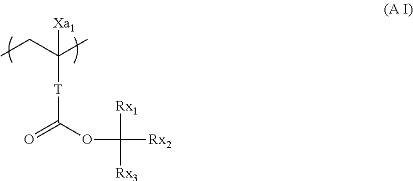

In General Formula (AI),

Xa₁ represents a hydrogen atom, or an alkyl group.

T represents a single bond or a divalent linking group.

Rx₁ to Rx₃ each independently represent an (linear or branched) alkyl group or a (monocyclic or polycyclic) cycloalkyl group.

Two of Rx₁ to Rx₃ may be bonded to each other to form a (monocyclic or polycyclic) cycloalkyl group.

The alkyl group represented by Xa₁ may or may not have a substituent, and examples thereof include a methyl group and a group represented by —CH₂—R₁₁. R₁₁ represents a halogen atom (a fluorine atom or the like), a hydroxyl group, or a monovalent organic group, and examples thereof include an alkyl group having 5 or less carbon atoms, and an acyl group having 5 or less carbon atoms. R₁₁ is preferably an alkyl group having 3 or less carbon atoms, and more preferably a methyl group. In one aspect, Xa₁ is preferably a hydrogen atom, a methyl group, a trifluoromethyl group, a hydroxymethyl group, or the like.

Examples of the divalent linking group of T include an alkylene group, a —COO—Rt- group, and an —O—Rt-group. In the formulae, Rt represents an alkylene group or a cycloalkylene group.

T is preferably a single bond or a —COO—Rt- group. Rt is preferably an alkylene group having 1 to 5 carbon atoms, and more preferably a —CH₂— group, a —(CH₂)₂— group, or a —(CH₂)₃— group.

As the alkyl group of Rx₁ to Rx₃, alkyl groups having 1 to 4 carbon atoms, such as a methyl group, an ethyl group, an n-propyl group, an isopropyl group, an n-butyl group, an isobutyl group, and a t-butyl group are preferable.

As the cycloalkyl group of Rx₁ to Rx₃, monocyclic cycloalkyl groups such as a cyclopentyl group and a cyclohexyl group, and polycyclic cycloalkyl groups such as a norbornyl group, a tetracyclodecanyl group, a tetracyclododecanyl group, and an adamantyl group are preferable.

As the cycloalkyl group formed by the bonding of two of Rx₁ to Rx₃, monocyclic cycloalkyl groups such as a cyclopentyl group and a cyclohexyl group, and polycyclic cycloalkyl groups such as a norbornyl group, a tetracyclodecanyl group, a tetracyclododecanyl group, and an adamantyl group are preferable, and monocyclic cycloalkyl groups having 5 or 6 carbon atoms are particularly preferable.

In the cycloalkyl group formed by the bonding of two of Rx₁ to Rx₃, for example, one of the methylene groups constituting the ring may be substituted with a heteroatom such as an oxygen atom or with a group having a heteroatom, such as a carbonyl group.

For the repeating unit represented by General Formula (AI), for example, an aspect in which Rx₁ is a methyl group or an ethyl group, and Rx₂ and Rx₃ are bonded to form the afore-mentioned cycloalkyl group, is preferable.

Each of the groups may have a sub stituent, and examples of the sub stituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), with the groups having 8 or less carbon atoms being preferable.

Specific preferred examples of the repeating unit having an acid-decomposable group are set forth below, but the present invention is not limited thereto.

In the specific examples, Rx and Xa₁ each represent a hydrogen atom, CH₃, CF₃, or CH₂OH. Rxa and Rxb each represent an alkyl group having 1 to 4 carbon atoms. Z represents a substituent containing a polar group, and in a case where Z's are present in plural numbers, they are each independent. p represents 0 or a positive integer. Examples of the substituent containing a polar group, represented by Z, include a linear or branched alkyl group, and a cycloalkyl group, each having a hydroxyl group, a cyano group, an amino group, an alkylamido group, or a sulfonamido group, and preferably an alkyl group having a hydroxyl group. As the branched alkyl group, an isopropyl group is particularly preferable.

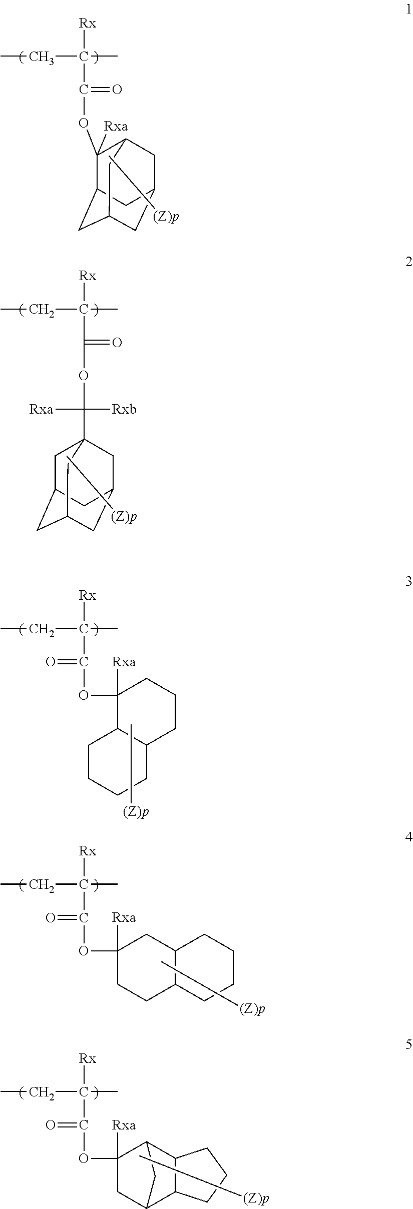

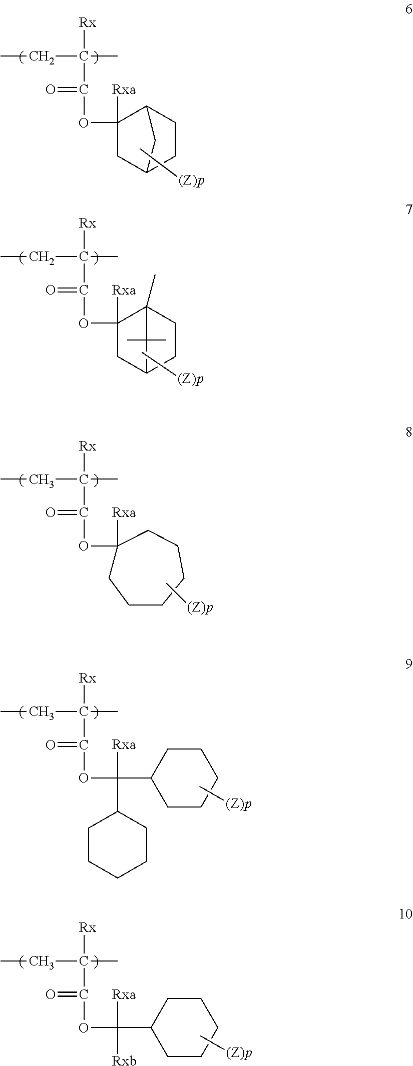

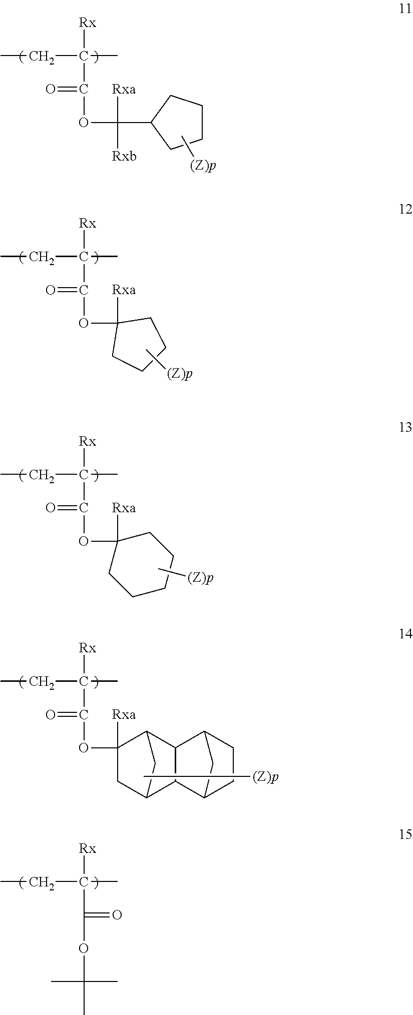

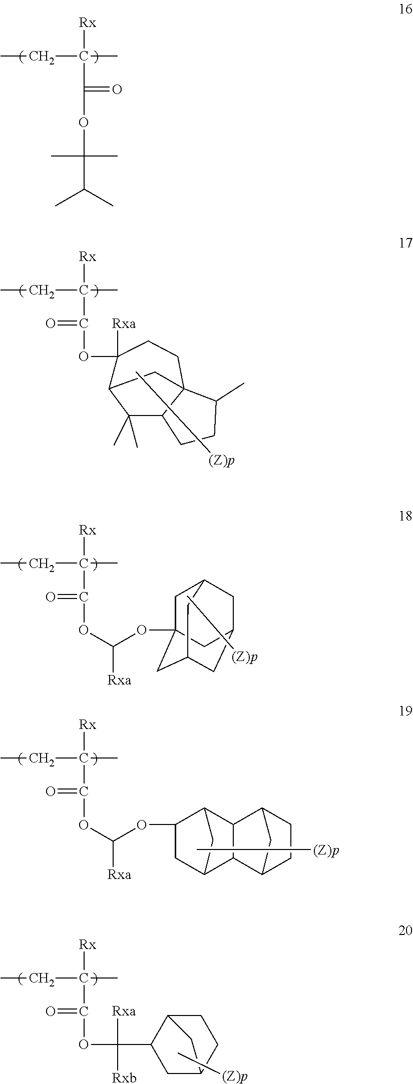

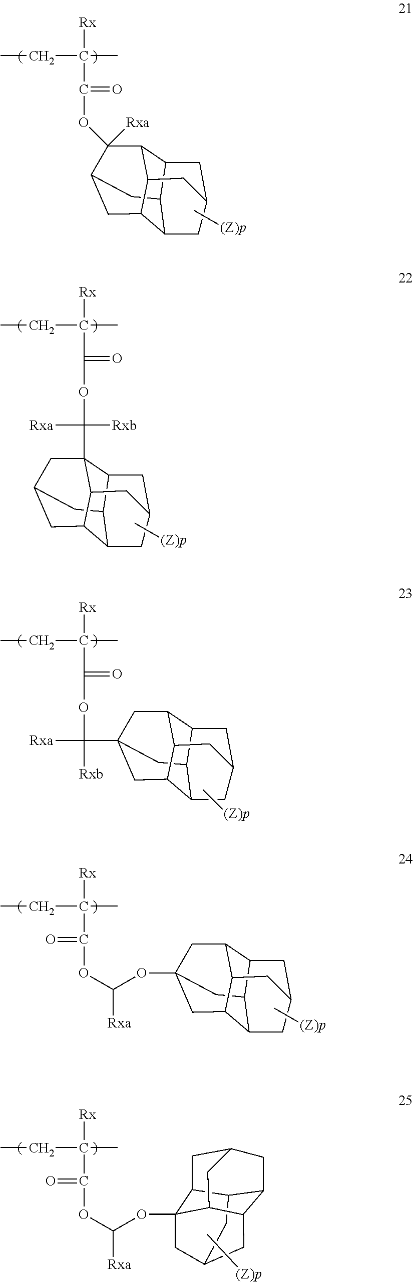

It is preferable that the resin (A) contains, for example, a repeating unit represented by General Formula (3) as the repeating unit represented by General Formula (AI).

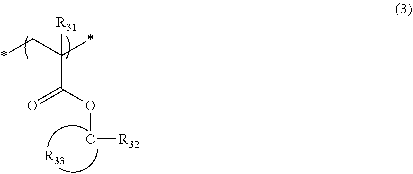

In General Formula (3),

R₃₁ represents a hydrogen atom or an alkyl group.

R₃₂ represents an alkyl group or a cycloalkyl group, and specific examples thereof include a methyl group, an ethyl group, an n-propyl group, an isopropyl group, an n-butyl group, an isobutyl group, a sec-butyl group, a tert-butyl group, and a cyclohexyl group.

R₃₃ represents an atomic group required for forming a monocyclic alicyclic hydrocarbon structure together with a carbon atom to which R₃₂ is bonded. In the alicyclic hydrocarbon structure, a part of the carbon atoms constituting the ring may be substituted with a heteroatom or a group having a heteroatom.

The alkyl group of R₃₁ may have a substituent, and examples of the substituent include a fluorine atom and a hydroxyl group. R₃₁ preferably represents a hydrogen atom, a methyl group, a trifluoromethyl group, or a hydroxymethyl group.

R₃₂ is preferably a methyl group, an ethyl group, an n-propyl group, an isopropyl group, a tert-butyl group, or a cyclohexyl group, and more preferably a methyl group, an ethyl group, an isopropyl group, or a tert-butyl group.

The monocyclic alicyclic hydrocarbon structure formed by R₃₃ together with a carbon atom is preferably a 3- to 8-membered ring, and more preferably a 5- or 6-membered ring.

In the monocyclic alicyclic hydrocarbon structure formed by R₃₃ together with a carbon atom, examples of the heteroatom which can constitute a ring include an oxygen atom and a sulfur atom, and examples of the group having a heteroatom include a carbonyl group. However, it is preferable that the group having a heteroatom is not an ester group (ester bond).

It is preferable that the monocyclic alicyclic hydrocarbon structure formed by R₃₃ together with a carbon atom is formed of only carbon atoms and hydrogen atoms.

The repeating unit represented by General Formula (3) is preferably a repeating unit represented by General Formula (3′).

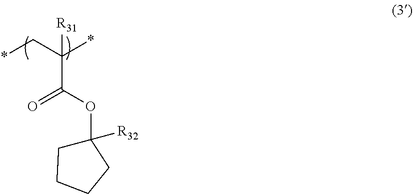

In General Formula (3′), R₃₁ and R₃₂ have the same definitions, respectively, as in General Formula (3).

Specific examples of the repeating unit having the structure represented by General Formula (3) include, not limited to, the following repeating units.

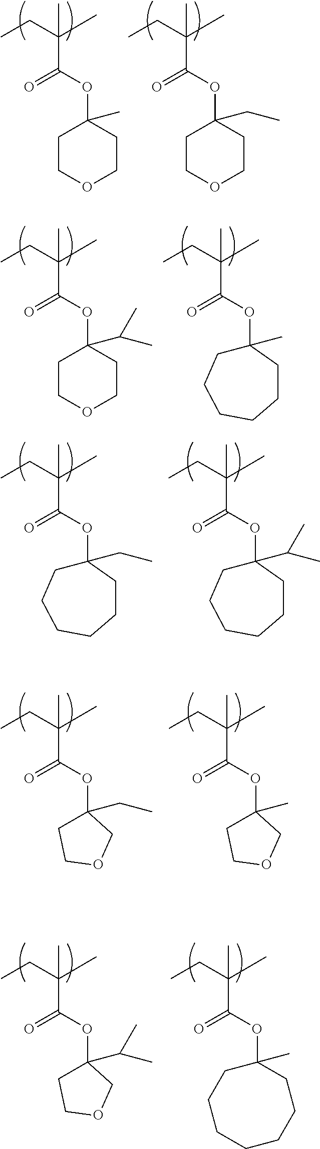

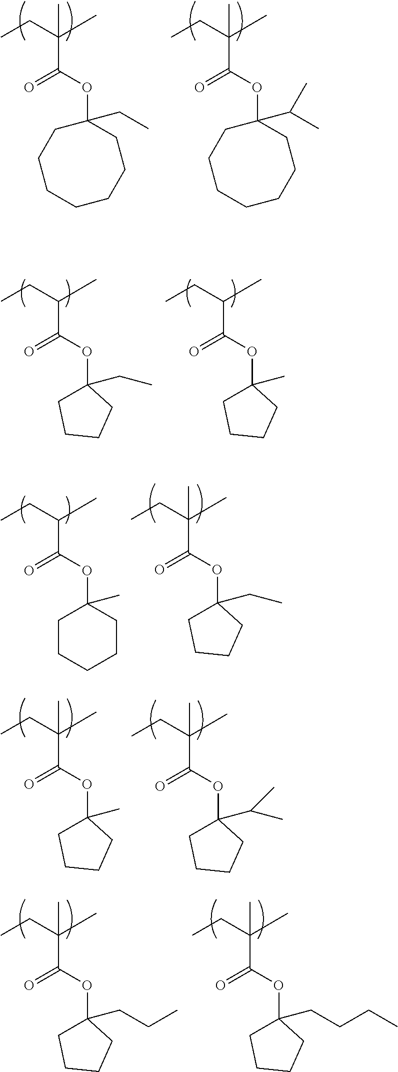

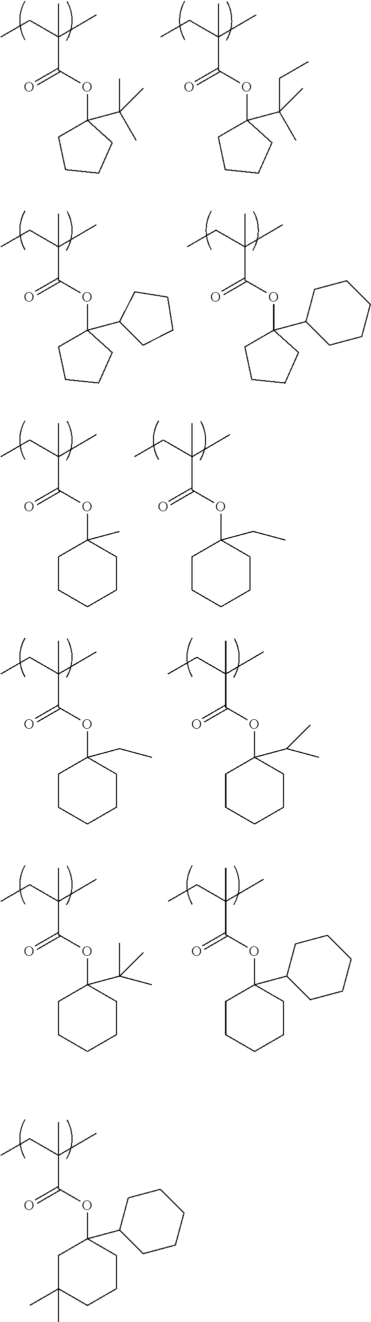

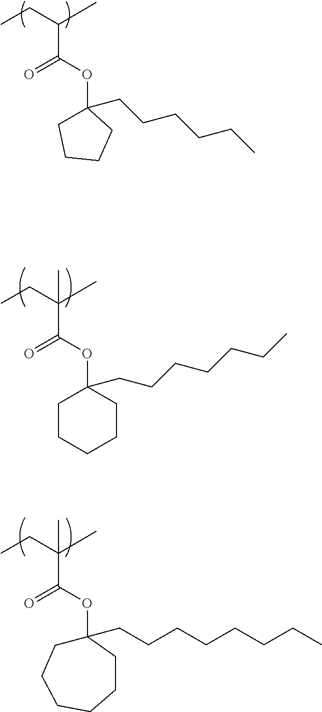

The content of the repeating unit having the structure represented by General Formula (3) is preferably 20% to 80% by mole, more preferably 25% to 75% by mole, and still more preferably 30% to 70% by mole, with respect to all the repeating units in the resin (A).

Furthermore, the repeating unit having an acid-decomposable group is also preferably a repeating unit represented by General Formula (A).

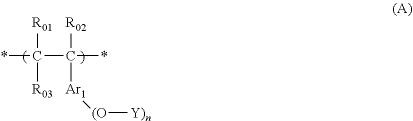

In the formula, R₀₁, R₀₂, and R₀₃ each independently represent, for example, a hydrogen atom, an alkyl group, a cycloalkyl group, a halogen atom, a cyano group, or an alkoxycarbonyl group. Ar₁ represents an aromatic ring group. R₀₃ represents an alkylene group or may be bonded to Ar₁, together with a —C—C— chain, to form a 5- or 6-membered ring.

n Y's each independently represent a hydrogen atom or a group that leaves by the action of an acid, provided that at least one of Y's represents a group that leaves by the action of an acid.

n represents an integer of 1 to 4, and is preferably 1 or 2, and more preferably 1.

The alkyl group as each of R₀₁ to R₀₃ is, for example, an alkyl group having 20 or less carbon atoms, preferably a methyl group, an ethyl group, a propyl group, an isopropyl group, an n-butyl group, a sec-butyl group, a hexyl group, a 2-ethylhexyl group, an octyl group, or a dodecyl group. More preferably, these alkyl groups are alkyl groups having 8 or less carbon atoms. Further, these alkyl groups may have a substituent.

The alkyl group included in the alkoxycarbonyl group is preferably the same as the alkyl group in each of R₀₁ to R₀₃.

The cycloalkyl group may be a monocyclic cycloalkyl group or a polycyclic cycloalkyl group. Preferred examples thereof include a monocyclic cycloalkyl group having 3 to 8 carbon atoms, such as a cyclopropyl group, a cyclopentyl group, and a cyclohexyl group. Further, these cycloalkyl groups may have a substituent.

Examples of the halogen atom include a fluorine atom, a chlorine atom, a bromine atom, and an iodine atom, with the fluorine atom being more preferable.

In a case where R₀₃ represents an alkylene group, preferred examples of the alkylene group include ones having 1 to 8 carbon atoms, such as a methylene group, an ethylene group, a propylene group, a butylene group, a hexylene group, and an octylene group.

The aromatic ring group as Ar₁ is preferably one having 6 to 14 carbon atoms, and examples thereof include a benzene ring, a toluene ring, and a naphthalene ring. Further, these aromatic ring groups may have a substituent.

Suitable examples of the group that leaves by the action of an acid as at least one of

Y's include those described above.

The group that leaves by the action of an acid as at least one of Y's is preferably a structure represented by General Formula (B).

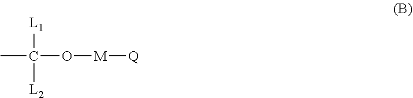

In the formula, L₁ and L₂ each independently represent a hydrogen atom, an alkyl group, a cycloalkyl group, an aryl group, or an aralkyl group.

M represents a single bond or a divalent linking group.

Q represents an alkyl group, a cycloalkyl group, a cyclic aliphatic group, an aromatic ring group, an amino group, an ammonium group, a mercapto group, a cyano group, or an aldehyde group. The cyclic aliphatic group and the aromatic ring group may include a heteroatom.

At least two of Q, M, and L₁ may be bonded to each other to form a 5- or 6-membered ring.

The alkyl group as each of L₁ and L₂ is, for example, an alkyl group having 1 to 8 carbon atoms, and specific examples thereof include a methyl group, an ethyl group, a propyl group, an n-butyl group, a sec-butyl group, a hexyl group, and an octyl group.

The cycloalkyl group as each of L₁ and L₂ is, for example, a cycloalkyl group having 3 to 15 carbon atoms, and specific examples thereof include a cyclopentyl group, a cyclohexyl group, a norbornyl group, and an adamantyl group.

The aryl group as each of L₁ and L₂ is, for example, an aryl group having 6 to 15 carbon atoms, and specific examples thereof include a phenyl group, a tolyl group, a naphthyl group, and an anthryl group.

The aralkyl group as each of L₁ and L₂ is, for example, an aralkyl group having 6 to 20 carbon atoms, and specific examples thereof include a benzyl group and a phenethyl group.

Examples of the divalent linking group as M include an alkylene group (for example, a methylene group, an ethylene group, a propylene group, a butylene group, a hexylene group, and an octylene group), a cycloalkylene group (for example, a cyclopentylene group and a cyclohexylene group), an alkenylene group (for example, an ethylene group, a propenylene group, and a butenylene group), an arylene group (for example, a phenylene group, a tolylene group, and a naphthylene group), —S—, —O—, —CO—, —SO₂—, —N(R₀)—, and a combination of two orore thereof. Here, Rₒ is a hydrogen atom or an alkyl group. The alkyl group as R₀ is, for example, an alkyl group having 1 to 8 carbon atoms, and specific examples thereof include a methyl group, an ethyl group, a propyl group, an n-butyl group, a sec-butyl group, a hexyl group, and an octyl group.

Examples of the alkyl group and the cycloalkyl group as Q are the same as those described above for the alkyl group and the cycloalkyl group of each of L₁ and L₂, respectively.

Examples of the cyclic aliphatic group or the aromatic ring group as Q include the above-described cycloalkyl group and aryl group as each of L₁ and L₂. The cycloalkyl group and the aryl group are each preferably a group having 3 to 15 carbon atoms.

Examples of the heteroatom-containing cyclic aliphatic or aromatic ring group as Q include a group having a heterocyclic structure such as thiirane, cyclothiolane, thiophene, furan, pyrrole, benzothiophene, benzofuran, benzopyrrole, triazine, imidazole, benzimidazole, triazole, thiadiazole, thiazole, and pyrrolidone, but the ring is not limited thereto as long as it is a ring formed of carbon and a heteroatom or a ring formed of only a heteroatom.

Examples of the ring structure which may be formed by mutual bonding of at least two of Q, M, or L₁ include a 5- or 6-membered ring structure obtained by forming a propylene group or a butylene group by these members. In addition, this 5- or 6-membered ring structure contains an oxygen atom.

Each of the groups represented by L₁, L₂, M, and Q in General Formula (B) may have a sub stituent, and examples of the sub stituent include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The substituent preferably has 8 or less carbon atoms.

The group represented by -(M-Q) is preferably a group having 1 to 20 carbon atoms, more preferably a group having 1 to 10 carbon atoms, and still more preferably a group having 1 to 8 carbon atoms.

The total content of the repeating units having an acid-decomposable group is preferably 20% to 90% by mole, more preferably 25% to 85% by mole, and still more preferably 30% to 80% by mole, with respect to all the repeating units in the resin (A).

In one aspect, the resin (A) preferably has a repeating unit having a cyclic carbonic acid ester structure. This cyclic carbonic acid ester structure is a structure having a ring including a bond represented by —O—C(═O)—O— as an atomic group constituting the ring. The ring including a bond represented by —O—C(═O)—O— as an atomic group constituting the ring is preferably a 5- to 7-membered ring, and most preferably a 5-membered ring. Such a ring may be fused with another ring to form a fused ring.

Moreover, the resin (A) may contain a repeating unit having a lactone structure or sultone (cyclic sulfonic acid ester) structure.

As the lactone group or the sultone group, any group having a lactone structure or sultone structure can be used, and is preferably a 5- to 7-membered ring lactone structure or sultone structure, with a 5- to 7-membered ring lactone structure or sultone structure to which another ring structure is fused so as to form a bicyclo structure or spiro structure being preferable. The resin (A) more preferably has a repeating unit having a lactone structure or sultone structure represented by any one of General Formulae (LC1-1) to (LC1-17), (SL1-1), and (SL1-2). Further, the lactone structure or the sultone structure may be directly bonded to a main chain. A preferred lactone structure or sultone structure is General Formula (LC1-1), (LC1-4), (LC1-5), or (LC1-8), with General Formula (LC1-4) being more preferable. By using a specific lactone structure or sultone structure, line width roughness (LWR) and development defects are improved.

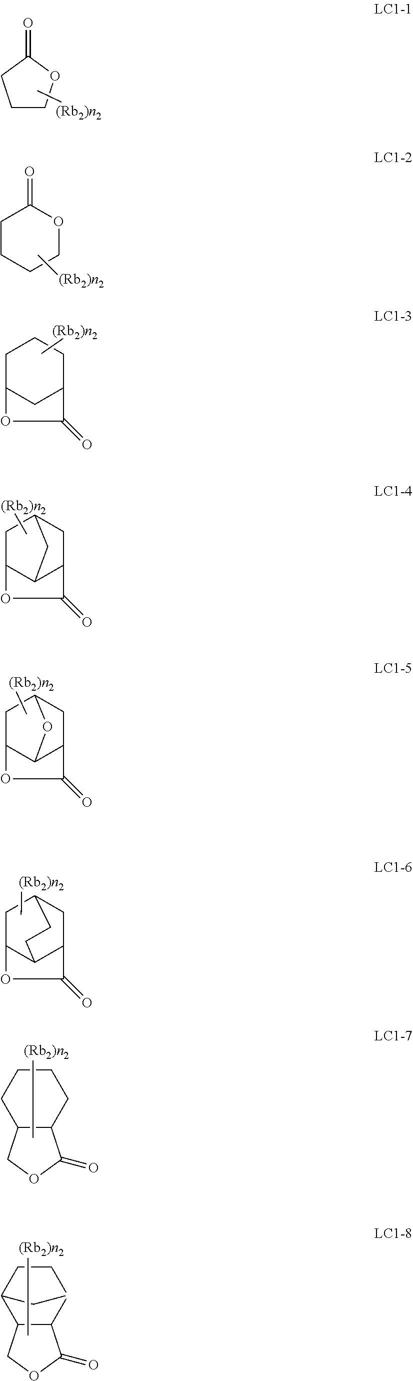

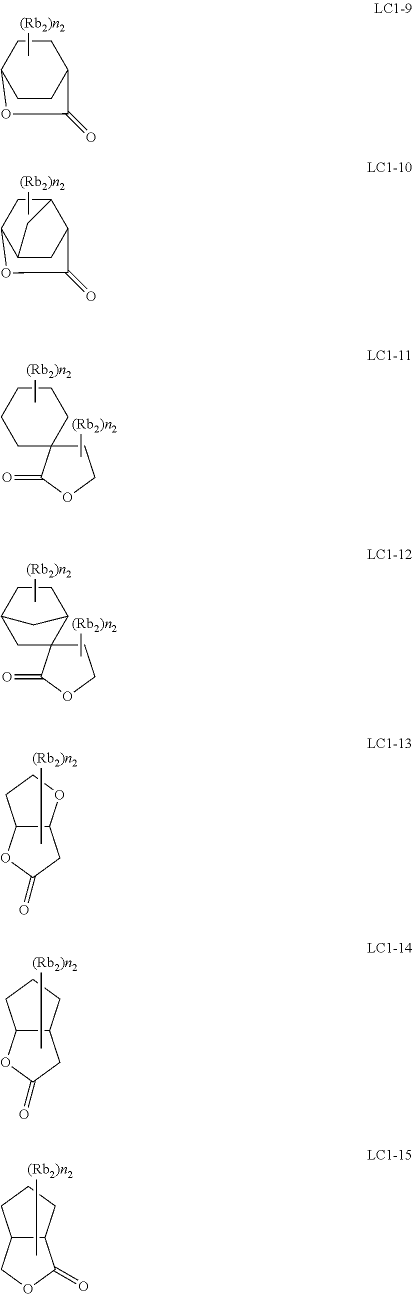

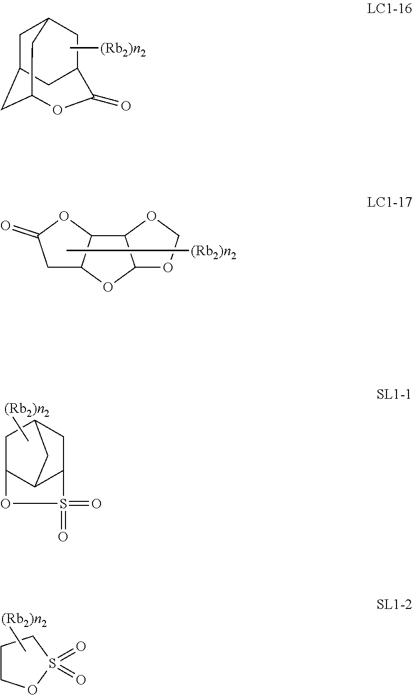

The lactone structure moiety or the sultone structure moiety may or may not have a sub stituent (Rb₂). Preferred examples of the sub stituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. Among these, an alkyl group having 1 to 4 carbon atoms, a cyano group, and an acid-decomposable group are more preferable. n₂ represents an integer of 0 to 4. In a case where n₂ is 2 or more, the substituents (Rb₂) which are present in plural numbers may be the same as or different from each other, and further, the substituents (Rb₂) which are present in plural numbers may be bonded to each other to form a ring.

The repeating unit having a lactone group or a sultone group usually has an optical isomer, and any optical isomer may be used. Further, one kind of optical isomer may be used singly or a plurality of optical isomers may be mixed and used. In a case of mainly using one kind of optical isomer, the optical purity (ee) thereof is preferably 90% or more, and more preferably 95% or more.

The resin (A) may have a repeating unit having a hydroxyl group or a cyano group other than General Formulae (AI) and (III). Thus, adhesiveness to a substrate and affinity for a developer are improved. The repeating unit having a hydroxyl group or a cyano group is preferably a repeating unit having an alicyclic hydrocarbon structure substituted with a hydroxyl group or a cyano group, and preferably has no acid-decomposable group. In the alicyclic hydrocarbon structure substituted with a hydroxyl group or a cyano group, as the alicyclic hydrocarbon structure, an adamantyl group, a diadamantyl group, and a norbornane group are preferable. As the alicyclic hydrocarbon structure substituted with a hydroxyl group or a cyano group, partial structures represented by General Formulae (VIIa) to (VIId) are preferable.

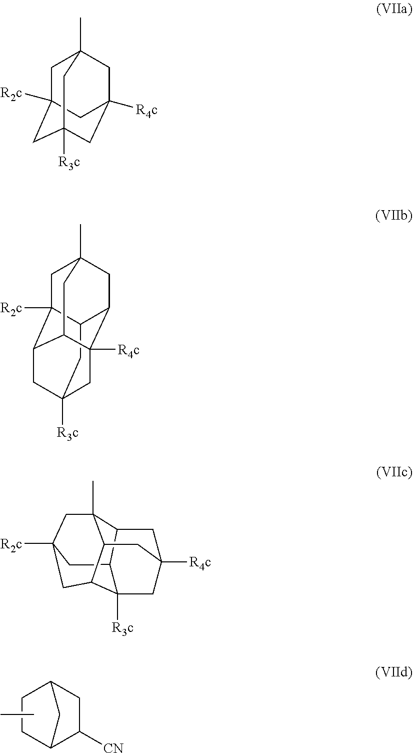

In General Formulae (VIIa) to (VIIc),

R₂c to R₄c each independently represent a hydrogen atom, a hydroxyl group, or a cyano group, provided that at least one of R₂c, R₃c, or R₄c represents a hydroxyl group or a cyano group. Preferably one or two of R₂c to R₄c are a hydroxyl group while the remainder is a hydrogen atom. In General Formula (VIIa), it is more preferable that two of R₂c to R₄c are a hydroxyl group and the remainder is a hydrogen atom.

Examples of the repeating unit having a partial structure represented by each of General Formulae (VIIa) to (VIId) include repeating units represented by General Formulae (AIIa) to (AIId).

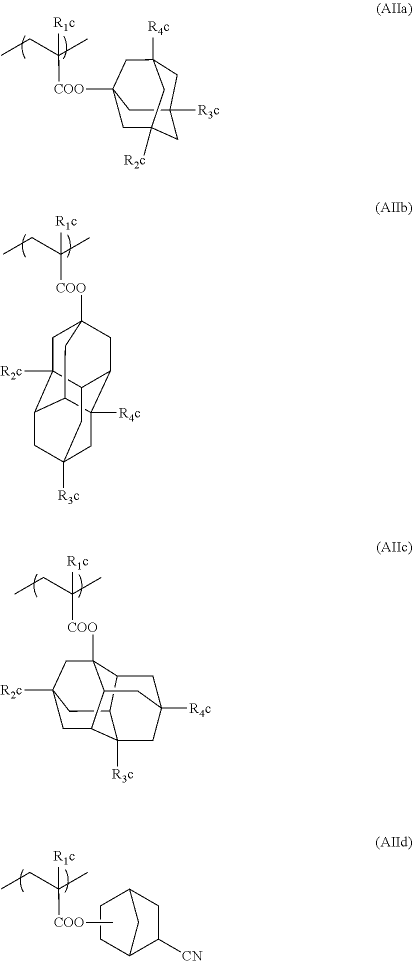

In General Formulae (AIIa) to (AIId),

R₁c represents a hydrogen atom, a methyl group, a trifluoromethyl group, or a hydroxymethyl group.

R₂c to R₄c have the same definitions as R₂c to R₄c, respectively, in General Formulae (VIIa) to (VIIc).

The content of the repeating unit having a hydroxyl group or a cyano group is preferably 5% to 40% by mole, more preferably 5% to 30% by mole, and still more preferably 10% to 25% by mole, with respect to all the repeating units of the resin (A).

Specific examples of the repeating unit having a hydroxyl group or a cyano group include the following repeating units, but the present invention is not limited thereto.

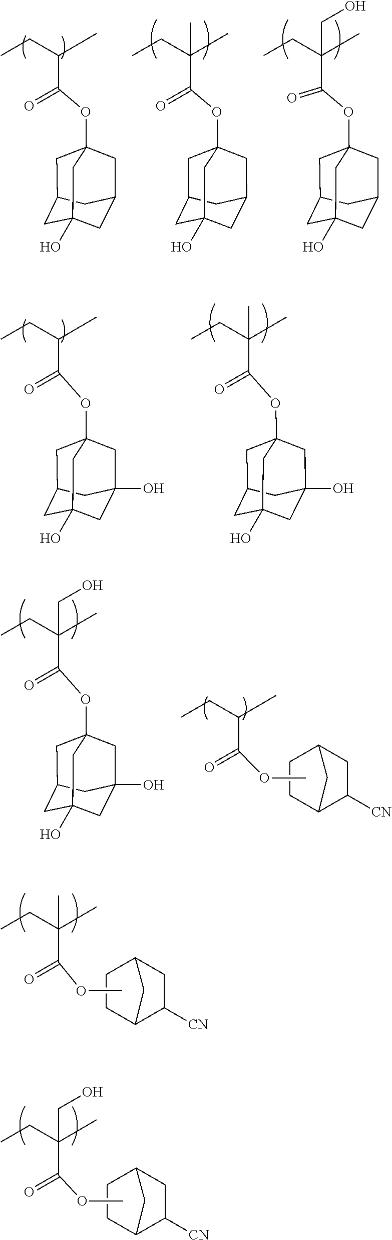

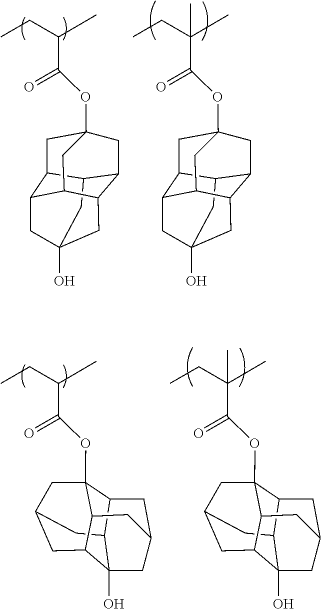

The resin (A) may have a repeating unit having an acid group. Examples of the acid group include a carboxyl group, a sulfonamido group, a sulfonylimido group, a bissulfonylimido group, and an aliphatic alcohol which is substituted by an electron withdrawing group (for example, a hexafluoroisopropanol group), at an a-position and more preferably having a repeating unit with a carboxyl group. By incorporation of a repeating unit having an acid group, resolution during formation of contact holes is enhanced. As the repeating unit having an acid group, any of a repeating unit where an acid group is bonded directly to the main chain of the resin such as repeating units derived from acrylic acid or methacrylic acid, a repeating unit where an acid group is bonded to the main chain of the resin via a linking group, or further, introduction of a polymerization initiator or a chain transfer agent which has an acid group to a terminal of a polymer chain used during polymerization is preferable, and the linking group may have a monocyclic or polycyclic hydrocarbon structure. The repeating unit derived from acrylic acid or methacrylic acid is particularly preferable.

Furthermore, the resin (A) preferably has a repeating unit having a phenolic hydroxyl group as the repeating unit having an acid group.

The phenolic hydroxyl group is a group formed by substituting a hydrogen atom of an aromatic ring group with a hydroxyl group. The aromatic ring is a monocyclic or polycyclic aromatic ring, and examples thereof include aromatic hydrocarbon rings having 6 to 18 carbon atoms, which may have a substituent, such as a benzene ring, a naphthalene ring, an anthracene ring, a fluorene ring, and a phenanthrene ring, or aromatic hetero rings including a hetero ring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, from the viewpoint of resolution, the benzene ring or the naphthalene ring is preferable, and the benzene ring is the most preferable.

As the repeating unit having a phenolic hydroxyl group, a repeating unit represented by General Formula (30) is also preferable.

General Formula (30)

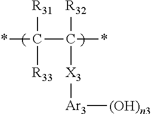

In General Formula (30),

R₃₁, R₃₂, and R₃₃ each independently represent a hydrogen atom, an alkyl group, a cycloalkyl group, a halogen atom, a cyano group, or an alkoxycarbonyl group, provided that R₃₃ may be bonded to Ar₃ to form a ring, and in this case, R₃₃ represents an alkylene group.

X₃ represents a single bond or a divalent linking group.

Ar₃ represents an (n3+1)-valent aromatic ring group, and in a case where Ar₃ is bonded to R₃₃ to form a ring, it represents an (n3+2)-valent aromatic ring group.

n₃ represents an integer of 1 to 4.

Ar₃ represents an (n3+1)-valent aromatic ring group. A divalent aromatic ring group in a case where n3 is 1 may have a substituent, and preferred examples thereof include an arylene group having 6 to 18 carbon atoms, such as a phenylene group, a tolylene group, a naphthylene group, and an anthracenylene group, or an aromatic ring group including a heterocycle such as thiophene, furan, pyrrole, benzothiophene, benzofuran, benzopyrrole, triazine, imidazole, benzimidazole, triazole, thiadiazole, and thiazole.

Specific suitable examples of the (n3+1)-valent aromatic ring group in a case where n3 is an integer of 2 or more include groups formed by obtaining removing arbitrary (n3−1) hydrogen atoms from the specific examples of the divalent aromatic ring groups.

The (n3+1)-valent aromatic ring group may further have a substituent.

Examples of the sub stituent which can be contained in the above-mentioned alkylene group and (n3+1)-valent aromatic ring group include an alkyl group, an alkoxy group such as a methoxy group, an ethoxy group, a hydroxyethoxy group, a propoxy group, a hydroxypropoxy group, and a butoxy group, and an aryl group such as a phenyl group.

Examples of the divalent linking group of X₃ include —COO— and —CONR₆₄—.

Preferred examples of the alkyl group of R₆₄ in —CONR₆₄— represented by X₃ (R₆₄ represents a hydrogen atom or an alkyl group) include an alkyl group having 1 to 8 carbon atoms, such as a methyl group, an ethyl group, a propyl group, an n-butyl group, a sec-butyl group, a hexyl group, and an octyl group.

As X₃, a single bond, —COO—, or —CONH— is preferable, and the single bond or —COO— is more preferable.

As Ar₃, an aromatic ring group having 6 to 18 carbon atoms, which may have a substituent, is more preferable, and a benzene ring group, a naphthalene ring group, or a biphenylene ring group is particularly preferable.

The repeating unit represented by General Formula (30) preferably comprises a hydroxystyrene structure. That is, Ar₃ is preferably a benzene ring group.

n₃ represents an integer of 1 to 4, preferably represents 1 or 2, and more preferably represents 1.

The content of the repeating unit having an acid group is preferably 30% to 90% by mole, more preferably 35% to 85% by mole, and still more preferably 40% to 80% by mole, with respect to all the repeating units in the resin (A).

Specific examples of the repeating unit having an acid group are set forth below, but the present invention is not limited thereto.

In the specific examples, Rx represents H, CH₃, CH₂OH, or CF₃.

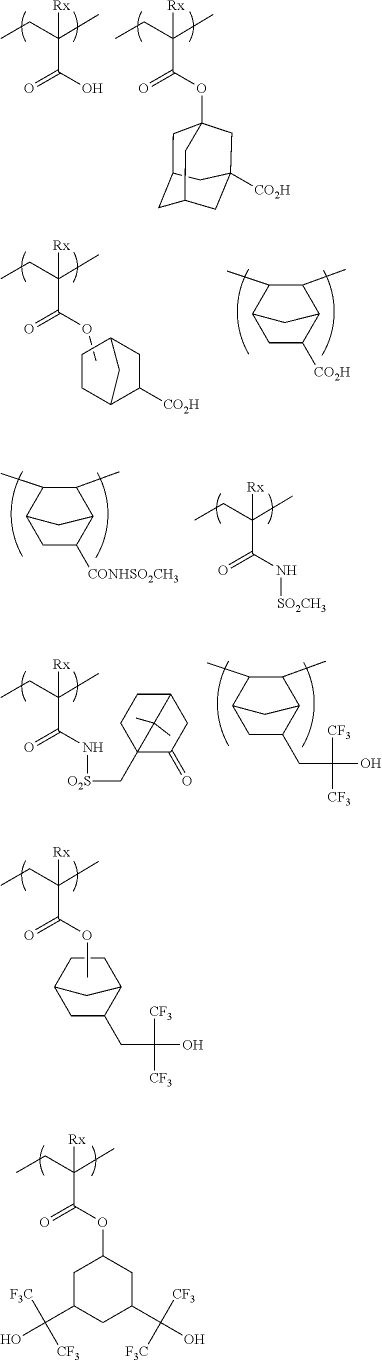

Moreover, specific examples of the repeating unit having a phenolic hydroxyl group among the repeating units having an acid group are set forth below, but are not limited thereto.

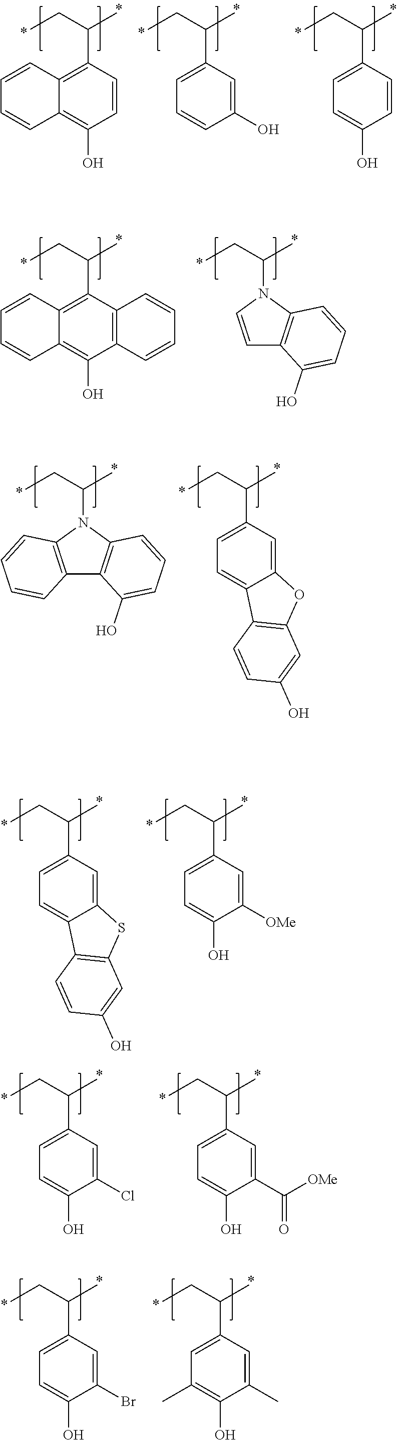

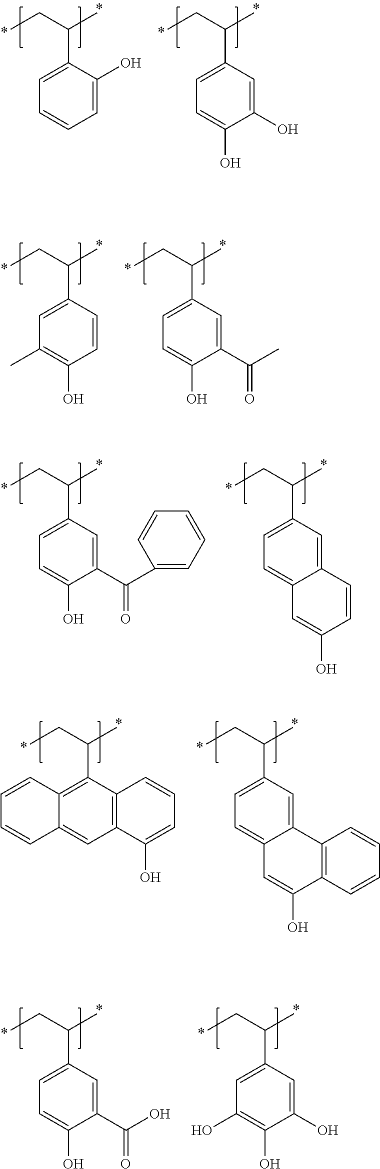

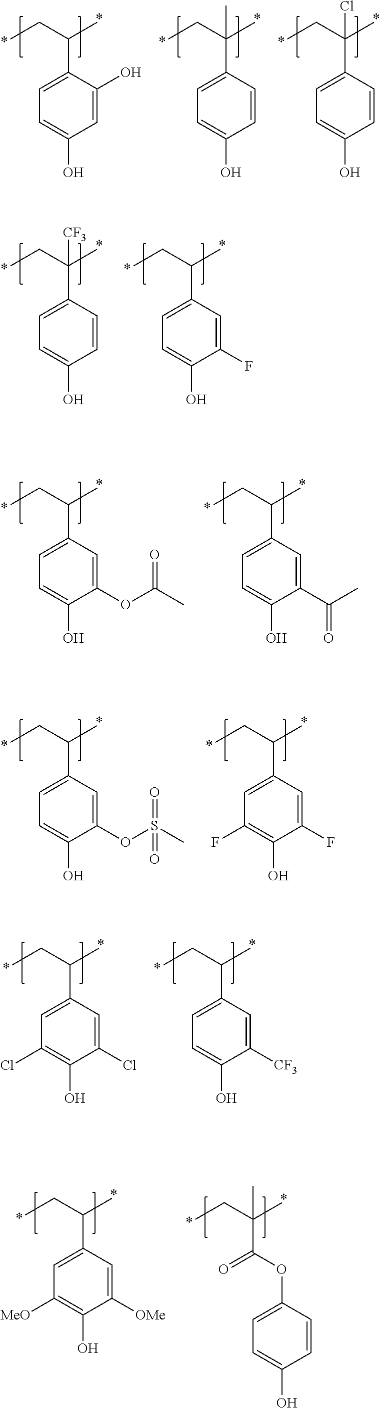

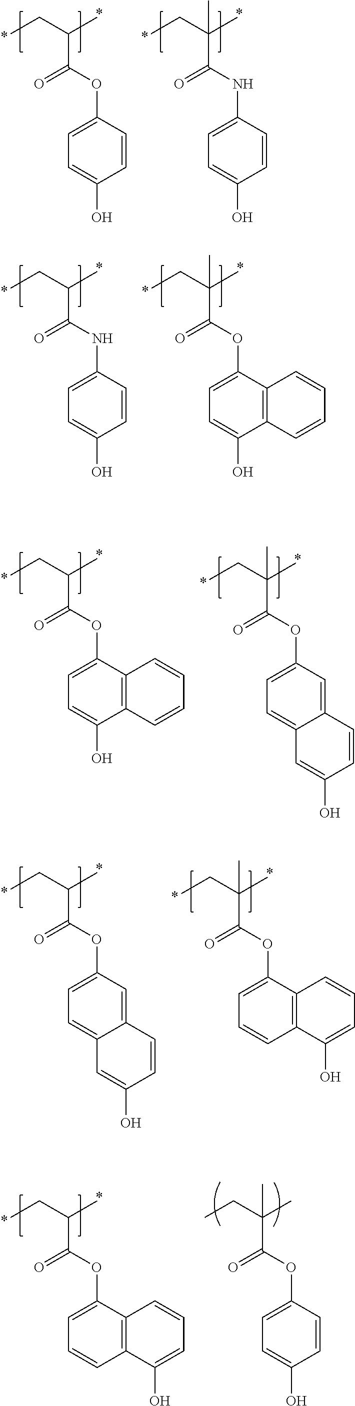

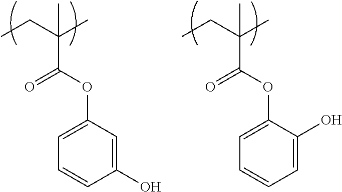

The resin (A) can have a repeating unit having a cyclic hydrocarbon structure having no polar group (for example, an acid group, a hydroxyl group, and a cyano group) and not exhibiting acid decomposability. Examples of such a repeating unit include a repeating unit represented by General Formula (IV).

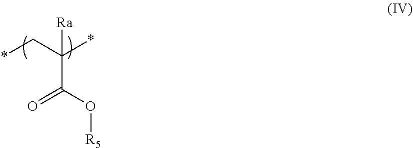

In General Formula (IV), R₅ represents a hydrocarbon group which has at least one cyclic structure and does not have a polar group.

Ra represents a hydrogen atom, an alkyl group, or a —CH₂—O—Ra₂ group. In the formula, Ra₂ represents a hydrogen atom, an alkyl group, or an acyl group. Ra₂ is preferably a hydrogen atom, a methyl group, a hydroxymethyl group, or a trifluoromethyl group, and particularly preferably a hydrogen atom or a methyl group.

The cyclic structure contained in R₅ includes a monocyclic hydrocarbon group and a polycyclic hydrocarbon group. Examples of the monocyclic hydrocarbon group include cycloalkyl groups having 3 to 12 carbon atoms, such as a cyclopentyl group, a cyclohexyl group, a cycloheptyl group, and a cyclooctyl group, cycloalkenyl groups having 3 to 12 carbon atoms, such as a cyclohexenyl group, and a phenyl group. Preferred examples of the monocyclic hydrocarbon group include a monocyclic hydrocarbon group having 3 to 7 carbon atoms, and more preferably a cyclopentyl group and a cyclohexyl group.

Examples of the polycyclic hydrocarbon group include a ring-aggregated hydrocarbon group and a crosslinked cyclic hydrocarbon group, and examples of the ring-aggregated hydrocarbon group include a bicyclohexyl group, a perhydronaphthalenyl group, a biphenyl group, and a 4-cyclohexylphenl group. Examples of the crosslinked cyclic hydrocarbon ring include bicyclic hydrocarbon rings such as a pinane ring, a bornane ring, a norpinane ring, a norbornane ring, and a bicyclooctane ring (a bicyclo[2.2.2]octane ring, a bicyclo[3.2.1]octane ring, and the like); tricyclic hydrocarbon rings such as a homobrendane ring, an adamantane ring, a tricyclo[5.2.1.0^{2,6}]decane ring, and a tricyclo[4.3.1.1^{2,5}]undecane ring; and tetracyclic hydrocarbon rings such as a tetracyclo[4.4.0.1^{2,5}.1^{7,10}]dodecane ring and a perhydro-1,4-methano-5,8-methanonaphthalene ring. Other examples of the crosslinked cyclic hydrocarbon ring include a hydrocarbon ring of a fused ring, for example, a fused ring in which a plurality of 5- to 8-membered cycloalkane rings such as a perhydronaphthalene (decalin) ring, a perhydroanthracene ring, a perhydrophenanthrene ring, a perhydroacenaphthene ring, a perhydrofluorene ring, a perhydroindene ring, and a perhydrophenalene ring are fused.

Preferred examples of the crosslinked cyclic hydrocarbon ring include a norbornyl group, an adamantyl group, a bicyclooctanyl group, and a tricyclo[5,2,1,0^{2,6}]decanyl group. More preferred examples of the crosslinked cyclic hydrocarbon ring include a norbornyl group and an adamantyl group.

These cyclic hydrocarbon structures may include a substituent, and preferred examples of the substituent include a halogen atom, an alkyl group, a hydroxyl group substituted with a hydrogen atom, an amino group substituted with a hydrogen atom, and the like. Preferred examples of the halogen atom include a bromine atom, a chlorine atom, and a fluorine atom, and preferred examples of the alkyl group include a methyl group, an ethyl group, a butyl group, and a t-butyl group. The alkyl group may further have a substituent, and examples of this substituent that may be further contained include a halogen atom, an alkyl group, a hydroxyl group substituted with a hydrogen atom, and an amino group substituted with a hydrogen atom.

Examples of the group substituted with a hydrogen atom include an alkyl group, a cycloalkyl group, an aralkyl group, a substituted methyl group, a substituted ethyl group, an alkoxycarbonyl group, and an aralkyloxycarbonyl group. Preferred examples of the alkyl group include an alkyl group having 1 to 4 carbon atoms, preferred examples of the substituted methyl group include a methoxymethyl group, a methoxythiomethyl group, a benzyloxymethyl group, a t-butoxymethyl group, and 2-methoxyethoxymethyl, preferred examples of the substituted ethyl group include 1-ethoxyethyl and 1-methyl-l-methoxyethyl, preferred examples of the acyl group include an aliphatic acyl group having 1 to 6 carbon atoms, such as a formyl group, an acetyl group, a propionyl group, a butyryl group, an isobutyryl group, a valeryl group, and pivaloyl, and examples of the alkoxycarbonyl group include an alkoxycarbonyl group having 1 to 4 carbon atoms.

The resin (A) may or may not contain a repeating unit having a cyclic hydrocarbon structure having no polar group and not exhibiting acid decomposability, but in a case where the resin (A) contains the repeating unit, the content of the repeating unit is preferably 1% to 40% by mole, and more preferably 2% to 20% by mole, with respect to all the repeating units in the resin (A).

Specific examples of the repeating unit having a cyclic hydrocarbon structure having no polar group and not exhibiting acid decomposability are set forth below, but the present invention is not limited thereto. In the formulae, Ra represents H, CH₃, CH₂OH, or CF₃.

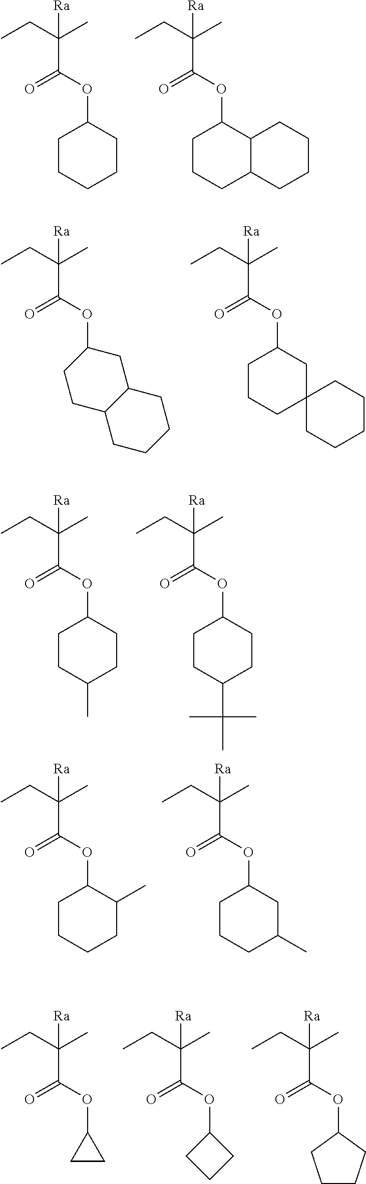

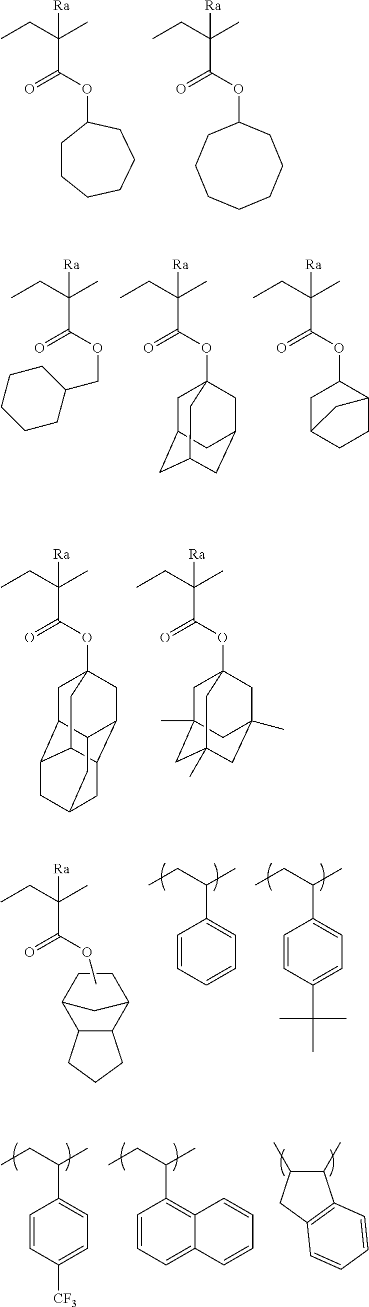

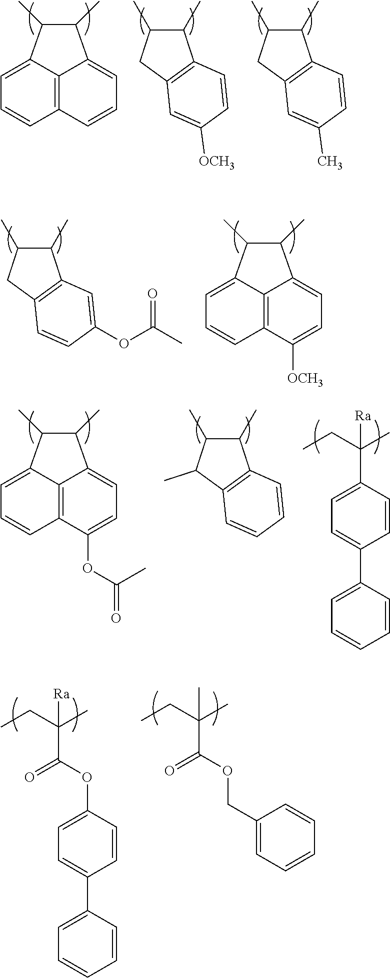

In addition to the repeating structural units, the resin (A) can have a variety of repeating structural units for the purpose of adjusting dry etching resistance or suitability for a standard developer, adhesiveness to a substrate, and a resist profile, and in addition, resolving power, heat resistance, sensitivity, and the like, which are characteristics generally required for the resist. Examples of such repeating structural units include, but are not limited to, repeating structural units corresponding to the following monomers.

Thus, it becomes possible to perform fine adjustments to performance required for the resin (A), in particular, (1) solubility with respect to a coating solvent, (2) film-forming properties (glass transition point), (3) alkali developability, (4) film loss (selection of hydrophilic, hydrophobic, or acid groups), (5) adhesiveness of an unexposed area to a substrate, (6) dry etching resistance, and the like.

Examples of such a monomer include a compound having one addition-polymerizable unsaturated bond selected from acrylic esters, methacrylic esters, acrylamides, methacrylamides, allyl compounds, vinyl ethers, vinyl esters, and the like.

In addition to these, an addition-polymerizable unsaturated compound that is copolymerizable with the monomers corresponding to various repeating structural units as described above may be copolymerized.

In the resin (A), the molar ratio of each repeating structural unit content is appropriately set in order to adjust dry etching resistance or suitability for a standard developer, adhesiveness to a substrate, and a resist profile of the resist, and in addition, resolving power, heat resistance, sensitivity, and the like, each of which is performance generally required for the resist.

The resin (A) can be synthesized in accordance with an ordinary method (for example, radical polymerization). Examples of the general synthesis method include a batch polymerization method in which polymerization is carried out by dissolving monomer species and an initiator in a solvent and heating the solution, a dropwise addition polymerization method in which a solution of monomer species and an initiator is added dropwise to a heating solvent for 1 to 10 hours, with the dropwise addition polymerization method being preferable. Examples of the reaction solvent include ethers such as tetrahydrofuran, 1,4-dioxane, and diisopropyl ether, ketones such as methyl ethyl ketone and methyl isobutyl ketone, ester solvents such as ethyl acetate, amide solvents such as dimethyl formamide and dimethyl acetamide, and a solvent which dissolves the composition of the embodiment of the present invention, such as propylene glycol monomethyl ether acetate, propylene glycol monomethyl ether, and cyclohexanone, which will be described later. It is more preferable to perform polymerization using the same solvent as the solvent used in the composition of the embodiment of the present invention. Thus, generation of the particles during storage can be inhibited.

It is preferable that the polymerization reaction is carried out in an inert gas atmosphere such as nitrogen and argon. As the polymerization initiator, commercially available radical initiators (an azo-based initiator, peroxide, or the like) are used to initiate the polymerization. As the radical initiator, an azo-based initiator is preferable, and the azo-based initiator having an ester group, a cyano group, or a carboxyl group is preferable. Preferable initiators include azobisisobutyronitrile, azobisdimethylvaleronitrile, dimethyl 2,2′-azobis(2-methyl propionate), or the like. The initiator is added or added in portionwise, as desired, a desired polymer is recovered after the reaction is completed, the reaction mixture is poured into a solvent, and then a method such as powder or solid recovery is used. The concentration of the reactant is 5% to 50% by mass and preferably 10% to 30% by mass. The reaction temperature is normally 10° C. to 150° C., preferably 30° C. to 120° C., and more preferably 60° C. to 100° C.

The weight-average molecular weight of the resin (A) is preferably 1,000 to 200,000, more preferably 2,000 to 20,000, still more preferably 3,000 to 15,000, and particularly preferably 3,000 to 11,000. By setting the weight-average molecular weight to 1,000 to 200,000, it is possible to prevent the deterioration of heat resistance or dry etching resistance, and also prevent the deterioration of developability and prevent the deterioration of film-forming properties due to increased viscosity.

The dispersity (molecular weight distribution) is usually 1.0 to 3.0, and the dispersity in the range of preferably 1.0 to 2.6, more preferably 1.0 to 2.0, and particularly preferably 1.1 to 2.0 is used. As the molecular weight distribution is smaller, the resolution and the resist shape are better, the side wall of the resist pattern is smoother, and the roughness is better.

The content of the resin (A) in the actinic ray-sensitive or radiation-sensitive composition is preferably 30% to 99% by mass, and more preferably 50% to 95% by mass, with respect to the total solid content in the actinic ray-sensitive or radiation-sensitive composition.

In addition, the resin (A) may be used singly or in combination of two or more kinds thereof.

<Compound (B) That Generates Acid upon Irradiation with Actinic Rays or Radiation>

The composition of the embodiment of the present invention preferably further contains a compound (B) that generates an acid upon irradiation with actinic rays or radiation (hereinafter also referred to as an “acid generator”). The compound (B) that generates an acid upon irradiation with actinic rays or radiation is preferably a compound that generates an organic acid upon irradiation with actinic rays or radiation.

As the acid generator, an acid generator that is appropriately selected from a photoinitiator for cationic photopolymerization, a photoinitiator for radical photopolymerization, a photo-decoloring agent for dyes, a photo-discoloring agent, a known compound that generates an acid upon irradiation with actinic rays or radiation, which is used for a microresist or the like, and a mixture thereof, can be used.

Examples of the acid generator include a diazonium salt, a phosphonium salt, a sulfonium salt, an iodonium salt, imidosulfonate, oxime sulfonate, diazodisulfone, disulfone, and o-nitrobenzyl sulfonate.

Examples of the preferred compounds among the acid generators include compounds represented by General Formulae (ZI), (ZII), and (ZIII).

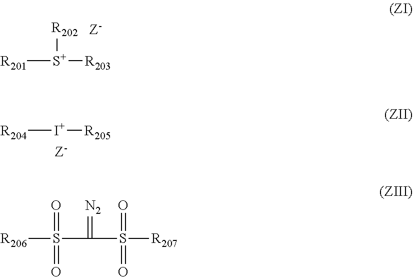

In General Formula (ZI),

R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

Furthermore, two of R₂₀₁ to R₂₀₃ may be bonded to each other to form a ring structure, and the ring may include an oxygen atom, a sulfur atom, an ester bond, an amide bond, or a carbonyl group, and examples of the group formed by the bonding of two of R₂₀₁ to R₂₀₃ include an alkylene group (for example, a butylene group and a pentylene group).

Z⁻ represents a non-nucleophilic anion.

Examples of the non-nucleophilic anion as Z⁻ include a sulfonate anion, a carboxylate anion, a sulfonylimide anion, a bis(alkylsulfonyl)imide anion, and a tris(alkylsulfonyl)methyl anion.

The non-nucleophilic anion is an anion having a noticeably low ability for causing a nucleophilic reaction, and is an anion which can suppress temporal decomposition caused by an intra-molecular nucleophilic reaction. Thus, the temporal stability of the resist composition is improved.

Examples of the sulfonate anion include an aliphatic sulfonate anion, an aromatic sulfonate anion, and a camphorsulfonate anion.

Examples of the carboxylate anion include an aliphatic carboxylate anion, an aromatic carboxylate anion, and an aralkyl carboxylate anion.

The aliphatic site in the aliphatic sulfonate anion and the aliphatic carboxylate anion may be an alkyl group or a cycloalkyl group, but preferred examples thereof include an alkyl group having 1 to 30 carbon atoms and a cycloalkyl group having 3 to 30 carbon atoms, such as a methyl group, an ethyl group, a propyl group, an isopropyl group, an n-butyl group, an isobutyl group, an sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, and a bornyl group.

Preferred examples of the aromatic group in the aromatic sulfonate anion and the aromatic carboxylate anion include an aryl group having 6 to 14 carbon atoms, such as a phenyl group, a tolyl group, and a naphthyl group.

The alkyl group, the cycloalkyl group, and the aryl group in the aliphatic sulfonate anion and the aromatic sulfonate anion may have a substituent. Examples of the substituent of the alkyl group, the cycloalkyl group, and the aryl group in the aliphatic sulfonate anion and the aromatic sulfonate anion include a nitro group, a halogen atom (a fluorine atom, a chlorine atom, a bromine atom, and an iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms). For the aryl group and the ring structure contained in each of the groups, examples of the examples further include an alkyl group (preferably having 1 to 15 carbon atoms) and a cycloalkyl group (preferably having 3 to 15 carbon atoms).

Preferred examples of the aralkyl group in the aralkyl carboxylate anion include an aralkyl group having 7 to 12 carbon atoms, such as a benzyl group, a phenethyl group, a naphthylmethyl group, a naphthylethyl group, and a naphthylbutyl group.

The alkyl group, the cycloalkyl group, the aryl group, and the aralkyl group in the aliphatic carboxylate anion, the aromatic carboxylate anion, and the aralkyl carboxylate anion may have a substituent. Examples of the substituent include the same halogen atoms, alkyl groups, cycloalkyl groups, alkoxy groups, and alkylthio groups as for the aromatic sulfonate anion.

Examples of the sulfonylimide anion include a saccharin anion.

The alkyl group in the bis(alkylsulfonyl)imide anion and the tris(alkylsulfonyl)methide anion is preferably an alkyl group having 1 to 5 carbon atoms, and examples thereof include a methyl group, an ethyl group, a propyl group, an isopropyl group, an n-butyl group, an isobutyl group, an sec-butyl group, a pentyl group, and a neopentyl group.

Two alkyl groups in the bis(alkylsulfonyl)imide anion may be linked to each other to form an alkylene group (preferably having 2 to 4 carbon atoms), which may form a ring together with an imido group and two sulfonyl groups. Examples of a substituent which may be contained in these alkyl groups and an alkylene group formed by linking two alkyl groups in the bis(alkylsulfonyl)imide anion include a halogen atom, an alkyl group substituted with a halogen atom, an alkoxy group, an alkylthio group, an alkyloxysulfonyl group, an aryloxysulfonyl group, and a cycloalkylaryloxysulfonyl group, and the alkyl group substituted with a fluorine atom is preferable.

Other examples of the non-nucleophilic anions include fluorinated phosphorus (for example, PF₆⁻), fluorinated boron (for example, BF₄⁻), and fluorinated antimony (for example, SbF₆⁻).

As the non-nucleophilic anion of Z⁻, an aliphatic sulfonate anion substituted with a fluorine atom at least at the a-position of sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom is preferable. As the non-nucleophilic anion, a perfluoroaliphatic sulfonate anion having 4 to 8 carbon atoms or a benzenesulfonate anion having a fluorine atom, and still more preferably a nonafluorobutanesulfonate anion, a perfluorooctanesulfonate anion, a pentafluorobenzenesulfonate anion, or a 3,5-bis(trifluoromethyl)benzenesulfonate anion is more preferable.

The acid generator is preferably a compound that generates an acid represented by General Formula (V) or (VI) upon irradiation with actinic rays or radiation. By incorporation of a cyclic organic group due to into the compound that generates an acid represented by General Formula (V) or (VI), it is possible to achieve more excellent resolution and roughness performance.

As the non-nucleophilic anion, an anion that generates an organic acid represented by General Formula (V) or (VI) can be used.

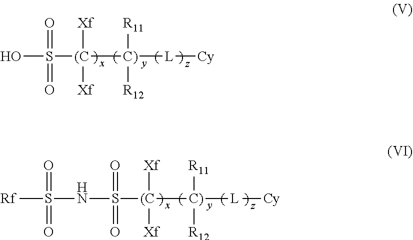

In the general formulae,

Xf's each independently represent a fluorine atom or an alkyl group substituted with at least one fluorine atom.

R₁₁ and R₁₂ each independently represent a hydrogen atom, a fluorine atom, or an alkyl group.

L's each independently represent a divalent linking group.

Cy represents a cyclic organic group.

Rf is a group including a fluorine atom.

x represents an integer of 1 to 20.

y represents an integer of 0 to 10.

z represents an integer of 0 to 10.

Xf represents a fluorine atom or an alkyl group substituted with at least one fluorine atom. The number of carbon atoms of the alkyl group is preferably 1 to 10, and more preferably 1 to 4. Further, the alkyl group substituted with at least one fluorine atom is preferably a perfluoroalkyl group.

Xf is preferably a fluorine atom or a perfluoroalkyl group having 1 to 4 carbon atoms. More specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, or

CH₂CH₂C₄F₉, and more preferably the fluorine atom or CF₃. In particular, it is preferable that both Xf s are fluorine atoms.

R₁₁ and R₁₂ each independently represent a hydrogen atom, a fluorine atom, or an alkyl group. The alkyl group may have a substituent (preferably a fluorine atom), and is preferably an alkyl group having 1 to 4 carbon atoms, and more preferably a perfluoroalkyl group having 1 to 4 carbon atoms. Specific examples of the alkyl group having a substituent of R₁₁ and R₁₂ include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

L represents a divalent linking group. Examples of the divalent linking group include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), and a divalent linking group obtained by combining a plurality of the groups. Among these, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- is more preferable.

Cy represents a cyclic organic group. Examples of the cyclic organic group include an alicyclic group, an aryl group, and a heterocycle group.

The alicyclic group may be monocyclic or polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among those, an alicyclic group with a bulky structure having 7 or more carbon atoms, such as a norbornyl group, a tricyclodecanyl group, a tetracyclodecanyl group, a tetracyclododecanyl group, an adamantyl group, a decahydroquinoline group, and a decahydroisoquinoline is preferable from the viewpoints of suppressing diffusivity into the film during a post-exposure baking (PEB) process and improving a mask error enhancement factor (MEEF).

The aryl group may be monocyclic or polycyclic. Examples of the aryl group include a phenyl group, a naphthyl group, a phenanthryl group, and an anthryl group.

The heterocyclic group may be monocyclic or polycyclic, but in a case where it is polycyclic, it is possible to suppress acid diffusion. Further, the heterocyclic group may or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having aromaticity include a tetrahydropyran ring, a lactone ring, a sultone ring, and a decahydroisoquinoline ring. As a heterocycle in the heterocyclic group, a furan ring, a thiophene ring, a pyridine ring, or a decahydroisoquinoline ring is particularly preferable.

The cyclic organic group may have a substituent. Examples of the substituent include, an alkyl group (which may be linear or branched, and preferably has 1 to 12 carbon atoms), a cycloalkyl group (which may be monocyclic, polycyclic, or spiro ring, and preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic ester group. Incidentally, the carbon constituting the cyclic organic group (carbon contributing to ring formation) may be carbonyl carbon.

x is preferably 1 to 8, and among these, x is preferably 1 to 4, and particularly preferably 1. y is preferably 0 to 4, and more preferably 0. z is preferably 0 to 8, and among these, z is preferably 0 to 4.

Examples of the group including a fluorine atom, represented by Rf, include an alkyl group having at least one fluorine atom, a cycloalkyl group having at least one fluorine atom, and an aryl group having at least one fluorine atom.

The alkyl group, the cycloalkyl group, and the aryl group may be substituted with a fluorine atom, and may also be substituted with another substituent including a fluorine atom. In a case where Rf is a cycloalkyl group having at least one fluorine atom or an aryl group having at least one fluorine atom, examples of another substituent including a fluorine atom include an alkyl group substituted with at least one fluorine atom.

Furthermore, the alkyl group, the cycloalkyl group, and the aryl group may further be substituted with a substituent not including a fluorine atom. Examples of the substituent include the substituents described above as Cy, which do not include a fluorine atom.

Examples of the alkyl group substituted with at least one fluorine atom represented by Xf include the same ones as the alkyl groups described above as the alkyl group having at least one fluorine atom represented by Rf. Examples of the cycloalkyl group having at least one fluorine atom represented by Rf include a perfluorocyclopentyl group and a perfluorocyclohexyl group. Examples of the aryl group having at least one fluorine atom represented by Rf include a perfluorophenyl group.

Examples of the organic group represented by each of R₂₀₁, R₂₀₂, and R₂₀₃ include groups corresponding to the compounds (ZI-1), (ZI-2), (ZI-3), and (ZI-4) which will be described later.

Incidentally, the organic group may be a compound having a plurality of structures represented by General Formula (ZI). For example, it may be a compound having a structure in which at least one of R₂₀₁, R₂₀₂, or R₂₀₃ in the compound represented by General Formula (ZI) is bonded to at least one of R₂₀₁, R₂₀₂, or R₂₀₃ of another compound represented by General Formula (ZI) through a single bond or a linking group.

More preferred examples of the component (ZI) include compounds (ZI-1), (ZI-2), (ZI-3), and (ZI-4) described below.

The compound (ZI-1) is an arylsulfonium compound in which at least one of R₂₀₁, R₂₀₂, or R₂₀₃ in General Formula (ZI) is an aryl group, that is, a compound having arylsulfonium as a cation.

In the arylsulfonium compound, all of R₂₀₁ to R₂₀₃ may be aryl groups, or some of R₂₀₁ to R₂₀₃ may be aryl groups and the remainders may be alkyl groups or cycloalkyl groups, but all of R₂₀₁ to R₂₀₃ may be aryl groups.

Examples of the arylsulfonium compound include a triarylsulfonium compound, a diarylalkylsulfonium compound, an aryl dialkylsulfonium compound, a diarylcycloalkyl sulfonium compound, and an aryldicycloalkyl sulfonium compound.

The aryl group in the arylsulfonium compound is preferably a phenyl group or a naphthyl group, and more preferably a phenyl group. The aryl group may be an aryl group having a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium compound has two or more aryl groups, these two or more aryl groups may be the same as or different from each other.

The alkyl group or the cycloalkyl group which may be contained, if desired, in the arylsulfonium compound, is preferably a linear or branched alkyl group having 1 to 15 carbon atoms or a cycloalkyl group having 3 to 15 carbon atoms, for example, a methyl group, an ethyl group, a propyl group, an n-butyl group, a sec-butyl group, a t-butyl group, a cyclopropyl group, a cyclobutyl group, and a cyclohexyl group.

The aryl group, the alkyl group, and the cycloalkyl group of each of R₂₀₁ to R₂₀₃ may have an alkyl group (for example, an alkyl group having 1 to 15 carbon atoms), a cycloalkyl group (for example, a cycloalkyl group having 3 to 15 carbon atoms), an aryl group (for example, an aryl group having 6 to 14 carbon atoms), an alkoxy group (for example, an alkoxy group having 1 to 15 carbon atoms), a halogen atom, a hydroxyl group, or a phenylthio group as a sub stituent. Preferred examples of the sub stituent include a linear, branched alkyl group having 1 to 12 carbon atoms, a cycloalkyl group having 3 to 12 carbon atoms, and a linear, branched, or cyclic alkoxy group having 1 to 12 carbon atoms, and more preferably an alkyl group having 1 to 4 carbon atoms and an alkoxy group having 1 to 4 carbon atoms. The substituent may be substituted to any one of three R₂₀₁ to R₂₀₃ or may be substituted to three all of them. Further, in a case where R₂₀₁ to R₂₀₃ are each an aryl group, the substituent is preferably substituted at the p-position of the aryl group.

Next, the compound (ZI-2) will be described.

The compound (ZI-2) is a compound in which R₂₀₁ to R₂₀₃ in General Formula (ZI) each independently represent an organic group containing no aromatic ring. Here, the aromatic ring also encompasses an aromatic ring containing a heteroatom.

The organic group, as each of R₂₀₁ to R₂₀₃, containing no aromatic ring, has generally 1 to 30 carbon atoms, and preferably 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and particularly preferably a linear or branched 2-oxoalkyl group.

The alkyl group and the cycloalkyl group as each of R₂₀₁ to R₂₀₃ may be linear, branched, or cyclic, and preferred examples thereof include a linear or branched alkyl group having 1 to 10 carbon atoms (such as a methyl group, an ethyl group, a propyl group, a butyl group, and a pentyl group), and a cycloalkyl group (a cyclopentyl group, a cyclohexyl group, and a norbornyl group) having 3 to 10 carbon atoms. More preferred examples of the alkyl group include a 2-oxoalkyl group and an alkoxycarbonylmethyl group. More preferred examples of the cycloalkyl group include a 2-oxocycloalkyl group.

The 2-oxoalkyl group may be linear or branched, and preferred examples thereof include the alkyl group which has >C═O at the 2-position thereof.

Preferred examples of the 2-oxocycloalkyl group include the cycloalkyl group which has >C═O at the 2-position thereof.

Preferred examples of the alkoxy group in the alkoxycarbonylmethyl group include an alkoxy group having 1 to 5 carbon atoms (such as a methoxy group, an ethoxy group, a propoxy group, a butoxy group, and a pentoxy group).

Each of R₂₀₁ to R₂₀₃ may further be substituted with a halogen atom, an alkoxy group (for example, an alkoxy group having 1 to 5 carbon atoms), a hydroxyl group, a cyano group, or a nitro group.

Next, the compound (ZI-3) will be described.

The compound (ZI-3) is a compound represented by General Formula (ZI-3), the compound having a phenacylsulfonium salt structure.

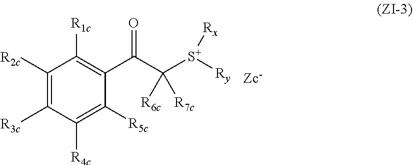

In General Formula (ZI-3),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Among any two or more members out of R_{1c} to R_{5c}, R_{5c} and R_{6c}, R_{6c} and R_{7c}, R_{5c} and Rₓ, or Rₓ and R_{y} each may be bonded to each other to form a ring structure, and the ring structure may contain an oxygen atom, a sulfur atom, a ketone group, an ester bond, or an amide bond.

Examples of the ring structure include an aromatic or non-aromatic hydrocarbon ring, an aromatic or non-aromatic heterocycle, or a polycyclic fused ring composed of two or more of these rings. Examples of the ring structure include 3- to 10-membered rings, and the ring structures are preferably 4- to 8-membered ring, and more preferably 5- or 6-membered rings.

Examples of groups formed by the bonding of any two or more of R_{1c} to R_{5c}, R_{6c} and R_{7c}, or Rₓ and R_{y} include a butylene group and a pentylene group.

As groups formed by the bonding of R_{5c} and R_{6c}, and R_{5c} and Rₓ, a single bond or alkylene group is preferable, and examples thereof include a methylene group and an ethylene group.

Zc⁻ represents a non-nucleophilic anion and examples thereof include the same non-nucleophilic anions as Z⁻ in General Formula (ZI).

The alkyl group as each of R_{1c} to R_{7c} may be linear or branched, examples thereof include an alkyl group having 1 to 20 carbon atoms, preferably a linear or branched alkyl group having 1 to 12 carbon atoms (for example, a methyl group, an ethyl group, a linear or branched propyl group, a linear or branched butyl group, and a linear or branched pentyl group), and examples of the cycloalkyl group include a cycloalkyl group having 3 to 10 carbon atoms (for example, a cyclopentyl group and a cyclohexyl group).

The aryl group as each of R_{1c} to R_{5c} preferably has 5 to 15 carbon atoms, and examples thereof include a phenyl group and a naphthyl group.

The alkoxy group as each of R_{1c} to R_{5c} may be linear, branched, or cyclic, and examples thereof include an alkoxy group having 1 to 10 carbon atoms, preferably linear and branched alkoxy groups having 1 to 5 carbon atoms (for example, a methoxy group, an ethoxy group, a linear or branched propoxy group, a linear or branched butoxy group, and a linear or branched pentoxy group), and a cyclic alkoxy group having 3 to 10 carbon atoms (for example, a cyclopentyloxy group and a cyclohexyloxy group).

Specific examples of the alkoxy group in the alkoxycarbonyl group as each of R_{1c} to R_{5c} are the same as the specific example of the alkoxy group as each of R_{1c} to R_{5c}.

Specific examples of the alkyl group in the alkylcarbonyloxy group and the alkylthio group as each of R_{1c} to R_{5c} are the same as the specific example of the alkyl group as each of R_{1c} to R_{5c}.

Specific examples of the alkoxy group in the cycloalkylcarbonyloxy group as each of R_{1c} to R_{5c} are the same as the specific example of the cycloalkyl group as each of R_{1c} to R_{5c}.

Specific examples of the aryl group in the aryloxy group and the arylthio group as each of R_{1c} to R_{5c} are the same as the specific example of the aryl group as each of R_{1c} to R_{5c}.

It is preferable that any one of R_{1c}, . . . , or R_{5c} is a linear or branched alkyl group, a cycloalkyl group, or a linear, branched or cyclic alkoxy group, and it is more preferable that the total number of carbon atoms of R_{1c} to R_{5c} is 2 to 15. Thus, the solubility in a solvent is further improved and generation of particles during storage is suppressed.

Examples of the ring structure that may be formed by mutual bonding of any two or more of R_{1c}, . . . , or R_{5c} preferably include a 5- or 6-membered ring, and particularly preferably a 6-membered ring (for example, a phenyl ring).

Examples of the ring structure that may be formed by mutual bonding of R_{5c} and R₆ include a 4-membered or higher ring (particularly preferably a 5- or 6-membered ring) formed together with a carbonyl carbon atom and a carbon atom in General Formula (I) by constituting a single bond or alkylene group (a methylene group, an ethylene group, and the like) by mutual bonding of R_{5c} and R_{6c}.

The aryl group as each of R_{6c} and R_{7c} preferably has 5 to 15 carbon atoms, and examples thereof include a phenyl group and a naphthyl group.

In aspects of R_{6c} and R_{7c}, a case where both of R_{6c} and R_{7c} are an alkyl group is preferable. In particularly, a case where R_{6c} and R_{7c} are each a linear or branched alkyl group having 1 to 4 carbon atoms is preferable, and a case where both of R_{6c} and R_{7c} are a methyl group is preferable.

Furthermore, in a case where R_{6c} and R_{7c} are bonded to form a ring, the group formed by bonding of R_{6c} and R_{7c} is preferably an alkylene group having 2 to 10 carbon atoms, and examples thereof include an ethylene group, a propylene group, a butylene group, a pentylene group, and a hexylene group. Further, the ring formed by bonding of R_{6c} and R_{7c} may have a heteroatom such as an oxygen atom in the ring.

Examples of the alkyl group and the cycloalkyl group as Rₓ and R_{y} include the same ones as the alkyl groups and the cycloalkyl groups as for R_{1c} to R_{7c}.

The 2-oxoalkyl group and the 2-oxocycloalkyl group as each of Rₓ and R_{y} may be linear or branched, and preferred examples thereof include the alkyl group which has >C═O at the 2-position of the alkyl group and the cycloalkyl group as each of R_{1c} to R_{7c}.

Examples of the alkoxy group in the alkoxycarbonylalkyl group as each of Rₓ and R_{y} include the same alkoxy groups as for each of R_{1c} to R_{5c}, and examples of the alkyl group include an alkyl group having 1 to 12 carbon atoms, and preferably a linear alkyl group having 1 to 5 carbon atoms (for example, a methyl group and an ethyl group).

The allyl group as each of Rₓ and R_{y} is not particularly limited, and is preferably an unsubstituted allyl group or an allyl group substituted with a monocyclic or polycyclic cycloalkyl group (preferably a cycloalkyl group having 3 to 10 carbon atoms).

The vinyl group as each of Rₓ and R_{y} is not particularly limited, and is preferably an unsubstituted vinyl group or a vinyl group substituted with a monocyclic or polycyclic cycloalkyl group (preferably a cycloalkyl group having 3 to 10 carbon atoms).

Examples of the ring structure that may be formed by mutual bonding of R_{5c} and Rₓ include a 5-membered or higher ring (particularly preferably a 5-membered ring) formed together with a sulfur atom and a carbonyl carbon atom in General Formula (I) by constituting a single bond or alkylene group (a methylene group, an ethylene group, and the like) by mutual bonding of R_{5c} and R.

Examples of the ring structure which may be formed by mutual bonding of Rₓ and R_{y} include a 5- or 6-membered ring, and particularly preferably a 5-membered ring (that is, a tetrahydrothiophene ring) which is formed by divalent Rₓ and R_{y} (for example, a methylene group, an ethylene group, and a propylene group) together with a sulfur atom in General Formula (ZI-3).

Rₓ and R_{y} are each preferably an alkyl group or a cycloalkyl group having 4 or more carbon atoms, more preferably an alkyl group having 6 or more carbon atoms, and still more preferably an alkyl group having 8 or more carbon atoms.

R_{1c} to R_{7c}, Rₓ and R_{y} may further have a substituent, and examples of such a substituent include a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, and an aryloxycarbonyloxy group.

In General Formula (ZI-3), it is more preferable that R_{1c}, R_{2c}, R₄, and R_{5c} each independently represent a hydrogen atom, and R_{1c} represents a group other than a hydrogen atom, that is, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

Specific examples of the cations of compounds represented by General Formula (ZI-2) or (ZI-3) in the present invention include the following cations.

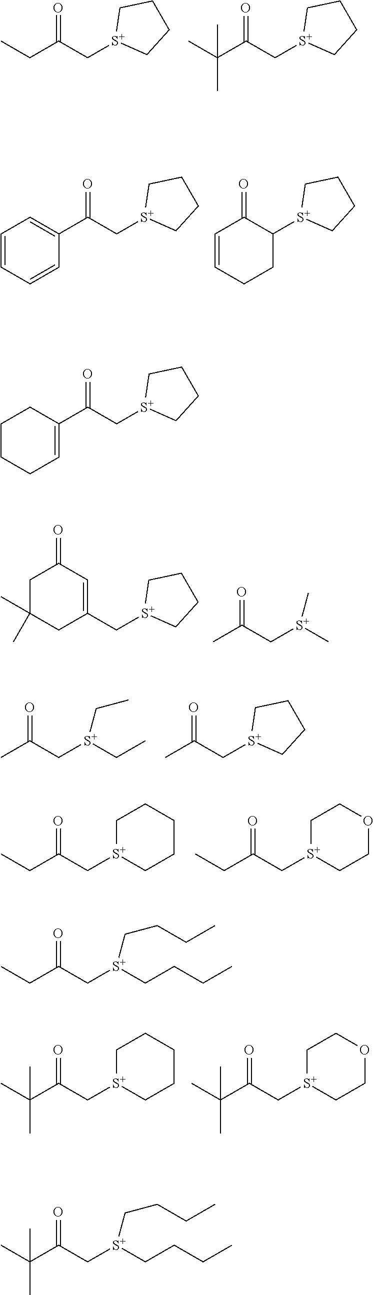

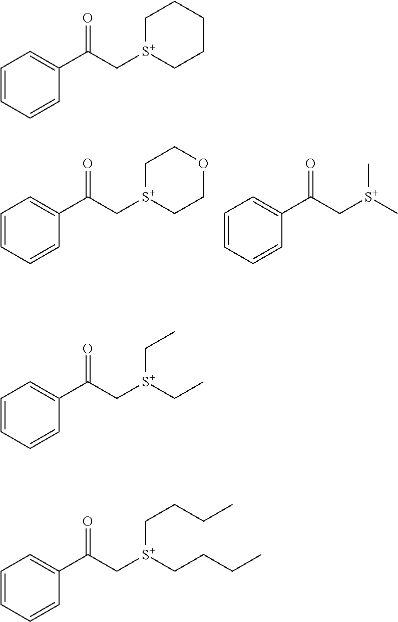

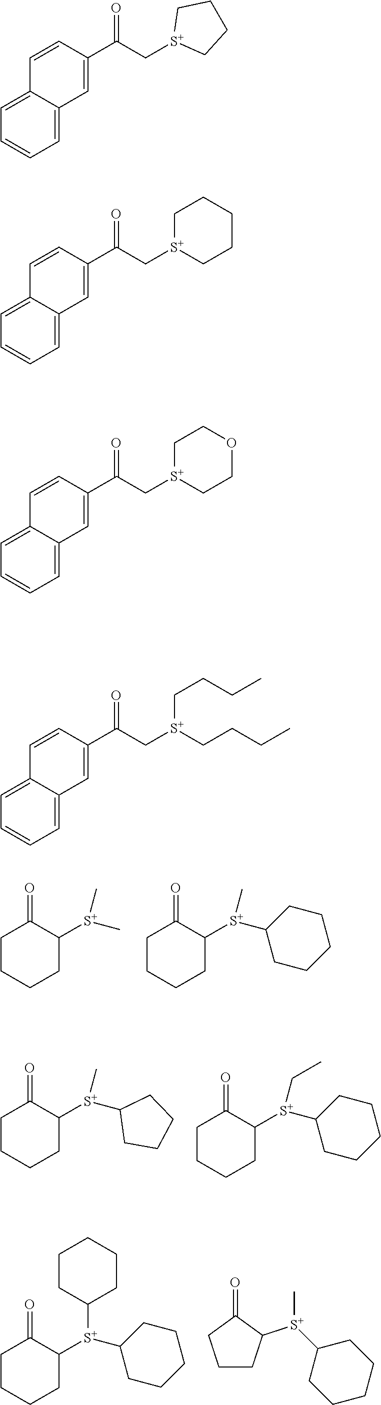

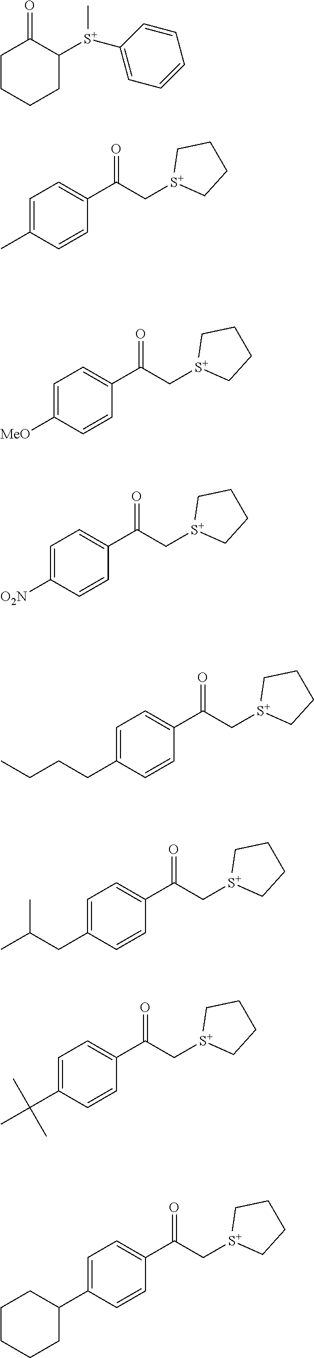

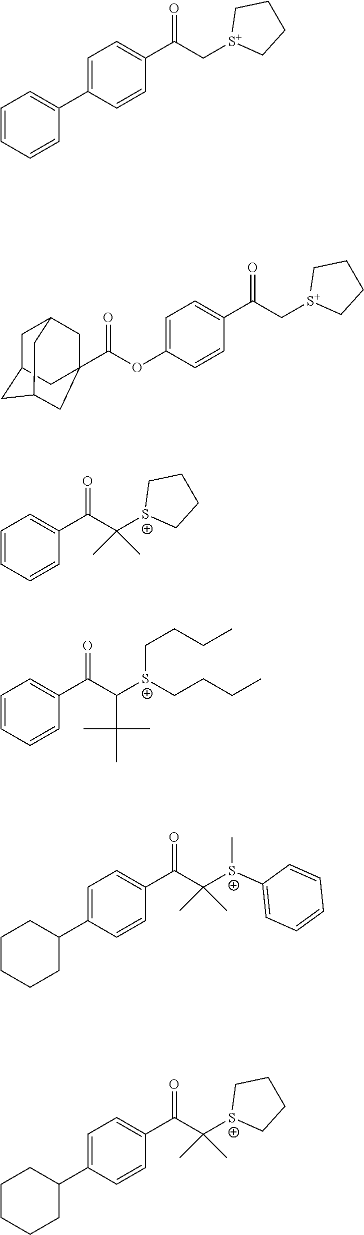

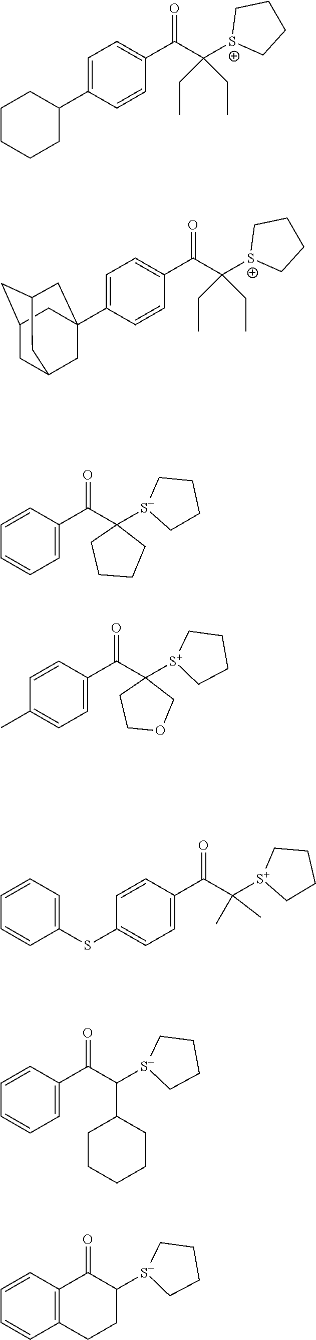

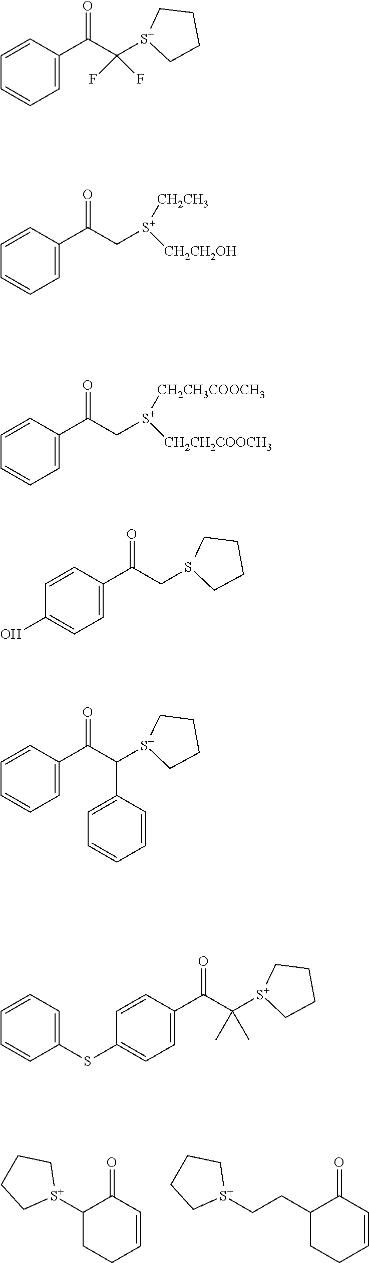

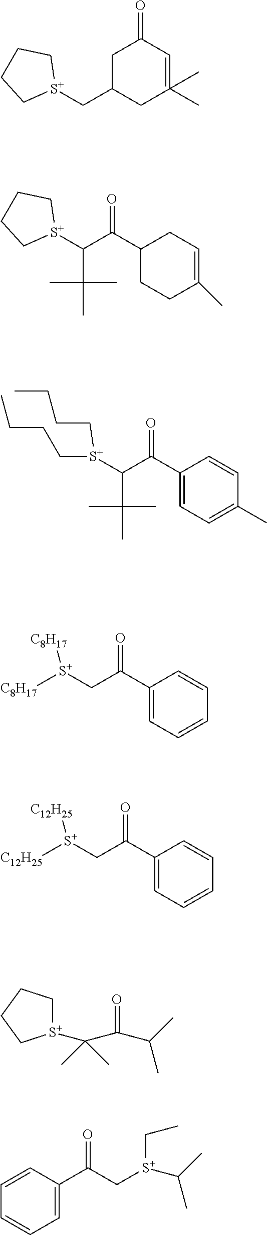

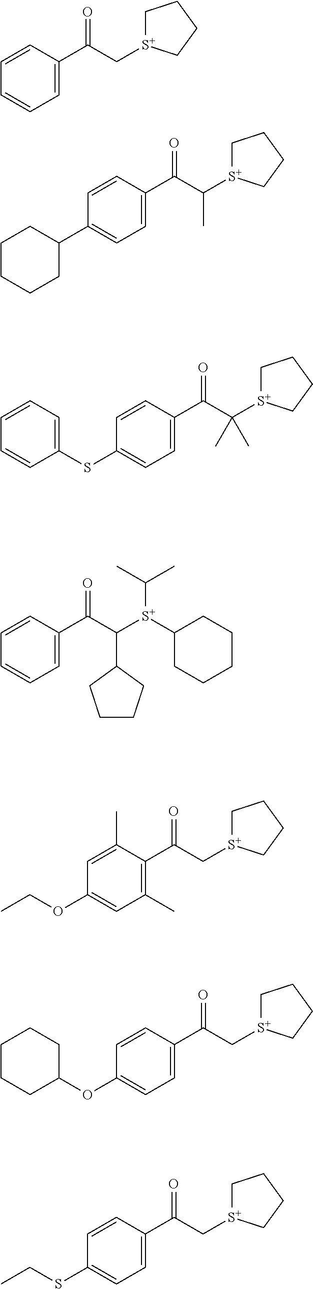

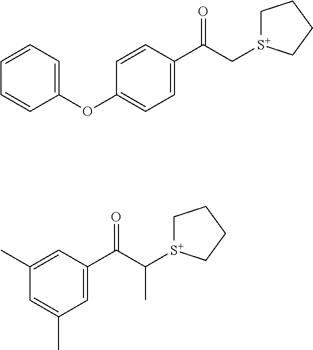

Next, the compound (ZI-4) will be described.

The compound (ZI-4) is represented by General Formula (ZI-4).

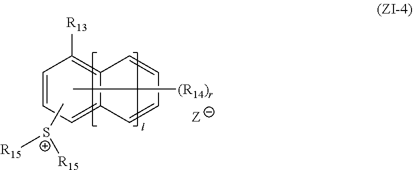

In General Formula (ZI-4),

R₁₃ represents a hydrogen atom, a fluorine atom, a hydroxyl group, an alkyl group, a cycloalkyl group, an alkoxy group, an alkoxycarbonyl group, or a group having a cycloalkyl group. These groups may have a substituent.

In a case where R₁₄'s are present in plural numbers, they each independently represent a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group. These groups may have a substituent.

R₁₅'s each independently represent an alkyl group, a cycloalkyl group, or a naphthyl group. Two R₁₅'s may be bonded to each other to form a ring. These groups may have a sub stituent.

l represents an integer of 0 to 2.

r represents an integer of 0 to 8.

Z⁻ represents a non-nucleophilic anion and examples thereof include the same non-nucleophilic anions as Z⁻ in General Formula (ZI).

In General Formula (ZI-4), as the alkyl group of each of R₁₃, R₁₄, and R₁₅, an alkyl which is linear or branched and has 1 to 10 carbon atoms is preferable, and preferred examples thereof include a methyl group, an ethyl group, an n-butyl group, and a t-butyl group.

Examples of the cycloalkyl group represented by each of R₁₃, R₁₄, and R₁₅ include a monocyclic or polycyclic cycloalkyl group (preferably a cycloalkyl group having 3 to 20 carbon atoms), and cyclopropyl, cyclopentyl, cyclohexyl, cycloheptyl, and cyclooctyl are particularly preferred.

The alkoxy group represented by each of R₁₃ and R₁₄ is linear or branched, preferably has 1 to 10 carbon atoms, and is preferably a methoxy group, an ethoxy group, an n-propoxy group, an i-propoxy group, an n-butoxy group, or the like.

The alkoxycarbonyl group represented by each of R₁₃ and R₁₄ is linear or branched, preferably has 2 to 11 carbon atoms, and is preferably a methoxycarbonyl group, an ethoxycarbonyl group, an n-butoxycarbonyl group, or the like.

Examples of a group having the cycloalkyl group of each of R₁₃ and R₁₄ include an alkoxy group having a monocyclic or polycyclic cycloalkyl group (preferably a cycloalkyl group having 3 to 20 carbon atoms), for example, a monocyclic or polycyclic cycloalkyloxy group, and an alkoxy group having a monocyclic or polycyclic cycloalkyl group. These groups may further have a substituent.

As the monocyclic or polycyclic cycloalkyloxy group of each of R₁₃ and R₁₄, a monocyclic or polycyclic cycloalkyloxy group having a total number of carbon atoms of 7 or more is preferable, a monocyclic or polycyclic cycloalkyloxy group having a total number of carbon atoms from 7 to 15 is more preferable, and a monocyclic or polycyclic cycloalkyloxy group having a monocyclic cycloalkyl group is preferable. The monocyclic cycloalkyloxy group having a total number of carbon atoms of 7 or more represents a monocyclic cycloalkyloxy group formed of a cycloalkyloxy group such as a cyclopropyloxy group, a cyclobutyloxy group, a cyclopentyloxy group, a cyclohexyloxy group, a cycloheptyloxy group, a cyclooctyloxy group, and a cyclododecanyloxy group, which optionally has a substituent such as an alkyl group such as a methyl group, an ethyl group, a propyl group, a butyl group, a pentyl group, a hexyl group, a heptyl group, an octyl group, a dodecyl group, a 2-ethylhexyl group, an isopropyl group, an sec-butyl group, a t-butyl group, and an iso-amyl group, a hydroxyl group, a halogen atom (fluorine, chlorine, bromine, or iodine), a nitro group, a cyano group, an amido group, a sulfonamido group, an alkoxy group such as a methoxy group, an ethoxy group, a hydroxyethoxy group, a propoxy group, a hydroxypropoxy group, and a butoxy group, an alkoxycarbonyl group such as a methoxycarbonyl group and an ethoxycarbonyl group, an acyl group such as a formyl group, an acetyl group, and a benzoyl group, an acyloxy group such as an acetoxy group and a butyryloxy group, and a carboxy group, in which a total number of carbon atoms thereof including those of any optional substituents on the cycloalkyl group is 7 or more.

In addition, examples of the polycyclic cycloalkyloxy group having a total number of carbon atoms of 7 or more include a norbornyloxy group, a tricyclodecanyloxy group, a tetracyclodecanyloxy group, and an adamantyloxy group.

The alkoxy group having the monocyclic or polycyclic cycloalkyl group as each of R₁₃ and R₁₄ preferably has a total number of carbon atoms of 7 or more, more preferably has a total number of carbon atoms from 7 to 15, and is preferably an alkoxy group having a monocyclic cycloalkyl group. The alkoxy group having a monocyclic cycloalkyl group having a total number of carbon atoms of 7 or more represents an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy, and iso-amyloxy, which is substituted with a monocyclic cycloalkyl group which may have the above-mentioned substituent, in which a total number of carbon atoms thereof including the substituents is 7 or more. Examples of the alkoxy group include a cyclohexylmethoxy group, a cyclopentylethoxy group, and a cyclohexylethoxy group, and the cyclohexylmethoxy group is preferable.

Moreover, examples of the alkoxy group having a polycyclic cycloalkyl group having a total number of carbon atoms of 7 or more include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, and an adamantylethoxy group, and the norbornylmethoxy group, the norbornylethoxy group, and the like are preferable.

Examples of the alkyl group of the alkylcarbonyl group of R₁₄ include the same specific examples of the above-mentioned alkyl groups as each of R₁₃ to R₁₅.

The alkylsulfonyl group and the cycloalkylsulfonyl groups of R₁₄ may be linear, branched, or cyclic, each preferably have 1 to 10 carbon atoms, and are each preferably, for example, a methanesulfonyl group, an ethanesulfonyl group, an n-propanesulfonyl group, an n-butanesulfonyl group, a cyclopentanesulfonyl group, a cyclohexanesulfonyl group, or the like.

Examples of a substituent that may be contained in each of the groups include a halogen atom (for example, a fluorine atom), a hydroxyl group, a carboxyl group, a cyano group, a nitro group, an alkoxy group, an alkoxyalkyl group, an alkoxycarbonyl group, and an alkoxycarbonyloxy group.

Examples of the alkoxy group include a linear, branched, or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, and a cyclohexyloxy group.

Examples of the alkoxyalkyl group include a linear, branched, or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group, and a 2-ethoxyethyl group.

Examples of the alkoxycarbonyl group include a linear, branched, or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group, and cyclohexyloxycarbonyl.

Examples of the alkoxycarbonyloxy group include a linear, branched, or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group, and cyclohexyloxycarbonyloxy.

Examples of the ring structure that may be formed by mutual bonding of two R₁₅'s include a 5- or 6-membered ring, and particularly preferably a 5-membered ring (that is, a tetrahydrothiophene ring), which is formed by two R₁₅'s together with the sulfur atom in General Formula (ZI-4), and the ring structure may be fused with an aryl group or a cycloalkyl group. The divalent R₁₅ may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group, and an alkoxycarbonyloxy group. A plurality of the substituents for the ring structure may be present, and they may be bonded to each other to form a ring (an aromatic or non-aromatic hydrocarbon ring, an aromatic or non-aromatic heterocycle, a polycyclic fused ring formed by combination of two or more of these rings, or the like).

R₁₅ in General Formula (ZI-4) is preferably a methyl group, an ethyl group, a naphthyl group, a divalent group which allows two R₁₅'s to be bonded to each other to form a tetrahydrothiophene ring structure together with a sulfur atom, or the like.

Examples of the substituent which may be contained in each of R₁₃ and R₁₄ include a hydroxyl group, an alkoxy group, or an alkoxycarbonyl group, and the substituent is preferably a halogen atom (particularly a fluorine atom).

l is preferably 0 or 1, and more preferably 1.

r is preferably 0 to 2.

Examples of the cation of the compound represented by General Formula (ZI-4) in the present invention include the following specific examples.

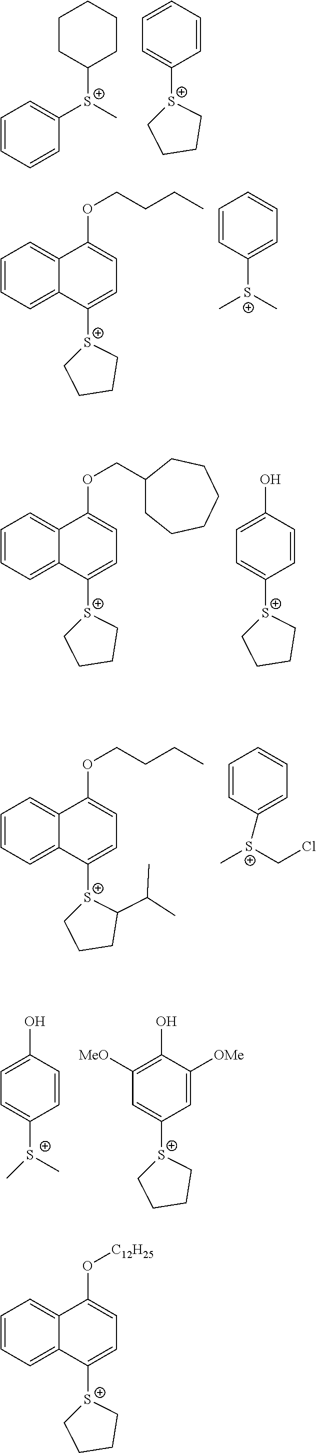

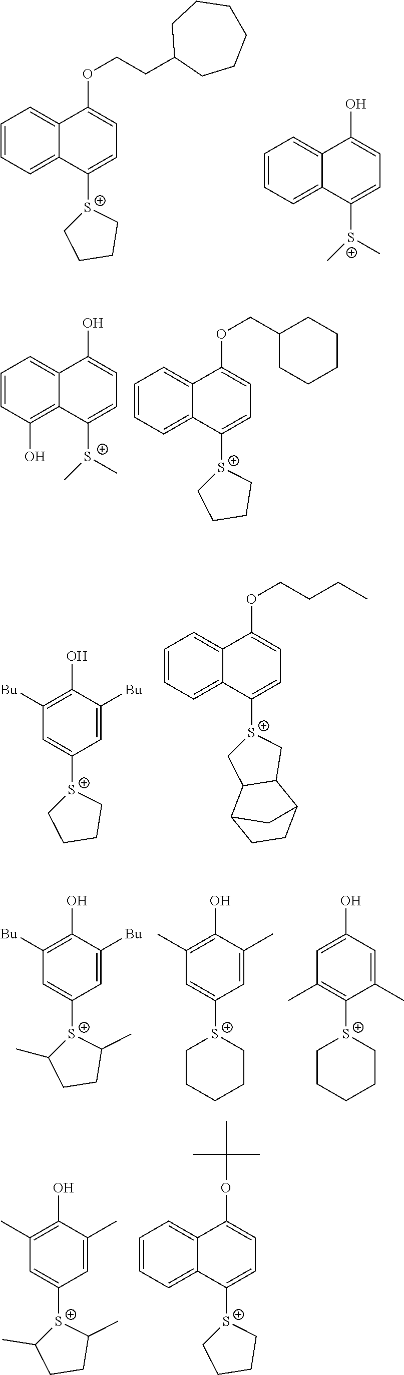

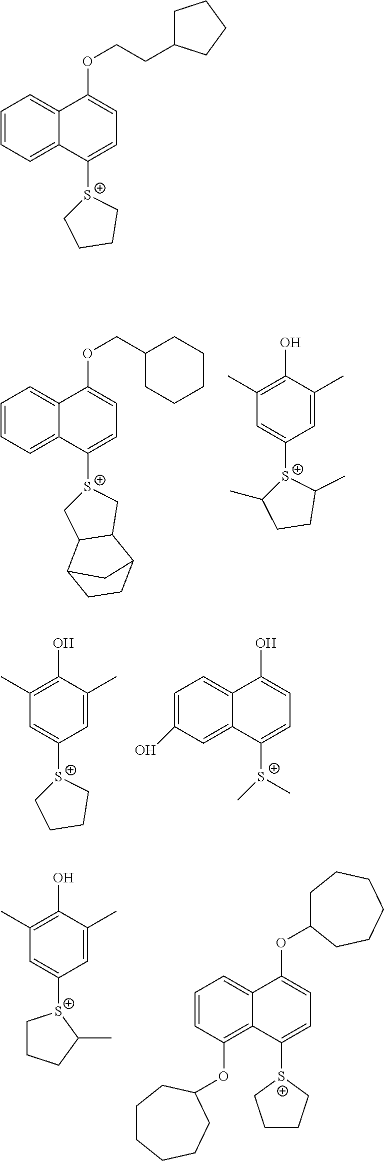

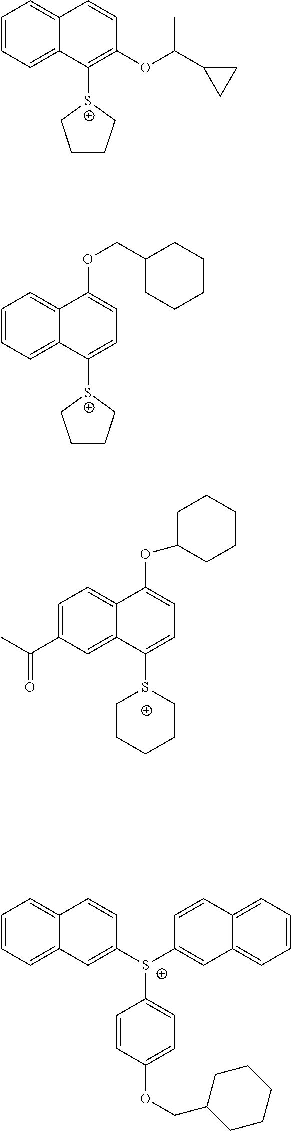

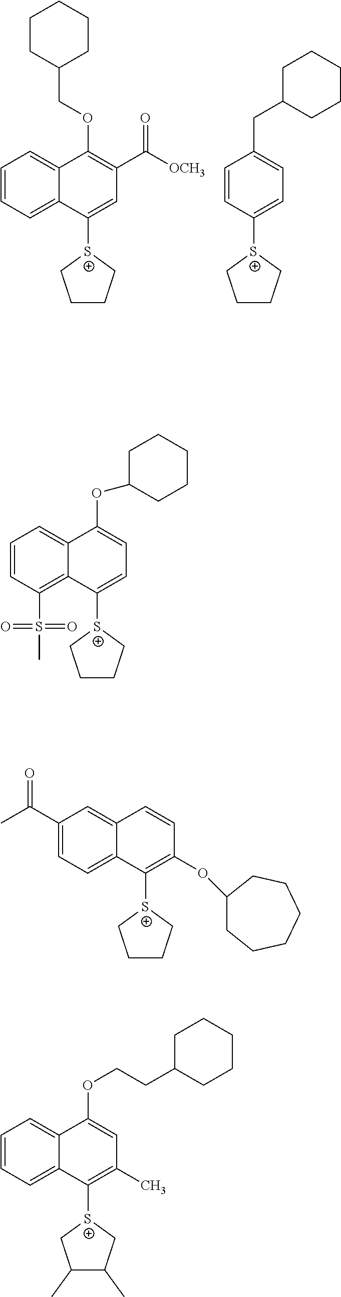

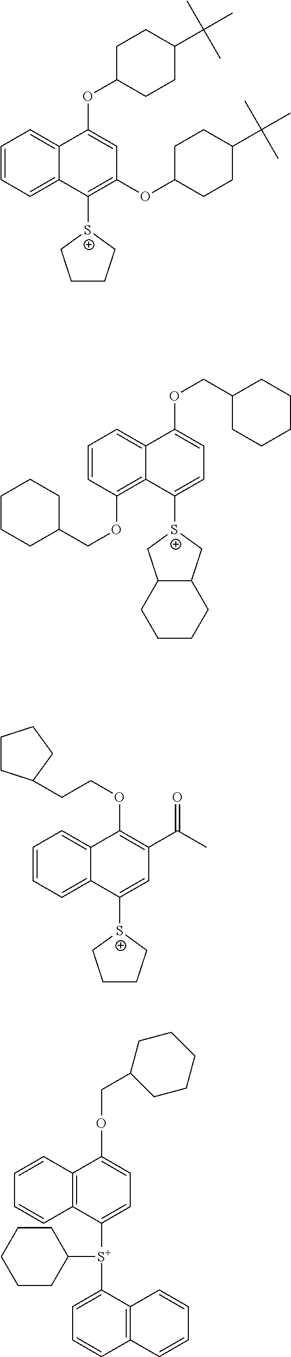

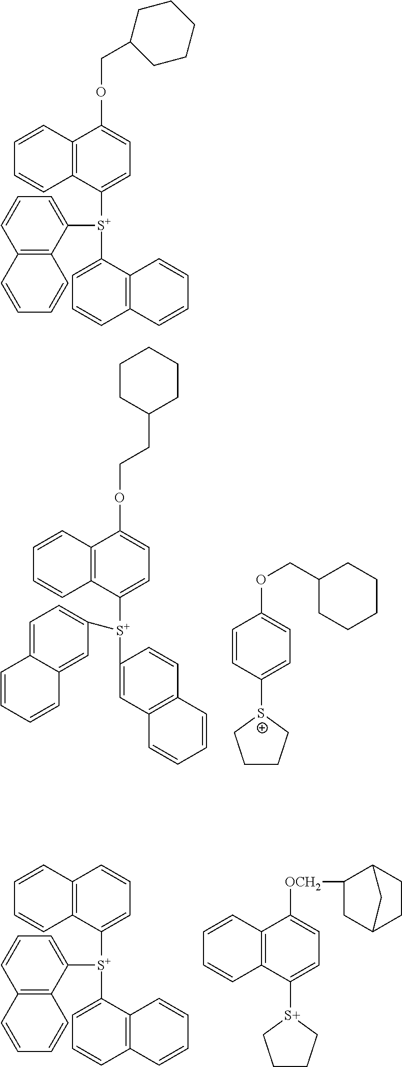

Next, General Formulae (ZII) and (ZIII) will be described.

In General Formulae (ZII) and (ZIII),

R₂₀₄ to R₂₀₇ each independently represent an aryl group, an alkyl group, or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group having a heterocyclic structure containing an oxygen atom, a nitrogen atom, a sulfur atom, or the like. Examples of the skeleton of the aryl group having a heterocyclic structure include pyrrole, furan, thiophene, indole, benzofuran, and benzothiophene.

Preferred examples of the alkyl group and the cycloalkyl group with respect to R₂₀₄ to R₂₀₇ include a linear or branched alkyl group having 1 to 10 carbon atoms (for example, a methyl group, an ethyl group, a propyl group, a butyl group, and a pentyl group) and a cycloalkyl group having 3 to 10 carbon atoms (for example, a cyclopentyl group, a cyclohexyl group, and a norbornyl group).

The aryl group, the alkyl group, and the cycloalkyl group of R₂₀₄ to R₂₀₇ may have a substituent, and examples of the substituent which may be contained in the aryl group, the alkyl group, and the cycloalkyl group of each of R₂₀₄ to R₂₀₇ include an alkyl group (for example, an alkyl group having 1 to 15 carbon atoms), a cycloalkyl group (for example, a cycloalkyl group having 3 to 15 carbon atoms), an aryl group (for example, an aryl group having 6 to 15 carbon atoms), an alkoxy group (for example, an alkoxy group having 1 to 15 carbon atoms), a halogen atom, a hydroxyl group, and a phenylthio group.

Z⁻ represents a non-nucleophilic anion, and examples thereof include the same ones as the non-nucleophilic anions of Z⁻ in General Formula (ZI).

Other examples of the acid generator include compounds represented by General Formulae (ZIV), (ZV), and (ZVI).

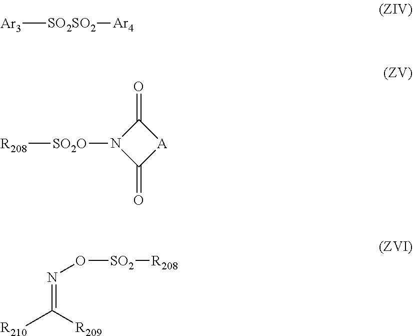

In General Formulae (ZIV) to (ZVI),

Ar₃ and Ar₄ each independently represent an aryl group.

R₂₀₈, R₂₀₉, and R₂₁₀ each independently represent an alkyl group, a cycloalkyl group, or an aryl group.

A represents an alkylene group, an alkenylene group, or an arylene group.

Specific examples of the aryl group of each of Ar₃, Ar₄, R₂₀₈, R₂₀₉, and R₂₁₀ include the same ones as the specific examples of the aryl group of each of R₂₀₁, R₂₀₂, and R₂₀₃ in General Formula (ZI-1).

Specific examples of the alkyl group and the cycloalkyl group of R₂₀₈, R₂₀₉, and R₂₁₀ include the same ones as the specific examples of the alkyl group and the cycloalkyl group of each of R₂₀₁, R₂₀₂, and R₂₀₃ in the compound (ZI-2).

Examples of the alkylene group of A include an alkylene group having 1 to 12 carbon atoms (for example, a methylene group, an ethylene group, a propylene group, an isopropylene group, a butylene group, and an isobutylene group); examples of the alkenylene group of A include an alkenylene group having 2 to 12 carbon atoms (for example, an ethenylene group, a propenylene group, and a butenylene group); and examples of the arylene group of A include an arylene group having 6 to 10 carbon atoms (for example, a phenylene group, a tolylene group, and a naphthylene group).

Among the acid generators, the compounds represented by General Formulae (ZI) to (ZIII) are more preferable.

Furthermore, the acid generator is preferably a compound that generates an acid having one sulfonic acid group or imido group, more preferably a compound that generates a monovalent perfluoroalkanesulfonic acid, a compound that generates an aromatic sulfonic acid substituted with a monovalent fluorine atom or a group containing a fluorine atom, or a compound that generates an imide acid substituted with a monovalent fluorine atom or a group containing a fluorine atom, and still more preferably a sulfonium salt of a fluorine-substituted alkanesulfonic acid, a fluorine-substituted benzenesulfonic acid, a fluorine-substituted imide acid, or a fluorine-substituted methide acid. The acid generator that can be used is particularly preferably a fluorine-substituted alkanesulfonic acid, a fluorine-substituted benzenesulfonic acid, or a fluorine-substituted imide acid, in which the pKa of an acid thus generated is -1 or less, and thus, the sensitivity is improved.

Among the acid generators, particularly preferred examples thereof are shown below.

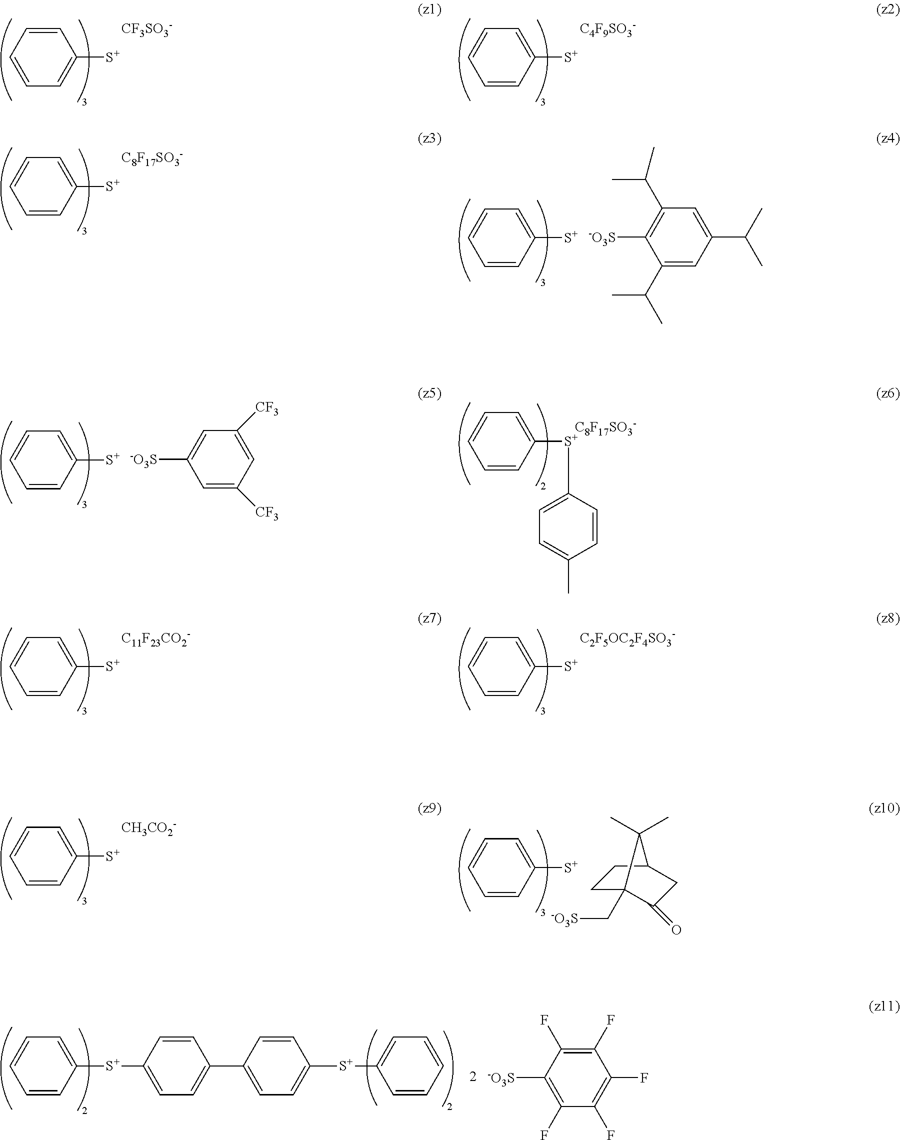

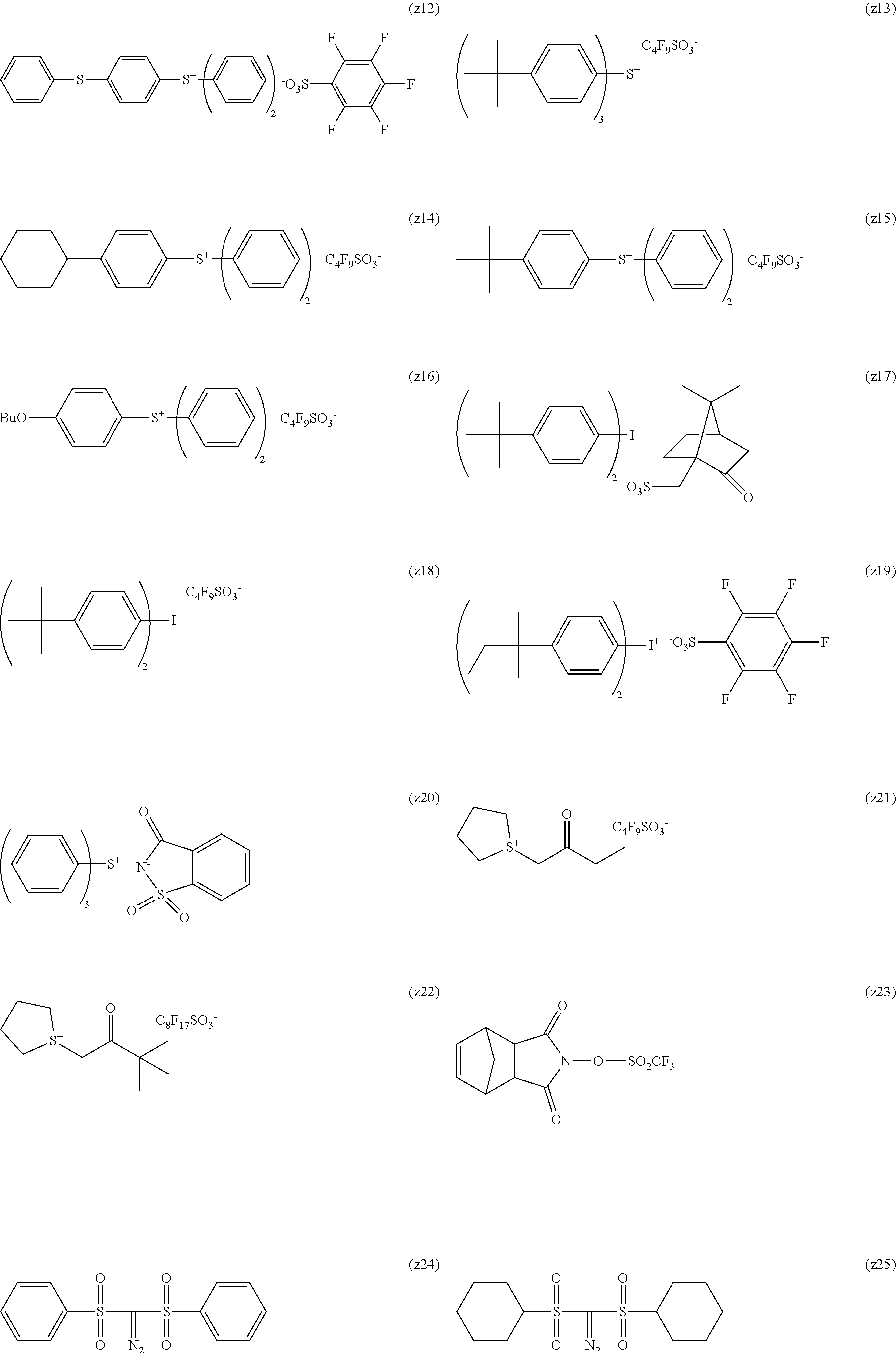

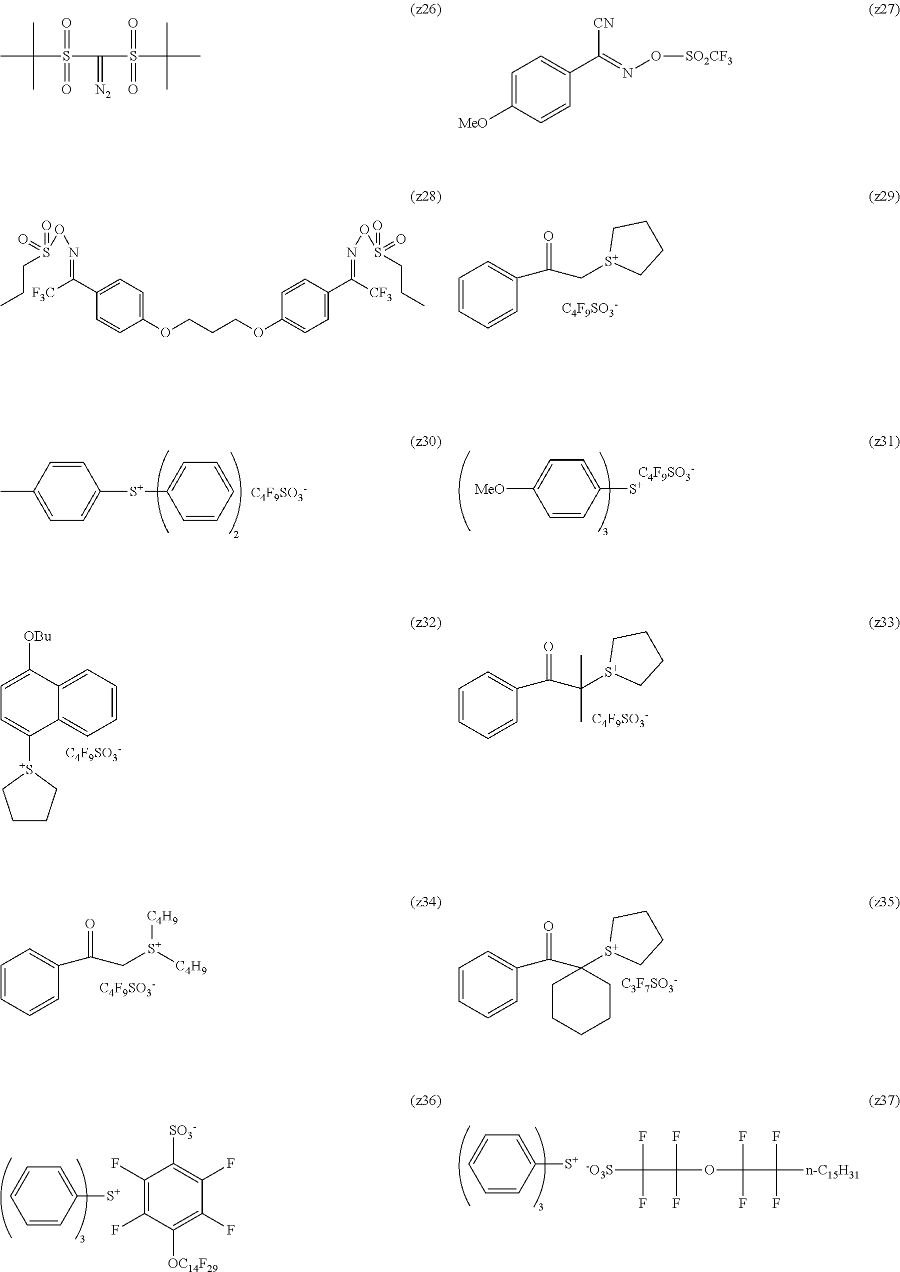

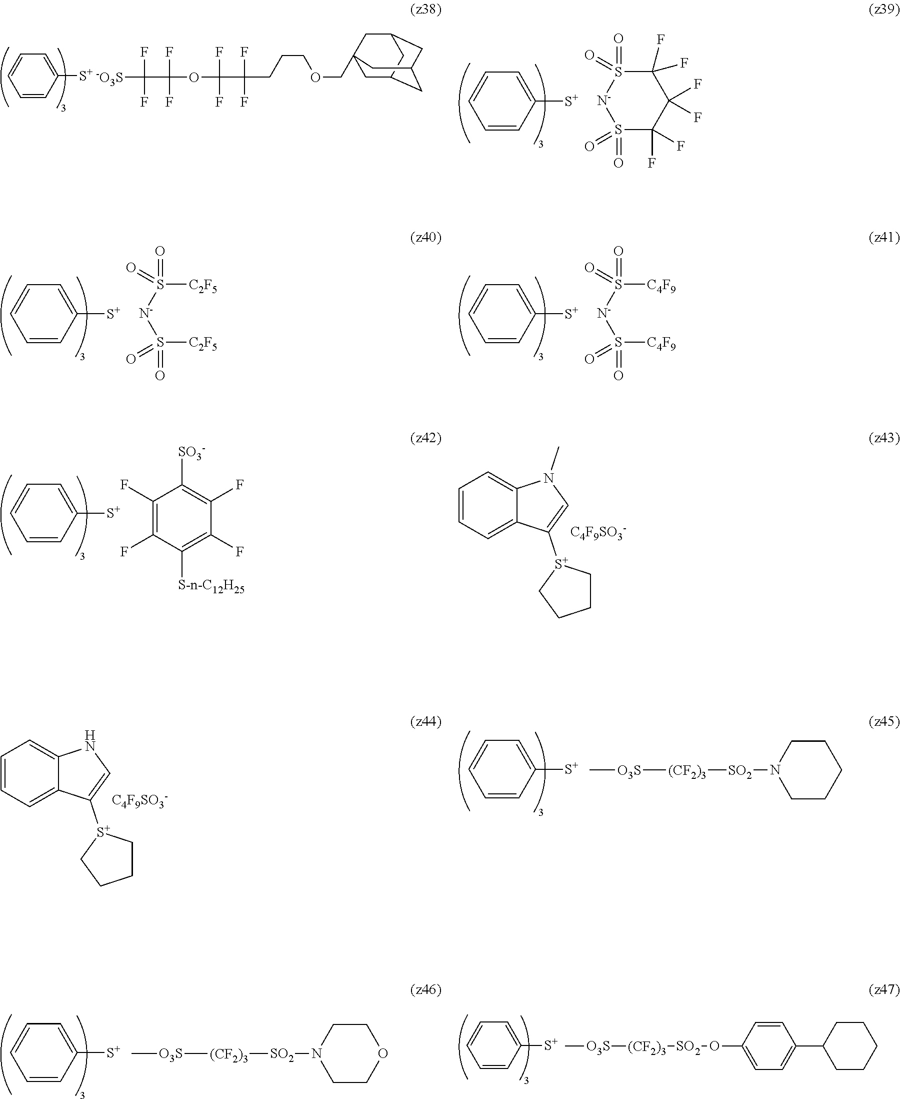

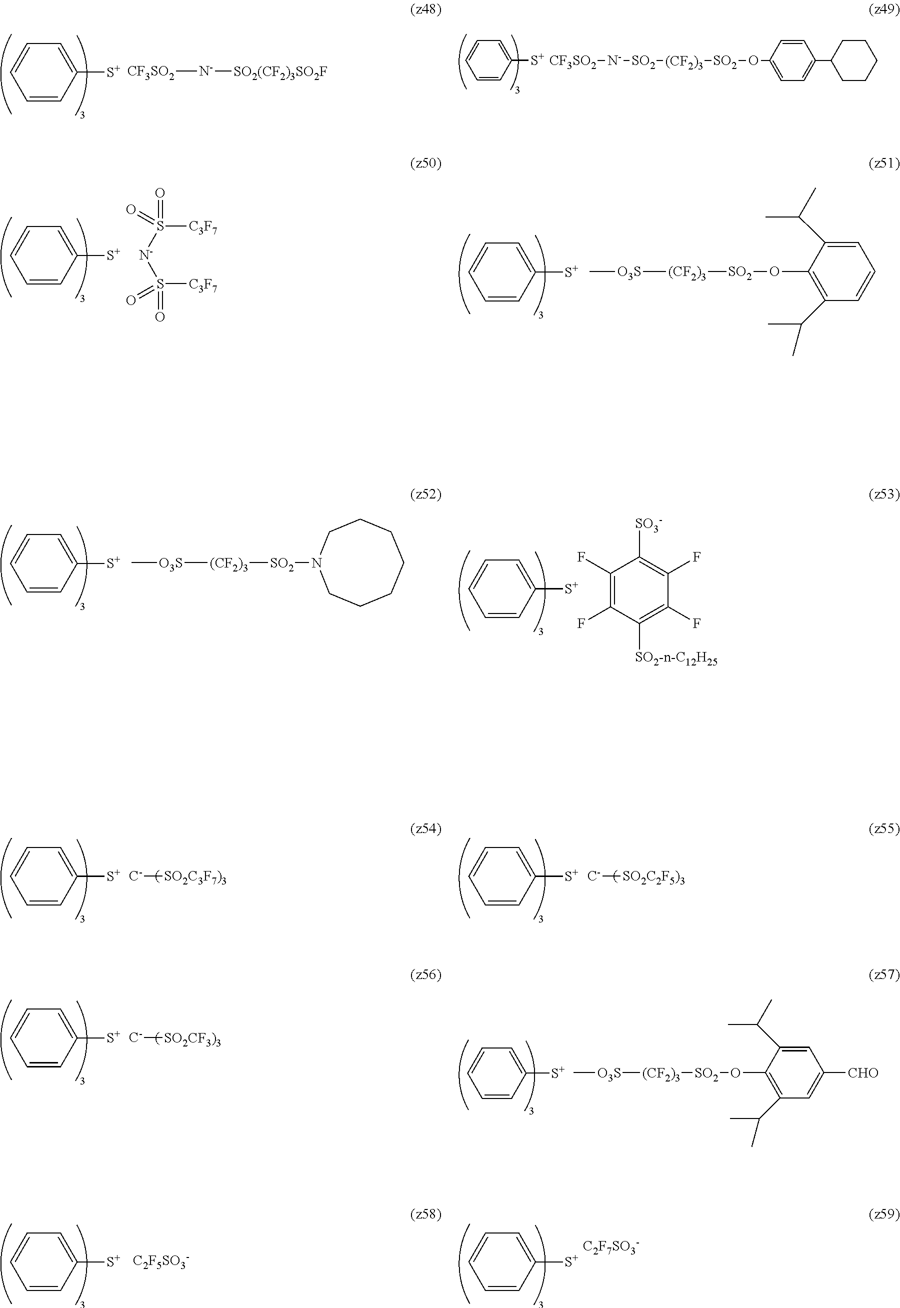

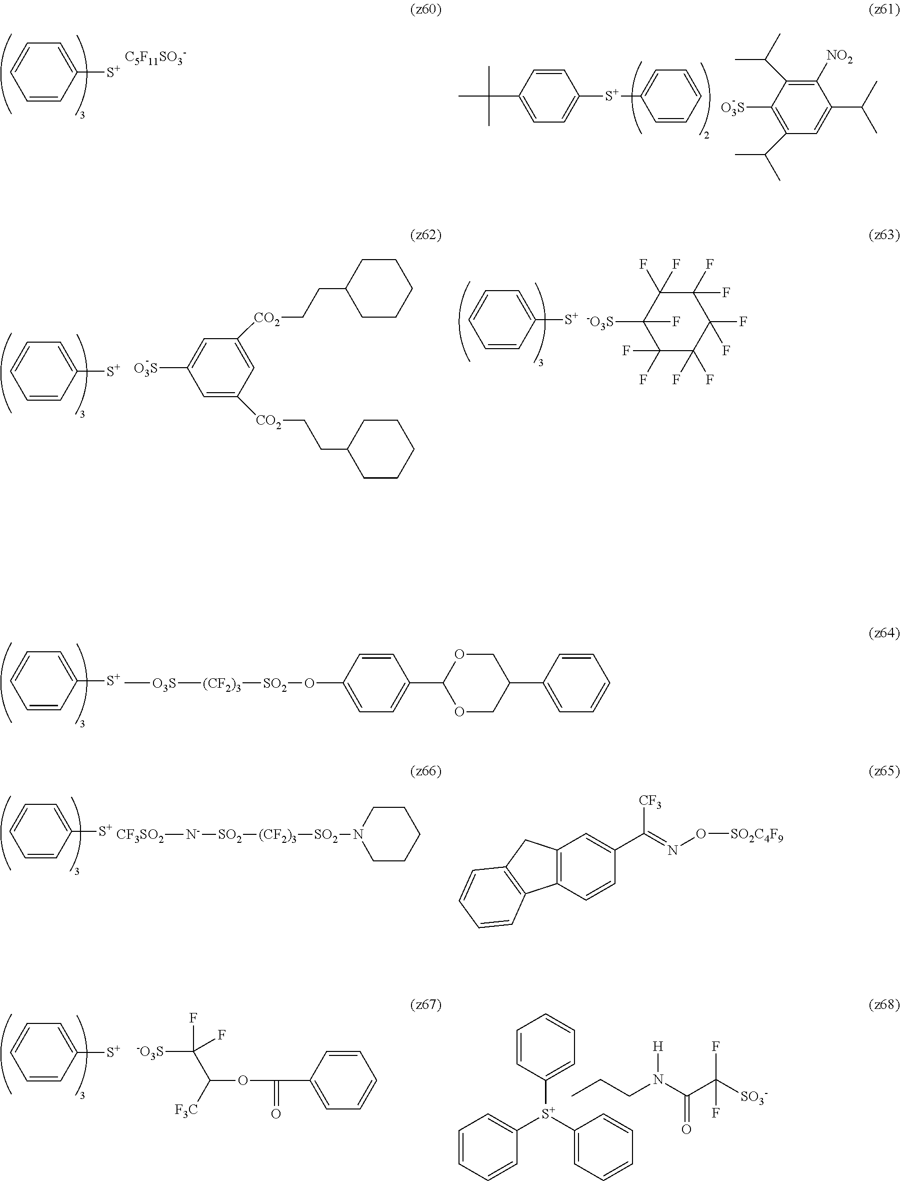

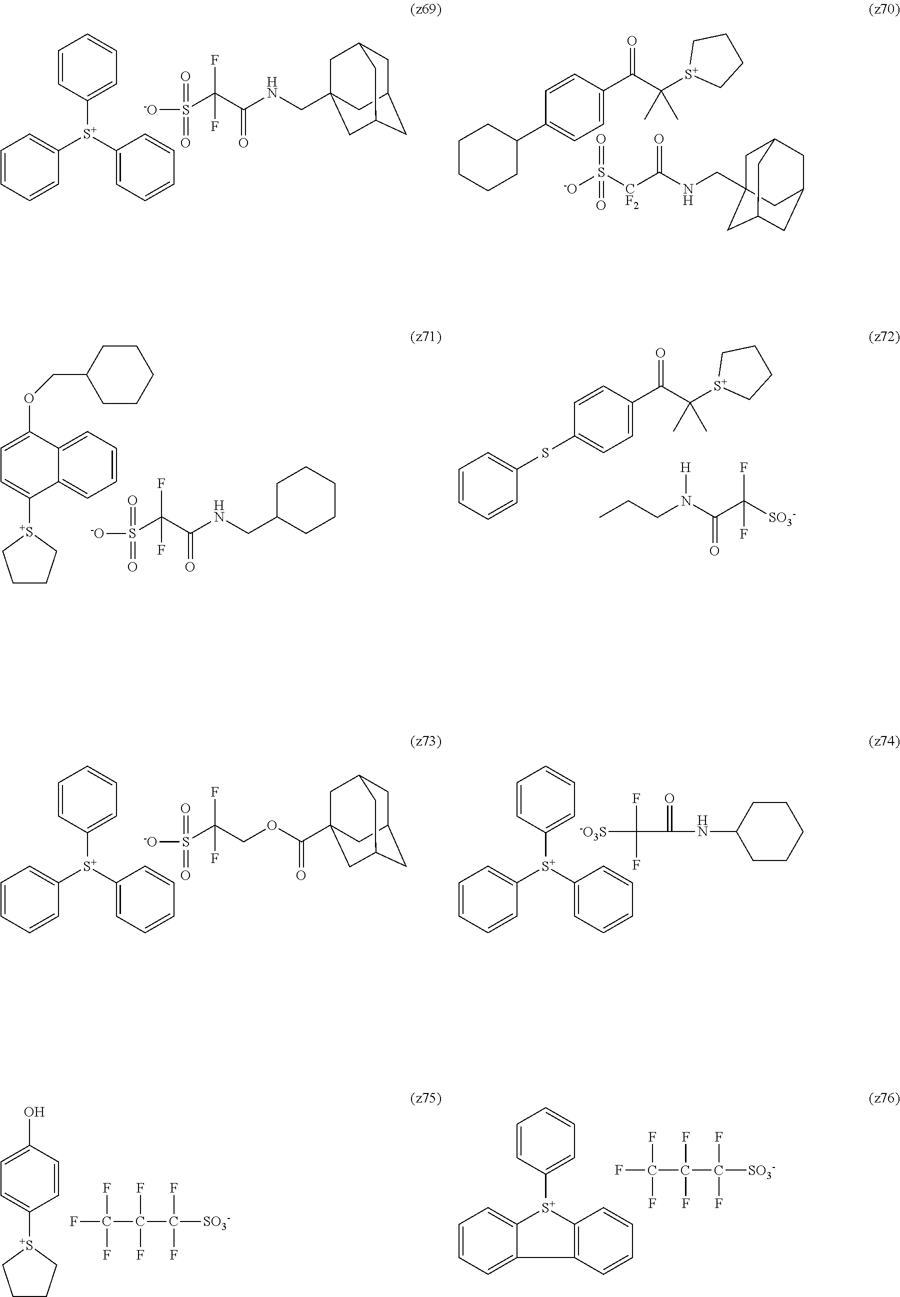

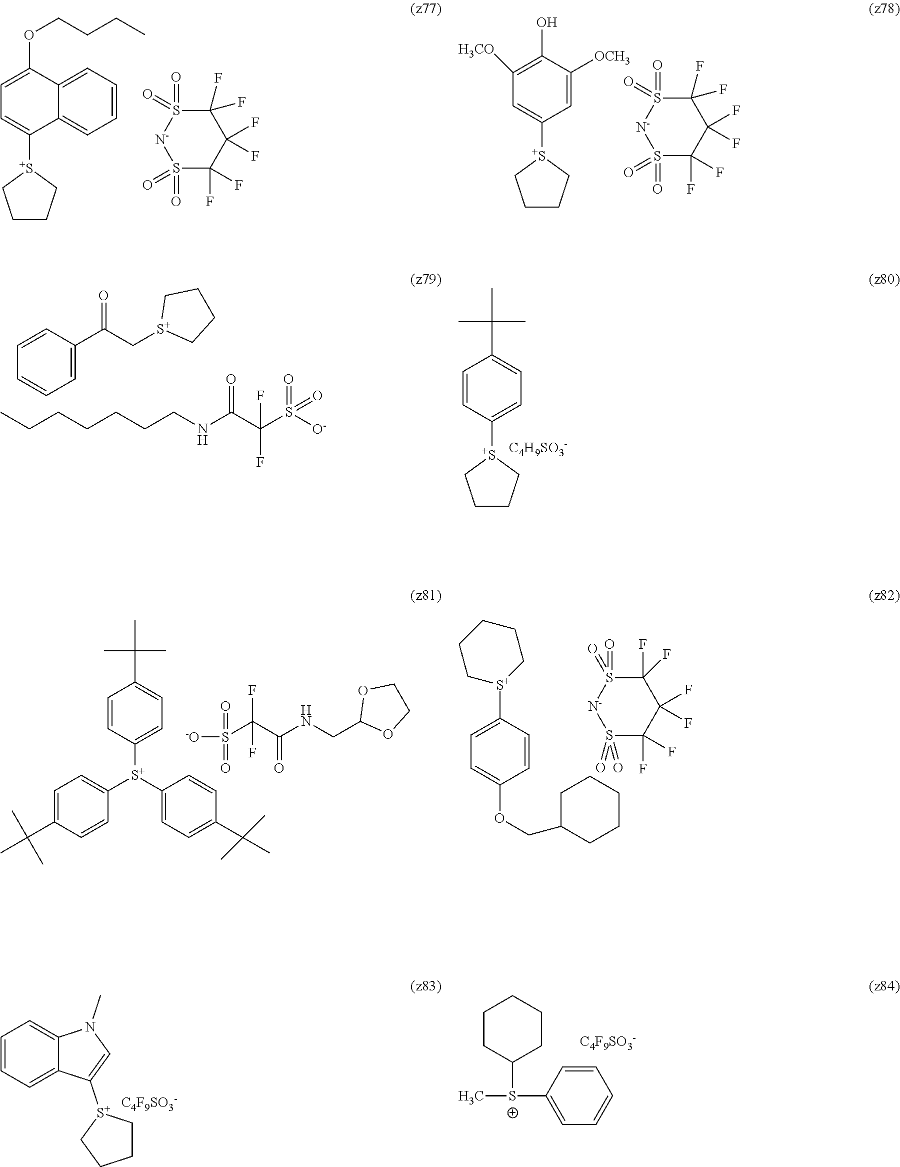

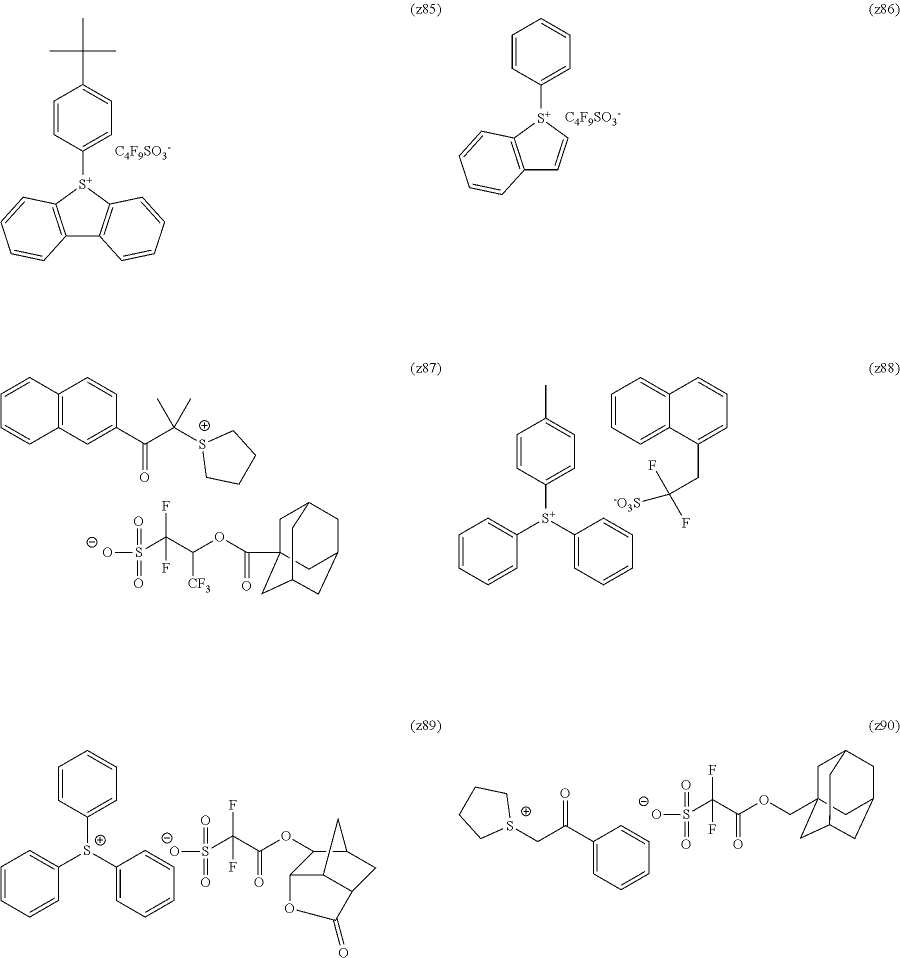

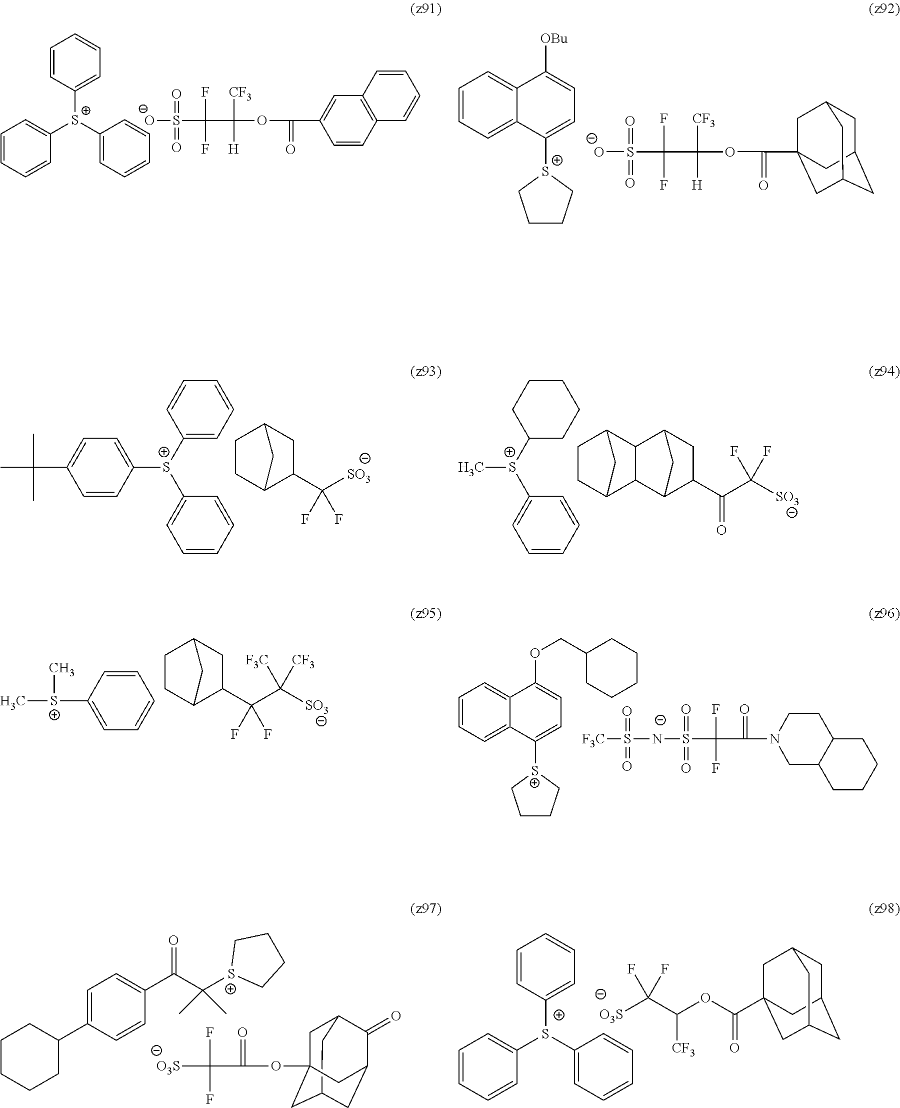

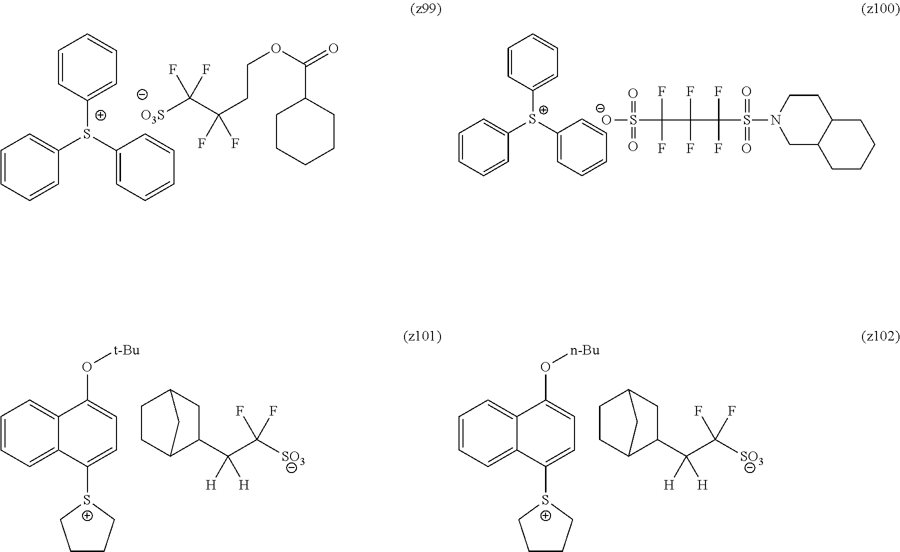

The acid generator can be synthesized by a known method, and can be synthesized in accordance with, for example, the method described in JP2007-161707A.

The acid generator may be used singly or in combination of two or more kinds thereof.

The content of the compound that generates an acid upon irradiation with actinic rays or radiation (excluding a case where the compound is represented by General Formula (ZI-3) or (ZI-4)) in the composition is preferably 0.1% to 30% by mass, more preferably 0.5% to 25% by mass, still more preferably 3% to 20% by mass, and particularly preferably 3% to 15% by mass, with respect to the total solid content of the actinic ray-sensitive or radiation-sensitive composition.

In addition, in a case where the acid generator is represented by General Formula (ZI-3) or (ZI-4), the content thereof is preferably 5% to 35% by mass, more preferably 8% to 30% by mass, still more preferably 9% to 30% by mass, and particularly preferably 9% to 25% by mass, with respect to the total solid content of the composition.

<Hydrophobic Resin (C)>

The composition of the embodiment of the present invention may contain a hydrophobic resin. Further, the hydrophobic resin is preferably different from the resin (A).

Although the hydrophobic resin is preferably designed to be unevenly distributed on an interface as described above, it does not need to have a hydrophilic group in its molecule as different from the surfactant, and does not need to contribute to uniform mixing of polar/nonpolar materials.

Examples of the effect of addition of the hydrophobic resin include suppression of out gas.

The hydrophobic resin preferably has any one of a “fluorine atom”, a “silicon atom”, or a “CH₃ partial structure which is contained in a side chain moiety of a resin” from the viewpoint of uneven distribution on the film surface layer, and more preferably has two or more kinds.

In a case where hydrophobic resin includes a fluorine atom and/or a silicon atom, the fluorine atom and/or the silicon atom in the hydrophobic resin may be contained in the main chain or the side chain of the resin.

In a case where the hydrophobic resin includes a fluorine atom, it is preferably a resin having an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

The aryl group having a fluorine atom is an aryl group such as a phenyl group and a naphthyl group, in which at least one hydrogen atom is substituted with a fluorine atom, and may further have a substituent other than a fluorine atom.

Preferred examples of the alkyl group having a fluorine atom, the cycloalkyl group having a fluorine atom, and the aryl group having a fluorine atom include groups represented by General Formulae (F2) to (F4), but the present invention is not limited thereto.

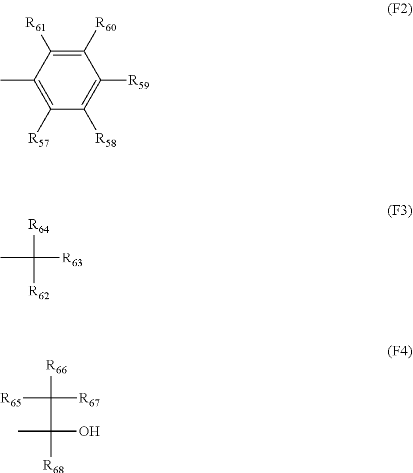

In General Formulae (F2) to (F4),

R₅₇ to R₆₈ each independently represent a hydrogen atom, a fluorine atom, or an (linear or branched) alkyl group, a provided that at least one of R₅₇, . . . , or R₆₁, at least one of R₆₂, . . . , or R₆₄, and at least one of R₆₅, . . . , or R₆₈ each independently represent a fluorine atom or an alkyl group (preferably having 1 to 4 carbon atoms) in which at least one hydrogen atom is substituted with a fluorine atom.

It is preferable that all of R₅₇ to R₆₁, and R₆₅ to R₆₇ are fluorine atoms. R₆₂, R₆₃, and R₆₈ are each preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be bonded to each other to form a ring.

Specific examples of the group represented by General Formula (F2) include a p-fluorophenyl group, a pentafluorophenyl group, and a 3,5-di(trifluoromethyl)phenyl group.

Specific examples of the group represented by General Formula (F3) include those exemplified in [0500] of US2012/0251948A1.

Specific examples of the group represented by General Formula (F4) include —C(CF₃)₂OH, —C(C₂F₅)₂OH, —C(CF₃)(CH₃)OH, and —CH(CF₃)OH, with —C(CF₃)₂OH being preferable.

The partial structure including a fluorine atom may be directly bonded to a main chain, or bonded to a main chain via a group selected from the group consisting of an alkylene group, a phenylene group, an ether bond, a thioether bond, a carbonyl group, an ester bond, an amide bond, a urethane bond, and a ureylene bond, or a group formed by combining two or more of these groups.

The hydrophobic resin may contain a silicon atom. The hydrophobic resin is preferably a resin having an alkylsilyl structure (preferably a trialkylsilyl group) or a cyclic siloxane structure as the partial structure having a silicon atom.

Examples of the alkylsilyl structure or the cyclic siloxane structure include the partial structures described in paragraphs <0304> to <0307> of JP2013-178370A.

Examples of the repeating unit having a fluorine atom or a silicon atom include those exemplified in [0519] of US2012/0251948A1.

Moreover, it is also preferable that the hydrophobic resin includes a CH₃ partial structure in the side chain moiety as described above.

Here, the CH₃ partial structure contained in the side chain moiety in the hydrophobic resin includes a CH₃ partial structure contained in an ethyl group, a propyl group, and the like.

On the other hand, a methyl group bonded directly to the main chain of the hydrophobic resin (for example, an a-methyl group in the repeating unit having a methacrylic acid structure) makes only a small contribution of uneven distribution to the surface of the hydrophobic resin due to the effect of the main chain, and it is therefore not included in the CH₃ partial structure.

More specifically, in a case where the hydrophobic resin includes a repeating unit derived from a monomer having a polymerizable moiety with a carbon-carbon double bond, such as a repeating unit represented by General Formula (M), and in addition, R₁₁ to R₁₄ are each CH₃ “itself”, such the CH₃ is not included in the CH₃ partial structure contained in the side chain moiety in the present invention.

On the other hand, a CH₃ partial structure which is present via a certain atom from a C-C main chain corresponds to the CH₃ partial structure in the present invention. For example, in a case where R₁₁ is an ethyl group (CH₂CH₃), the hydrophobic resin has “one” CH₃ partial structure in the present invention.

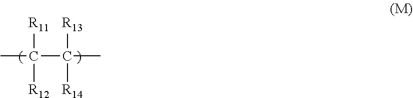

In General Formula (M),

R₁₁ to R₁₄ each independently represent a side chain moiety.

Examples of each of R₁₁ to R₁₄ in the side chain moiety include a hydrogen atom and a monovalent organic group.

Examples of the monovalent organic group for each of R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, each of which may further have a substituent.

The hydrophobic resin is preferably a resin including a repeating unit having the CH₃ partial structure in the side chain moiety thereof. Further, the hydrophobic resin more preferably has, as such a repeating unit, at least one repeating unit (x) selected from a repeating unit represented by General Formula (II) or a repeating unit represented by General Formula (III).

Hereinafter, the repeating unit represented by General Formula (II) will be described in detail.

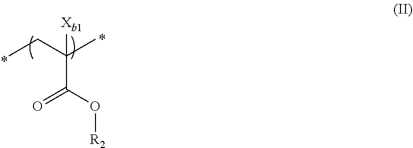

In General Formula (II), X_{b1} represents a hydrogen atom, an alkyl group, a cyano group, or a halogen atom, and R₂ represents an organic group which has one or more CH₃ partial structures and is stable against an acid. Here, it is preferable that the organic group which is stable against an acid is more specifically an organic group not having the “acid-decomposable group” described in the resin (A).

The alkyl group of X_{b1} is preferably an alkyl group having 1 to 4 carbon atoms, and examples thereof include a methyl group, an ethyl group, a propyl group, a hydroxymethyl group, and a trifluoromethyl group, with the methyl group being preferable.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ partial structures. Each of the cycloalkyl group, the alkenyl group, the cycloalkenyl group, the aryl group and the aralkyl group may further have an alkyl group as a substituent.

R₂ is preferably an alkyl group or an alkyl-substituted cycloalkyl group, each of which has one or more CH₃ partial structures.

The number of the CH₃ partial structures contained in the organic group which has one or more CH₃ partial structures and is stable against an acid as R₂ is preferably from 2 to 10, and more preferably from 2 to 8.

Specific preferred examples of the repeating unit represented by General Formula (II) are set forth below, but the present invention is not limited thereto.

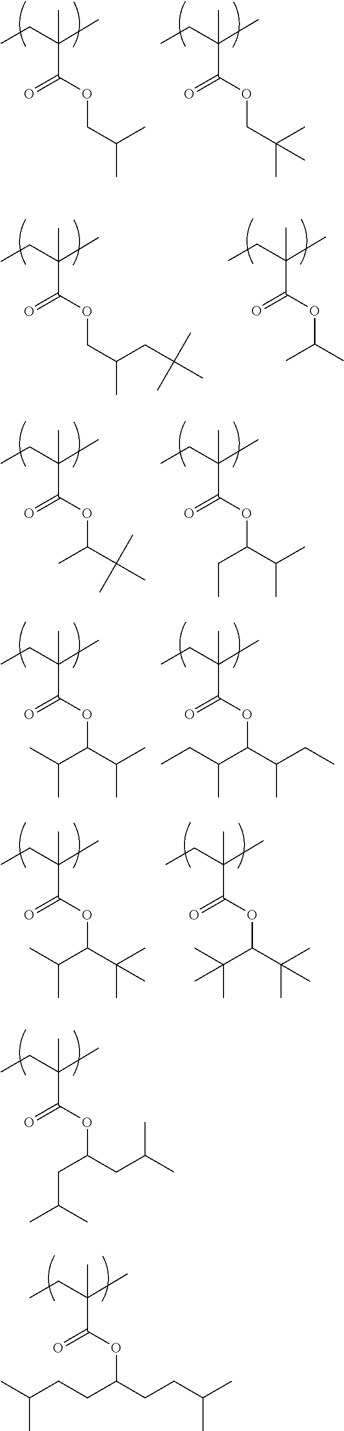

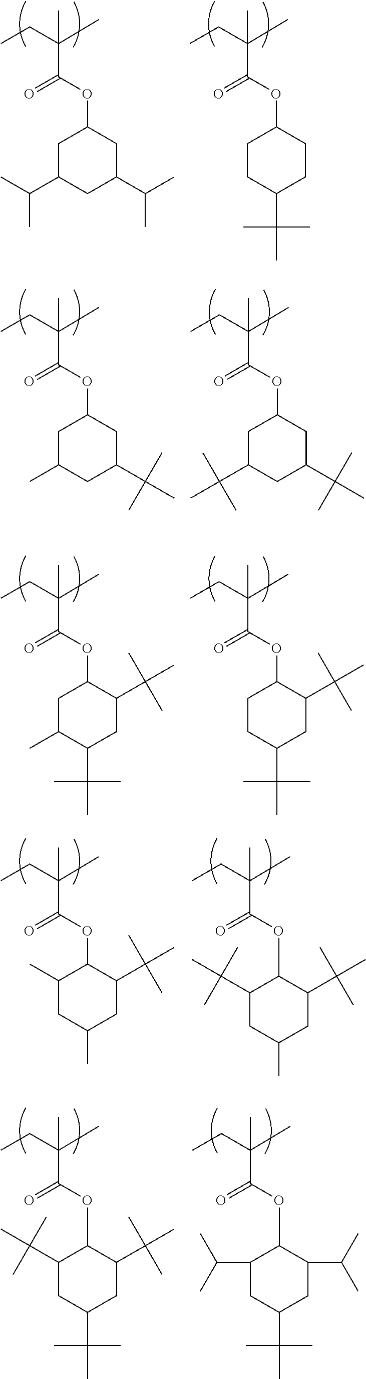

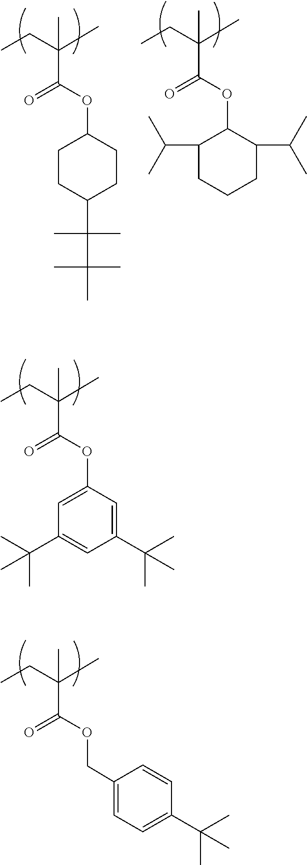

The repeating unit represented by General Formula (II) is preferably a repeating unit which is stable against an acid (non-acid-decomposable), and specifically, it is preferably a repeating unit not having a group capable of decomposing by the action of an acid to generate a polar group.

Hereinafter, the repeating unit represented by General Formula (III) will be described in detail.

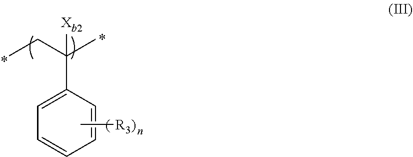

In General Formula (III), X_{b2} represents a hydrogen atom, an alkyl group, a cyano group, or a halogen atom, R₃ represents an organic group which has one or more CH₃ partial structures and is stable against an acid, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, and a trifluoromethyl group, but a hydrogen atom is preferable.

X_{b2} is preferably a hydrogen atom.

Since R₃ is an organic group stable against an acid, more specifically, R₃ is preferably an organic group which does not have the “acid-decomposable group” described for the resin (A).

Examples of R₃ include an alkyl group having one or more CH₃ partial structures.

The number of the CH₃ partial structures contained in the organic group which has one or more CH₃ partial structures and is stable against an acid as R₃ is preferably from 1 to 10, more preferably from 1 to 8, and still more preferably from 1 to 4.

n represents an integer of 1 to 5, more preferably 1 to 3, and still more preferably 1 or 2.

Specific preferred examples of the repeating unit represented by General Formula (III) include the following repeating units, but the present invention is not limited thereto.

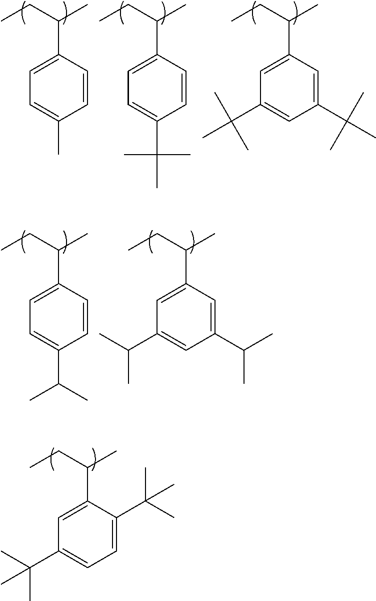

The repeating unit represented by General Formula (III) is preferably a repeating unit which is stable against an acid (non-acid-decomposable), and specifically, it is preferably a repeating unit which does not have a group capable of decomposing by the action of an acid to generate a polar group.

In a case where the hydrophobic resin includes a CH₃ partial structure in the side chain moiety thereof, and in particular, it has neither a fluorine atom nor a silicon atom, the content of at least one repeating unit (x) of the repeating unit represented by General Formula (II) or the repeating unit represented by General Formula (III) is preferably 90% by mole or more, and more preferably 95% by mole or more, with respect to all the repeating units of the hydrophobic resin. Further, the content is usually 100% by mole or less with respect to all the repeating units of the hydrophobic resin.

By incorporating at least one repeating unit (x) of the repeating unit represented by General Formula (II) or the repeating unit represented by General Formula (III) in a proportion of 90% by mole or more with respect to all the repeating units of the hydrophobic resin into the hydrophobic resin, the surface free energy of the hydrophobic resin is increased. As a result, it is difficult for the hydrophobic resin to be unevenly distributed on the surface of the resist film and the static/dynamic contact angle of the resist film with respect to water can be securely increased, thereby enhancing the immersion liquid tracking properties.

In addition, in a case where the hydrophobic resin contains (i) a fluorine atom and/or a silicon atom or (ii) a CH₃ partial structure in the side chain moiety, the hydrophobic resin may have at least one group selected from the following groups (x) to (z):

(x) an acid group,

(y) a group having a lactone structure, an acid anhydride group, or an acid imido group, and

(z) a group capable of decomposing by the action of an acid.

Examples of the acid group (x) include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bi s(alkylcarbonyl)methylene group, a bis(alkylcarbonyl)imido group, a bis(alkylsulfonyl)methylene group, a bis(alkylsulfonyl)imido group, a tris(alkycarbonyl)methylene group, and a tris(alkylsulfonyl)methylene group.

Preferred examples of the acid group include a fluorinated alcohol group (preferably a hexafluoroisopropanol group), a sulfonimido group, and a bis(alkylcarbonyl)methylene group.

Examples of the repeating unit having an acid group (x) include a repeating unit in which the acid group is directly bonded to the main chain of the resin, such as a repeating unit by an acrylic acid or a methacrylic acid, and a repeating unit in which the acid group is bonded to the main chain of the resin through a linking group, and the acid group may also be introduced into the polymer chain terminal by using a polymerization initiator or chain transfer agent containing an acid group during the polymerization. All of these cases are preferable. The repeating unit having an acid group (x) may have at least one of a fluorine atom or a silicon atom.

The content of the repeating units having an acid group (x) is preferably 1% to 50% by mole, more preferably 3% to 35% by mole, and still more preferably 5% to 20% by mole, with respect to all the repeating units in the hydrophobic resin.

Specific examples of the repeating unit having an acid group (x) are set forth below, but the present invention is not limited thereto. In the formulae, Rx represents a hydrogen atom, CH₃, CF₃, or CH₂OH.

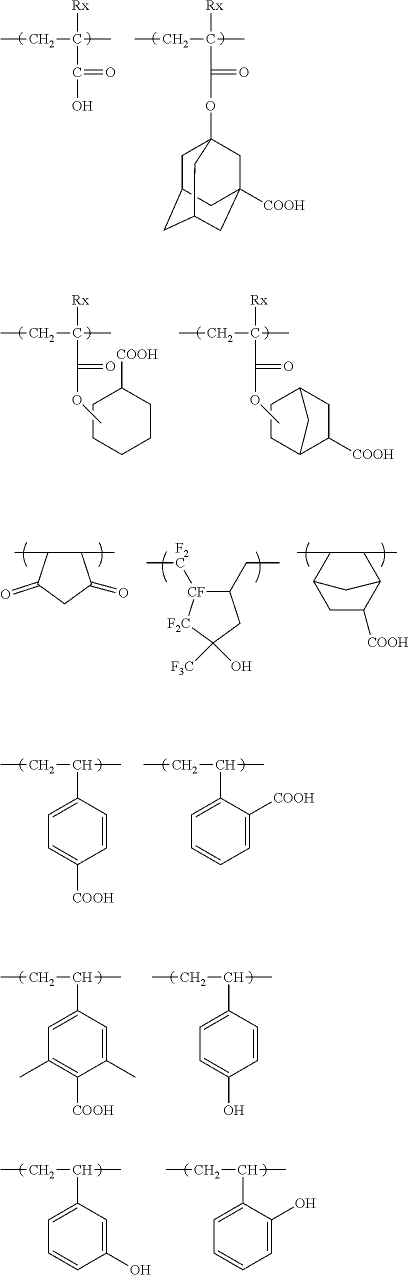

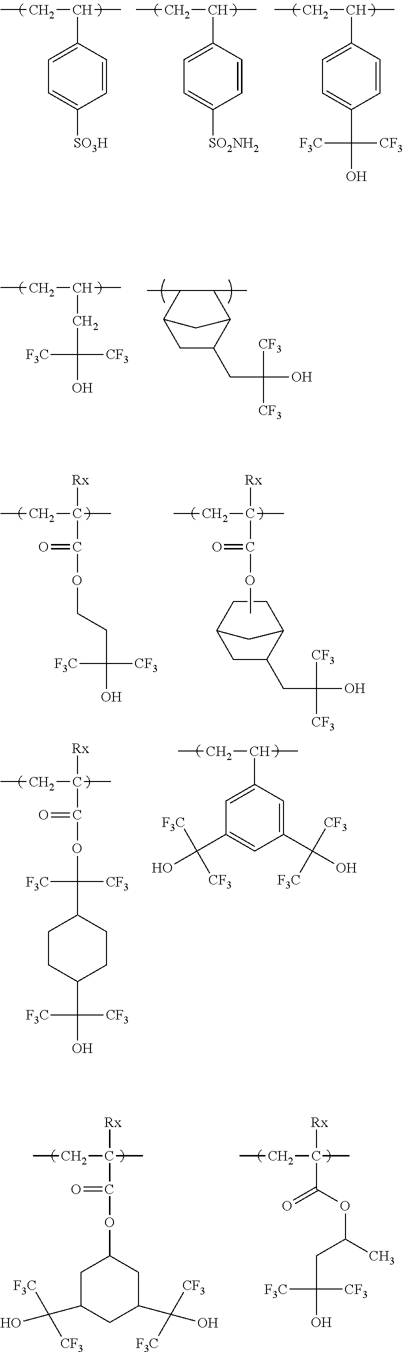

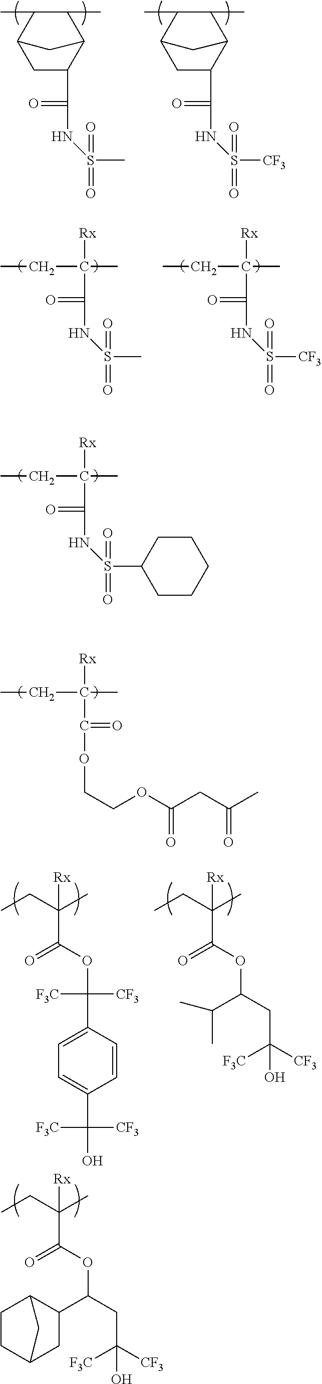

As the group having a lactone structure, the acid anhydride group, or the acid imido group (y), a group having a lactone structure is particularly preferable.

The repeating unit including the group is, for example, a repeating unit in which the group is directly bonded to the main chain of the resin, such as a repeating unit by an acrylic ester or a methacrylic ester. This repeating unit may be a repeating unit in which the group is bonded to the main chain of the resin through a linking group. Alternatively this repeating unit may be introduced into the terminal of the resin by using a polymerization initiator or chain transfer agent containing the group during the polymerization.

Examples of the repeating unit containing a group having a lactone structure include the same ones as the repeating unit having a lactone structure as described above for the resin (A).

The content of the repeating units having a group having a lactone structure, an acid anhydride group, or an acid imido group is preferably 1% to 100% by mole, more preferably 3% to 98% by mole, and still more preferably 5% to 95% by mole, with respect to all the repeating units in the hydrophobic resin.

With respect to the hydrophobic resin, examples of the repeating unit having a group (z) that decomposes by the action of an acid include the same ones as the repeating units having an acid-decomposable group, as exemplified in the resin (A). The repeating unit having a group (z) that decomposes by the action of an acid may have at least one of a fluorine atom or a silicon atom. With respect to the hydrophobic resin, the content of the repeating units having a group (z) that decomposes by the action of an acid is preferably 1% to 80% by mole, more preferably 10% to 80% by mole, and still more preferably 20% to 60% by mole, with respect to all the repeating units in the hydrophobic resin.

In a case where the hydrophobic resin has fluorine atoms, the content of the fluorine atoms is preferably 5% to 80% by mass, and more preferably 10% to 80% by mass, with respect to the weight-average molecular weight of the hydrophobic resin. In addition, the repeating unit including a fluorine atom is preferably in the amount of 10% to 100% by mole, and more preferably in the amount of 30% to 100% by mole, with respect to all the repeating units included in the hydrophobic resin.

In a case where the hydrophobic resin has a silicon atom, the content of the silicon atom is preferably 2% to 50% by mass, and more preferably 2% to 30% by mass, with respect to the weight-average molecular weight of the hydrophobic resin. In addition, the repeating unit including a silicon atom is preferably in the amount of 10% to 100% by mole, and more preferably in the amount of 20% to 100% by mole, with respect to all the repeating units in the hydrophobic resin.

On the other hand, in particular, in a case where the hydrophobic resin includes a CH₃ partial structure in the side chain moiety thereof, it is also preferable that the hydrophobic resin has a form substantially not having any one of fluorine atoms or silicon atoms. In this case, specifically, the content of the repeating unit having a fluorine atom or a silicon atom is preferably 5% by mole or less, more preferably 3% by mole or less, and still more preferably 1% by mole or less, with respect to all the repeating units in the hydrophobic resin, and ideally, the content is 0% by mole, that is, the hydrophobic resin does not contain a fluorine atom and a silicon atom. In addition, it is preferable that the hydrophobic resin is substantially composed only of repeating units which are composed only of atoms selected from a carbon atom, an oxygen atom, a hydrogen atom, a nitrogen atom, and a sulfur atom. More specifically, the proportion of the repeating units which are composed only of atoms selected from a carbon atom, an oxygen atom, a hydrogen atom, a nitrogen atom, and a sulfur atom is preferably 95% by mole or more, more preferably 97% by mole or more, still more preferably 99% by mole or more, and ideally 100% by mole, in all the repeating units in the hydrophobic resin.

The weight-average molecular weight in terms of standard polystyrene, of the hydrophobic resin, is preferably 1,000 to 100,000, more preferably 1,000 to 50,000, and still more preferably 2,000 to 15,000.

Furthermore, the hydrophobic resin may be used singly or in combination of a plurality of kinds thereof.

The content of the hydrophobic resin in the composition is preferably 0.01% to 10% by mass, more preferably 0.05% to 8% by mass, and still more preferably 0.1% to 7% by mass, with respect to the total solid content of the composition of the embodiment of the present invention.

It is natural that the hydrophobic resin contains a small amount of impurities such as metals, but the amount of residual monomers and oligomer components in the hydrophobic resin is preferably 0.01% to 5% by mass, more preferably 0.01% to 3% by mass, and still more preferably 0.05% to 1% by mass. Thus, a composition having no temporal change in foreign substances in a liquid, sensitivity, and the like is obtained. Further, the molecular weight distribution (Mw/Mn, also referred to as a dispersity) is preferably in a range of 1 to 5, more preferably in a range of 1 to 3, and still more preferably in a range of 1 to 2, in views of a resolution, a resist shape, sidewalls of a resist pattern, roughness, and the like.

As the hydrophobic resin, various commercial products can also be used, or the resin can be synthesized by an ordinary method (for example, radical polymerization). Examples of the general synthesis method include a batch polymerization method in which polymerization is carried out by dissolving monomer species and an initiator in a solvent and heating the solution, a dropwise addition polymerization method in which a solution of monomer species and an initiator is added dropwise to a heating solvent for 1 to 10 hours, with the dropwise addition polymerization method being preferable.

A reaction solvent, a polymerization initiator, reaction conditions (a temperature, a concentration, and the like), and a purification method after the reaction are the same as those described for the resin (A), but in the synthesis of the hydrophobic resin, the concentration of the reaction is preferably 30% to 50% by mass.

<Acid Diffusion Control Agent (D)>

The composition of the embodiment of the present invention preferably contains an acid diffusion control agent (D). The acid diffusion control agent (D) acts as a quencher that inhibits a reaction of the acid-decomposable resin in the unexposed area by excessive generated acids by trapping the acids generated from an acid generator or the like upon exposure. As the acid diffusion control agent (D), a basic compound, a low-molecular-weight compound which has a nitrogen atom and a group that leaves by the action of an acid, a basic compound whose basicity is reduced or lost upon irradiation with actinic rays or radiation, or an onium salt which becomes a relatively weak acid with respect to the acid generator upon irradiation with actinic rays or radiation can be used.

Preferred examples of the basic compound include compounds having structures represented by Formulae (A) to (E).

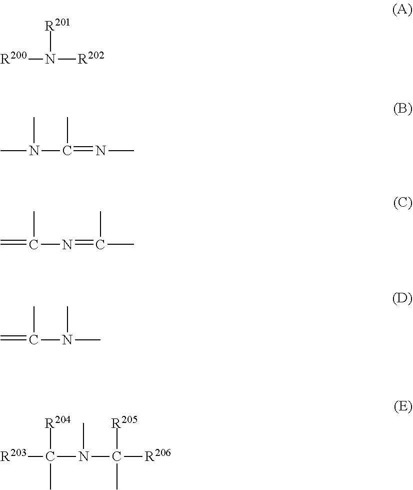

In General Formulae (A) and (E),

R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms), and R²⁰¹ and R²⁰² may be bonded to each other to form a ring.

R²⁰³, R²⁰⁴, R²⁰⁵, and R²⁰⁶ may be the same as or different from each other, and each represent an alkyl group having 1 to 20 carbon atoms.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl groups in General Formulae (A) and (E) are more preferably unsubstituted.

Preferred examples of the compound include guanidine, aminopyrrolidine, pyrazole, pyrazoline, piperazine, aminomorpholine, aminoalkylmorpholine, and piperidine. More preferred examples of the compound include a compound having an imidazole structure, a diazabicyclo structure, an onium hydroxide structure, an onium carboxylate structure, a trialkylamine structure, an aniline structure, or a pyridine structure; an alkylamine derivative having a hydroxyl group and/or an ether bond; and an aniline derivative having a hydroxyl group and/or an ether bond.

Specific preferred examples of the compound include the compounds exemplified in <0379> of US2012/0219913A1.

Preferred examples of the basic compound include an amine compound having a phenoxy group, an ammonium salt compound having a phenoxy group, an amine compound containing a sulfonic ester group, and an ammonium salt compound having a sulfonic ester group.

As the amine compound, a primary, secondary, or tertiary amine compound can be used, and an amine compound in which at least one alkyl group is bonded to a nitrogen atom is preferable. The amine compound is more preferably a tertiary amine compound. Any amine compound is available as long as at least one alkyl group (preferably having 1 to 20 carbon atoms) is bonded to a nitrogen atom, and a cycloalkyl group (preferably having 3 to 20 carbon atoms) or an aryl group (preferably having 6 to 12 carbon atoms) may be bonded to the nitrogen atom, in addition to the alkyl group. The amine compound preferably has an oxygen atom in the alkyl chain to form an oxyalkylene group. The number of the oxyalkylene groups within the molecule is 1 or more, preferably 3 to 9, and more preferably from 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

As the ammonium salt compound, a primary, secondary, tertiary, or quaternary ammonium salt compound can be used, and an ammonium salt compound in which at least one alkyl group is bonded to a nitrogen atom is preferable. Any ammonium salt compound is available as long as at least one alkyl group (preferably having 1 to 20 carbon atoms) is bonded to a nitrogen atom, and a cycloalkyl group (preferably having 3 to 20 carbon atoms) or an aryl group (preferably having 6 to 12 carbon atoms) may be bonded to the nitrogen atom, in addition to the alkyl group. The ammonium salt compound preferably has an oxygen atom in the alkyl chain to form an oxyalkylene group. The number of the oxyalkylene groups within the molecule is 1 or more, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

Examples of the anion of the ammonium salt compound include a halogen atom, sulfonate, borate, and phosphate, and among these, the halogen atom and sulfonate are preferable.

Furthermore, the following compounds are also preferable as the basic compound.

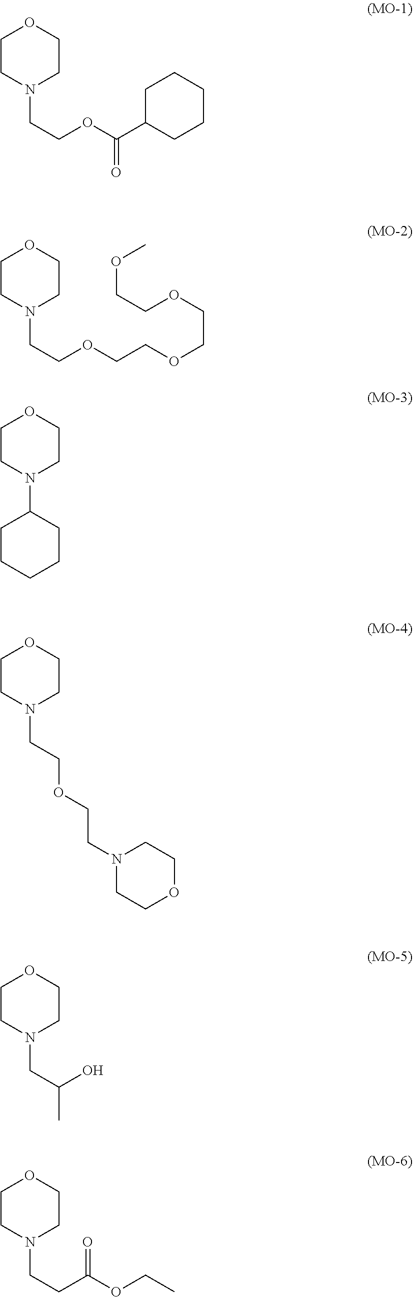

In addition to the compounds as described above, as the basic compound, the compounds described in [0180] to [0225] of JP2011-022560A, [0218] and [0219] of JP2012-137735A, and [0416] to [0438] of WO2011/158687A1, and the like can also be used.

These basic compounds may be used singly or in combination of two or more kinds thereof.

The composition of the embodiment of the present invention may or may not contain a basic compound, but in a case where it contains the basic compound, the content of the basic compound is usually 0.001% to 10% by mass, and preferably 0.01% to 5% by mass, with respect to the solid content of the composition.

The ratio of between the acid generator (a total amount in a case of using plural kinds of the acid generators) and the basic compound to be used in the composition is preferably acid generator/basic compound (molar ratio)=2.5 to 300. That is, the molar ratio is preferably 2.5 or more in a view of sensitivity and resolution, and is preferably 300 or less in a view of suppressing the reduction in resolution due to thickening of the resist pattern with aging after exposure until the heat treatment. The acid generator/basic compound (molar ratio) is more preferably 5.0 to 200, and still more preferably 7.0 to 150.

The low-molecular-weight compound (hereinafter also referred to as a “compound (D-1)”) which has a nitrogen atom and a group that leaves by the action of an acid is preferably an amine derivative having a group that leaves by the action of an acid on a nitrogen atom.

As the group that leaves by the action of an acid, an acetal group, a carbonate group, a carbamate group, a tertiary ester group, a tertiary hydroxyl group, or a hemiaminal ether group is preferable, and a carbamate group or a hemiaminal ether group is particularly preferable.

The molecular weight of the compound (D-1) is preferably 100 to 1,000, more preferably 100 to 700, and particularly preferably 100 to 500.

The compound (D-1) may have a carbamate group having a protecting group on a nitrogen atom. The protecting group constituting the carbamate group can be represented by General Formula (d-1).

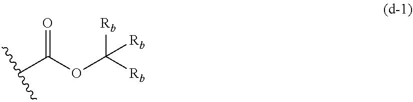

In General Formula (d-1),

R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be bonded to each other to form a ring.

The alkyl group, the cycloalkyl group, the aryl group, or the aralkyl group represented by R_{b} may be substituted with a functional group such as a hydroxyl group, a cyano group, an amino group, a pyrrolidino group, a piperidino group, a morpholino group, and an oxo group, an alkoxy group, or a halogen atom. This is the same as for the alkoxyalkyl group represented by R_{b}.

R_{b} is preferably a linear or branched alkyl group, a cycloalkyl group, or an aryl group, and more preferably a linear or branched alkyl group, or a cycloalkyl group.

Examples of the ring formed by mutual bonding of two R_{b}'s include an alicyclic hydrocarbon group, an aromatic hydrocarbon group, a heterocyclic hydrocarbon group, and derivatives thereof.

Examples of the specific structure of the group represented by General Formula (d-1) include, but are not limited to, the structures disclosed in <0466> of US2012/0135348A1.

It is particularly preferable that the compound (D-1) has a structure represented by General Formula (6).

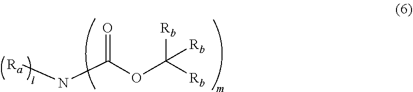

In General Formula (6), Rₐ represents a hydrogen atom, an alkyl group, a cycloalkyl group, an aryl group, or an aralkyl group. In a case where 1 is 2, two Rₐ's may be the same as or different from each other. Two Rₐ's may be bonded to each other to form a heterocycle may be bonded to each other to form, together with a carbon atom to which they are bonded with the nitrogen atom in the formula. The heterocycle may contain a heteroatom other than the nitrogen atom in the formula.

R_{b} has the same meaning as R_{b} in General Formula (d-1), and preferred examples are also the same.

l represents an integer of 0 to 2, and m represents an integer of 1 to 3, satisfying l+m=3.

In General Formula (6), the alkyl group, the cycloalkyl group, the aryl group, and the aralkyl group as Rₐ may be substituted with the same groups as the group mentioned above as a group which may be substituted in the alkyl group, the cycloalkyl group, the aryl group, and the aralkyl group as R_{b}.

Specific examples of the alkyl group, the cycloalkyl group, the aryl group, and the aralkyl group (such the alkyl group, a cycloalkyl group, an aryl group, and aralkyl group may be substituted with the groups as described above) of Rₐ include the same groups as the specific examples as described above with respect to R_{b}.

Specific examples of the particularly preferred compound (D-1) in the present invention include, but are not limited to, the compounds disclosed in paragraph <0475> in US2012/0135348A1.

The compounds represented by General Formula (6) can be synthesized in accordance with JP2007-298569A, JP2009-199021A, and the like.

In the present invention, the compound (D-1) having a group that leaves by the action of an acid on a nitrogen atom may be used singly or in combination of two or more kinds thereof.

The content of the compound (D-1) in the composition of the embodiment of the present invention is preferably 0.001% to 20% by mass, more preferably 0.001% to 10% by mass, and still more preferably 0.01% to 5% by mass, with respect to the total solid content of the composition.

The basic compound whose basicity is reduced or lost upon irradiation with actinic rays or radiation (hereinafter also referred to as a “compound (PA)”) is a compound which has a proton-accepting functional group, and decomposes upon irradiation with actinic rays or radiation to exhibit deterioration in proton-accepting properties, no proton-accepting properties, or a change from the proton-accepting properties to acidic properties.

The proton-accepting functional group refers to a functional group having a group or an electron which is capable of electrostatically interacting with a proton, and for example, means a functional group with a macrocyclic structure, such as a cyclic polyether, or a functional group containing a nitrogen atom having an unshared electron pair not contributing to π-conjugation. The nitrogen atom having an unshared electron pair not contributing to π-conjugation is, for example, a nitrogen atom having a partial structure represented by the following formula.

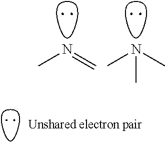

Preferred examples of the partial structure of the proton-accepting functional group include crown ether, azacrown ether, primary to tertiary amines, pyridine, imidazole, and pyrazine structures.

The compound (PA) decomposes upon irradiation with actinic rays or radiation to generate a compound exhibiting deterioration in proton-accepting properties, no proton-accepting properties, or a change from the proton-accepting properties to acidic properties. Here, exhibiting deterioration in proton-accepting properties, no proton-accepting properties, or a change from the proton-accepting properties to acidic properties means a change of proton-accepting properties due to the proton being added to the proton-accepting functional group, and specifically a decrease in the equilibrium constant at chemical equilibrium in a case where a proton adduct is generated from the compound (PA) having the proton-accepting functional group and the proton.

The proton-accepting properties can be confirmed by carrying out pH measurement.

In the present invention, the acid dissociation constant pKa of the compound generated by the decomposition of the compound (PA) upon irradiation with actinic rays or radiation preferably satisfies pKa<−1, more preferably −13<pKa<−1, and still more preferably −13<pKa<−3.

In the present invention, the acid dissociation constant pKa indicates an acid dissociation constant pKa in an aqueous solution, and is described, for example, in Chemical Handbook (II) (Revised 4^{th} Edition, 1993, compiled by the Chemical Society of Japan, Maruzen Company, Ltd.), and a lower value thereof indicates higher acid strength. Specifically, the acid dissociation constant pKa in an aqueous solution may be measured by using an infinite-dilution aqueous solution and measuring the acid dissociation constant at 25° C., or a value based on the Hammett substituent constants and the database of publicly known literature data can also be obtained by computation using the following software package 1. All the values of pKa described in the present specification indicate values determined by computation using this software package.

Software package 1: Advanced Chemistry Development (ACD/Labs) Software V 8.14 for Solaris (1994-2007 ACD/Labs).

The compound (PA) generates a compound represented by General Formula (PA-1), for example, as the proton adduct generated by decomposition upon irradiation with actinic rays or radiation. The compound represented by General Formula (PA-1) is a compound exhibiting deterioration in proton-accepting properties, no proton-accepting properties, or a change from the proton-accepting properties to acidic properties since the compound has a proton-accepting functional group as well as an acidic group, as compared with the compound (PA).

Q-A-(X)ₙ—B—R (PA-1)

In General Formula (PA-1),

Q represents —SO₃H, —CO₂H, or —W₁NHW₂R_{f}, in which R_{f} represents an alkyl group (preferably having 1 to 20 carbon atoms), a cycloalkyl group (preferably having 3 to 20 carbon atoms), or an aryl group (preferably having 6 to 30 carbon atoms), and W₁ and W₂ each independently represent —SO₂— or —CO—.

A represents a single bond or a divalent linking group.

X represents —SO₂— or —CO—.

n represents 0 or 1.

B represents a single bond, an oxygen atom, or —N(Rₓ)R_{y}—, in which Rₓ represents a hydrogen atom or a monovalent organic group, and R_{y} represents a single bond or a divalent organic group, a provided that Rₓ may be bonded to R_{y} to form a ring or may be bonded to R to form a ring.

R represents a monovalent organic group having a proton-accepting functional group.

General Formula (PA-1) will be described in more detail.

The divalent linking group in A is preferably a divalent linking group having 2 to 12 carbon atoms, and examples thereof include an alkylene group and a phenylene group. The divalent linking group is more preferably an alkylene group having at least one fluorine atom, and preferably has 2 to 6 carbon atoms, and more preferably has 2 to 4 carbon atoms. The divalent linking group may have a linking group such as an oxygen atom and a sulfur atom in the alkylene chain. The alkylene group preferably an alkylene group, in particular, in which 30% to 100% by number of the hydrogen atoms are substituted with fluorine atoms, more preferably in which a carbon atom bonded to the Q site has a fluorine atom, still more preferably a perfluoroalkylene group, and particularly preferably a perfluoroethylene group, a perfluoropropylene group, or a perfluorobutylene group.

The monovalent organic group in Rₓ is preferably an organic group having 1 to 30 carbon atoms, and examples thereof include an alkyl group, a cycloalkyl group, an aryl group, an aralkyl group, and an alkenyl group. These groups may further have a substituent.

The alkyl group in Rₓ may have a substituent, is preferably a linear or branched alkyl group having 1 to 20 carbon atoms, and may have an oxygen atom, a sulfur atom, or a nitrogen atom in the alkyl chain.

The cycloalkyl group in Rₓ may have a substituent, is preferably a monocyclic or polycyclic cycloalkyl group having 3 to 20 carbon atoms, and may have an oxygen atom, a sulfur atom, or a nitrogen atom in the ring.

The aryl group in Rₓ may have a sub stituent and is preferably an aryl group having 6 to 14 carbon atoms, and examples thereof include a phenyl group and a naphthyl group.

The aralkyl group in Rₓ may have a sub stituent and is preferably an aralkyl group having 7 to 20 carbon atoms, and examples thereof include a benzyl group and a phenethyl group.

The alkenyl group in Rₓ may have a substituent, may be linear or branched, and is preferably an alkenyl group having 3 to 20 carbon atoms, and examples of such the alkenyl group include a vinyl group, an allyl group, and a styryl group.

In a case where Rₓ further has a substituent, examples of the substituent include a halogen atom, a linear, branched, or cyclic alkyl group, an alkenyl group, an alkynyl group, an aryl group, an acyl group, an alkoxycarbonyl group, an aryloxycarbonyl group, a carbamoyl group, a cyano group, a carboxyl group, a hydroxyl group, an alkoxy group, an aryloxy group, an alkylthio group, an arylthio group, a heterocyclic oxy group, an acyloxy group, an amino group, a nitro group, a hydrazino group, and a heterocyclic group.

Preferred examples of the divalent organic group in R_{y} include an alkylene group.

Examples of the ring structure which may be formed by mutual bonding of Rₓ and R_{y} include a 5- to 10-membered ring, and particularly preferably a 6-membered ring, including a nitrogen atom.

The proton-accepting functional group in R is as described above, and examples thereof include nitrogen-including heterocyclic aromatic structures such as azacrown ether, primary to tertiary amines, pyridine, and imidazole.

The organic group having such a structure is preferably an organic group having 4 to 30 carbon atoms, and examples thereof include an alkyl group, a cycloalkyl group, an aryl group, an aralkyl group, and an alkenyl group.

The alkyl group, the cycloalkyl group, the aryl group, the aralkyl group, or the alkenyl group in the alkyl group, the cycloalkyl group, the aryl group, the aralkyl group, or the alkenyl group, each including a proton-accepting functional group or an ammonium group in R, is the same as the alkyl group, the cycloalkyl group, the aryl group, the aralkyl group, or the alkenyl group, mentioned as Rₓ, respectively.

In a case where B is —N(Rₓ)R_{y}—, it is preferable that R and Rₓ are bonded to each other to form a ring. By forming a ring structure, the stability is improved and the storage stability of a composition using the ring is improved. The number of carbon atoms which form a ring is preferably 4 to 20, the ring may be monocyclic or polycyclic, and an oxygen atom, and a sulfur atom, or a nitrogen atom may be included in the ring.

Examples of the monocyclic structure include 4-, 5-, 6-, 7-, and 8-membered rings, each including a nitrogen atom. Examples of the polycyclic structure include structures formed by a combination of two, or three or more monocyclic structures.

R_{f} in —W₁NHW₂R_{f} represented by Q is preferably an alkyl group having 1 to 6 carbon atoms, which may have a fluorine atom, and more preferably a perfluoroalkyl group having 1 to 6 carbon atoms. Further, it is preferable that at least one of W₁ or W₂ is —SO₂—, and it is more preferable that both of W₁ and W₂ are —SO₂—.

Q is particularly preferably —SO₃H or —CO₂H from the viewpoint of hydrophilicity of acid group.

Among the compounds represented by General Formula (PA-1), the compound in which the Q moiety is sulfonic acid, can be synthesized by a common sulfonamidation reaction. For example, the compound can be obtained by a method of selectively reacting one sulfonyl halide moiety of a bissulfonyl halide compound with an amine compound to form a sulfonamide bond, followed by hydrolysis of another sulfonyl halide moiety thereof, or a method of reacting a cyclic sulfonic acid anhydride with an amine compound to cause ring-opening.

The compound (PA) is preferably an ionic compound. The proton-accepting functional group may be included in an anionic moiety or a cationic moiety, and it is preferable that the functional group is included in an anionic moiety.

Preferred examples of the compound (PA) include compounds represented by General Formulae (4) to (6).

R_{f}—W₂—N⁻—W₁-A-(X)ₙ—B—R [C]⁺ (4)

R—SO₃⁻ [C]⁺ (5)

R—CO₂⁻ [C]⁺ (6)

In General Formulae (4) to (6), A, X, n, B, R, R_{f}, W₁, and W₂ each have the same definitions as those, respectively, in General Formula (PA-1).

C⁺ represents a counter cation.

The counter cation is preferably an onium cation. More specifically, preferred examples thereof include the sulfonium cations described as S⁺(R₂₀₁)(R₂₀₂)(R₂₀₃) in General Formula (ZI) and the iodonium cations described as I⁺(R₂₀₄)(R₂₀₅) in General Formula (ZII) with regard to the acid generator.

Specific examples of the compound (PA) include the compounds exemplified in <0280> of US2011/0269072A1.

Furthermore, in the present invention, compounds (PA) other than a compound which generates the compound represented by General Formula (PA-1) can also be appropriately selected. For example, a compound containing a proton acceptor site at its cationic moiety may be used as an ionic compound. More specific examples thereof include a compound represented by General Formula (7).

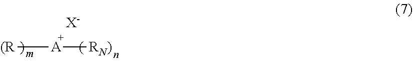

In the formula, A represents a sulfur atom or an iodine atom.

m represents 1 or 2 and n represents 1 or 2, provided that m+n=3 in a case where A is a sulfur atom and that m+n=2 in a case where A is an iodine atom.

R represents an aryl group.

R_{N} represents an aryl group substituted with the proton-accepting functional group, and X⁻ represents a counter anion.

Specific examples of X⁻ include the same anions as those of the acid generators as described above.

Specific preferred examples of the aryl group of each of R and R_{N} include a phenyl group.

Specific examples of the proton-accepting functional group contained in R_{N} are the same as those of the proton-accepting functional group as described above in Formula (PA-1).

Specific examples of the ionic compounds having a proton acceptor site at a cationic moiety include the compounds exemplified in <0291> of US2011/0269072A1.

Furthermore, such compounds can be synthesized, for example, with reference to the methods described in JP2007-230913A, JP2009-122623A, and the like.

The compound (PA) may be used singly or in combination of two or more kinds thereof.

The content of the compound (PA) is preferably 0.1% to 10% by mass, and more preferably 1% to 8% by mass, with respect to the total solid content of the composition.

In the composition of the embodiment of the present invention, an onium salt which becomes a relatively weak acid with respect to the acid generator can be used as an acid diffusion control agent (D).

In a case of mixing the acid generator and the onium salt that generates an acid which is a relatively weak acid (preferably a weak acid having a pKa of more than −1) with respect to an acid generated from the acid generator, and then using the mixture, in a case where the acid generated from the acid generator upon irradiation with actinic rays or radiation collides with an onium salt having an unreacted weak acid anion, a weak acid is discharged by salt exchange, thereby generating an onium salt having a strong acid anion. In this process, the strong acid is exchanged with a weak acid having a lower catalytic ability, and therefore, the acid is deactivated in appearance, and thus, it is possible to carry out the control of acid diffusion.

As the onium salt which becomes a relatively weak acid with respect to the acid generator, compounds represented by General Formulae (d1-1) to (d1-3) are preferable.

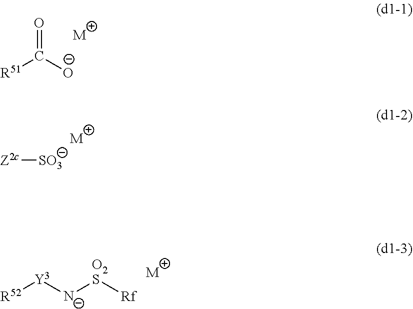

In the formulae, R⁵¹ is a hydrocarbon group which may have a substituent, Z^{2c} is a hydrocarbon group (provided that carbon atom adjacent to S is not substituted with a fluorine atom) having 1 to 30 carbon atoms, which may have a substituent, R⁵² is an organic group, Y³ is a linear, branched, or cyclic alkylene group or arylene group, Rf is a hydrocarbon group including a fluorine atom, and M⁺'s are each independently a sulfonium or iodonium cation.

Preferred examples of the sulfonium cation or the iodonium cation represented by M⁺ include the sulfonium cations exemplified by the General Formula (ZI) and the iodonium cations exemplified by (ZII).

Preferred examples of the anionic moiety of the compound represented by General Formula (d1-1) include the structures exemplified in paragraph [0198] of JP2012-242799A.

Preferred examples of the anionic moiety of the compound represented by General Formula (d1-2) include the structures exemplified in paragraph [0201] of JP2012-242799A.

Preferred examples of the anionic moiety of the compound represented by General Formula (d1-3) include the structures exemplified in paragraphs [0209] and [0210] of JP2012-242799A.

The onium salt which becomes a relatively weak acid with respect to the acid generator may be a compound (hereinafter also referred to as a “compound (D-2)”) having a cationic moiety and an anionic moiety in the same molecule, in which the cationic moiety and the anionic moiety are linked to each other through a covalent bond.

As the compound (D-2), a compound represented by any one of General Formula (C-1), (C-2), or (C-3) is preferable.

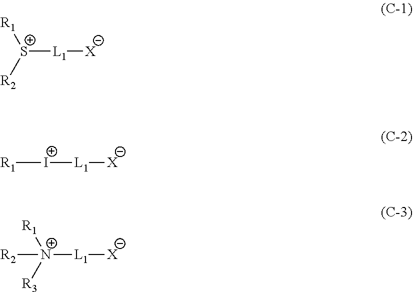

In General Formulae (C-1) to (C-3),

R₁, R₂, and R₃ represent a substituent having 1 or more carbon atoms.

L₁ represents a divalent linking group that links a cationic moiety with an anionic moiety, or a single bond.

—X⁻ represents an anionic moiety selected from —COO⁻, —SO₃⁻, −SO₂⁻, and —N⁻—R₄. R₄ represents a monovalent substituent having a carbonyl group: —C(═O)—, a sulfonyl group: —S(═O)₂—, or a sulfinyl group: —S(═O)— at a site for linking to an adjacent N atom.

R₁, R₂, R₃, R₄, and L₁ may be bonded to one another to form a ring structure. Further, in (C-3), two members out of R₁ to R₃ may be combined to form a double bond with an N atom.

Examples of the substituent having 1 or more carbon atoms in each of R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group. The substituent is preferably an alkyl group, a cycloalkyl group, or an aryl group.

Examples of L₁ as a divalent linking group include a linear or branched alkylene group, a cycloalkylene group, an arylene group, a carbonyl group, an ether bond, ester bond, amide bond, a urethane bond, a urea bond, and a group formed by a combination of two or more kinds of these groups. L₁ is more preferably alkylene group, an arylene group, an ether bond, ester bond, and a group formed by a combination of two or more kinds of these groups.

Preferred examples of the compound represented by General Formula (C-1) include the compounds exemplified in paragraphs [0037] to [0039] of JP2013-006827A and paragraphs [0027] to [0029] of JP2013-008020A.

Preferred examples of the compound represented by General Formula (C-2) include the compounds exemplified in paragraphs [0012] and [0013] of JP2012-189977A.

Preferred examples of the compound represented by General Formula (C-3) include the compounds exemplified in paragraphs [0029] to [0031] of JP2012-252124A.

The content of the onium salt which becomes a relatively weak acid with respect to the acid generator is preferably 0.5% to 10.0% by mass, more preferably 0.5% to 8.0% by mass, and still more preferably 1.0% to 8.0% by mass, with respect to the solid content of the composition.

<Surfactant (E)>

The actinic ray-sensitive or radiation-sensitive composition of the embodiment of the present invention may or may not further contain a surfactant. In a case where the composition contains the surfactant, it is more preferable that the composition contains any one or two or more of fluorine- and/or silicon-based surfactants (a fluorine-based surfactant, a silicon-based surfactant, and a surfactant having both a fluorine atom and a silicon atom).

Examples of the fluorine- and/or silicon-based surfactants include the surfactants described in paragraph <0276> in US2008/0248425A, for example, EFTOP EF301 and EF303 (manufactured by Shin-Akita Kasei K. K.), FLORAD FC430, 431, and 4430 (manufactured by Sumitomo 3M Inc.), MEGAFACE F171, F173, F176, F189, F113, F110, F177, F120, and R08 (manufactured by DIC Corp.), SURFLON S-382, SC101, 102, 103, 104, 105, and 106, and KH-20 (manufactured by Asahi Glass Co., Ltd.), TROYSOL S-366 (manufactured by Troy Chemical Corp.), GF-300 and GF-150 (manufactured by Toagosei Chemical Industry Co., Ltd.), SURFLON S-393 (manufactured by Seimi Chemical Co., Ltd.), EFTOP EF121, EF122A, EF122B, RF122C, EF125M, EF135M, EF351, EF352, EF801, EF802, and EF601(manufactured by JEMCO Inc.), PF636, PF656, PF6320, and PF6520 (manufactured by OMNOVA Solutions Inc.), and FTX-204G, 208G, 218G, 230G, 204D, 208D, 212D, 218D, and 222D (manufactured by NEOS COMPANY LIMITED). In addition, Polysiloxane Polymer KP-341 (manufactured by Shin-Etsu Chemical Co., Ltd.) can also be used as the silicon-based surfactant.

Furthermore, in addition to those known surfactants as described above, a surfactant using a polymer having a fluoroaliphatic group derived from a fluoroaliphatic compound which is produced by a telomerization method (also referred to as a telomer method) or an oligomerization method (also referred to as an oligomer method), can be used as the surfactant. The fluoroaliphatic compound can be synthesized in accordance with the method described in JP2002-090991A.

Examples of the commercially available surfactants include MEGAFAC F178, F-470, F-473, F-475, F-476, and F-472 (manufactured by DIC Corp.); a copolymer of an acrylate (or methacrylate) having a C₆F₁₃ group with a (poly(oxyalkylene)) acrylate (or methacrylate); and a copolymer of an acrylate (or methacrylate) having a C₃F₇ group with a (poly(oxyethylene)) acrylate (or methacrylate) and a (poly(oxypropylene)) acrylate (or methacrylate).

In addition, in the present invention, the surfactants other than the fluorine- and/or silicon-based surfactants, which are described in <0280> in US2008/0248425A, can also be used.

These surfactants may be used singly or in combination of more than one surfactants.

In a case where the actinic ray-sensitive or radiation-sensitive composition contains a surfactant, the amount of the surfactant to be used is preferably 0.0001% to 2% by mass, and more preferably 0.0005% to 1% by mass, with respect to the total solid amount (excluding the solvent) of the actinic ray-sensitive or radiation-sensitive composition.

On the other hand, by setting the amount of the surfactant to be added to 10 ppm or less with respect to the total amount (excluding the solvent) of the actinic ray-sensitive or radiation-sensitive composition, the hydrophobic resin is more unevenly distributed to the surface, so that the resist film surface can be made more hydrophobic, which can enhance the water tracking properties during the liquid immersion exposure.

<Other Additives>

The composition of the embodiment of the present invention may or may not contain an onium carboxylate salt. Examples of such an onium carboxylate salt include those described in <0605> and <0606> in US2008/0187860A.

The onium carboxylate salt can be synthesized by reacting sulfonium hydroxide, iodonium hydroxide, ammonium hydroxide and carboxylic acid with silver oxide in a suitable solvent.

In a case where the composition of the embodiment of the present invention contains the onium carboxylate salt, the content of the salt is generally 0.1% to 20% by mass, preferably 0.5% to 10% by mass, and more preferably 1% to 7% by mass, with respect to the total solid content of the composition.

The composition of the embodiment of the present invention may further contain an acid proliferation agent, a dye, a plasticizer, a light sensitizer, a light absorbent, an alkali-soluble resin, a dissolution inhibitor, a compound promoting solubility in a developer (for example, a phenol compound with a molecular weight of 1,000 or less, an alicyclic or aliphatic compound having a carboxyl group), and the like, as desired.

Such a phenol compound having a molecular weight of 1,000 or less can be easily synthesized by those skilled in the art with reference to the method described in, for example, JP1992-122938A (JP-H04-122938A), JP1990-028531A (JP-H02-028531A), US4916210A, EP219294B, or the like.

Specific examples of the alicyclic compound or aliphatic compound having a carboxyl group include, but not limited to, a carboxylic acid derivative having a steroid structure such as a cholic acid, deoxycholic acid or lithocholic acid, an adamantane carboxylic acid derivative, adamantane dicarboxylic acid, cyclohexane carboxylic acid, and cyclohexane dicarboxylic acid.

The actinic ray-sensitive or radiation-sensitive composition of the embodiment of the present invention is a composition for forming an actinic ray-sensitive or radiation-sensitive film having a film thickness of more than 9μm and 20 μm or less, and the film thickness of the actinic ray-sensitive or radiation-sensitive film is more preferably 10 μm or more, and still more preferably 11 μm or more.

In addition, the film thickness of the actinic ray-sensitive or radiation-sensitive film is more preferably 15 μm or less, and still more preferably 13 μm or less.

The concentration of the solid content of the composition of the embodiment of the present invention is usually 10% to 50% by mass, preferably 15% to 45% by mass, and more preferably 20% to 40% by mass. By setting the concentration of the solid content to these ranges, it is possible to uniformly coat the resist solution on a substrate.

The concentration of the solid content is the mass percentage of the mass of other resist components excluding the solvent with respect to the total mass of the composition.

The composition of the embodiment of the present invention is preferably used by dissolving the components in a solvent (S) satisfying the conditions (a) to (c), filtering the solution through a filter, and then applying the solution on a predetermined substrate. The filter for use in filtration is preferably a polytetrafluoroethylene-, polyethylene-, or nylon-made filter having a pore size of 0.3 μm or less, more preferably of 0.2 μm or less, and still more preferably of 0.1 μm or less. In the filtration through a filter as described in, for example, JP2002-062667A, circulating filtration may be carried out, or the filtration may be carried out by connecting plural kinds of filters in series or in parallel. In addition, the composition may be filtered in plural times. Furthermore, the composition may be subjected to a deaeration treatment or the like before or after filtration through a filter.

[Pattern Forming Method]

Next, the pattern forming method of an embodiment of the present invention will be described.

The pattern forming method of the embodiment of the present invention is a pattern forming method including i) a step of forming an actinic ray-sensitive or radiation-sensitive film having a film thickness of more than 9 μm and 20 μm or less using an actinic ray-sensitive or radiation-sensitive composition including a solvent (S) satisfying the conditions (a) to (c), ii) a step of irradiating the actinic ray-sensitive or radiation-sensitive film with actinic rays or radiation (exposing step), and iii) a step of developing the actinic ray-sensitive or radiation-sensitive film irradiated with actinic rays or radiation, using a developer (developing step).

It is preferable that the pattern forming method of the embodiment of the present invention includes iv) a heating step after ii) the exposing step.

The pattern forming method of the embodiment of the present invention may include ii) the exposing step in plural times.

The pattern forming method of the embodiment of the present invention may include iv) the heating step in plural times.

In the pattern forming method of the embodiment of the present invention, the step of forming a film using an actinic ray-sensitive or radiation-sensitive composition, the step of exposing the film, and the developing step can be carried out by a method that is generally known.

In the film forming step in the step i), it is preferable to form an actinic ray-sensitive or radiation-sensitive film by applying an actinic ray-sensitive or radiation-sensitive composition onto a substrate.

The substrate on which the actinic ray-sensitive or radiation-sensitive film is formed is not particularly limited, and a substrate such as an inorganic substrate such as silicon, SiN, SiO₂, and SiN, and a coating type inorganic substrate such as system-on-glass (SOG), which are generally used in a process for manufacturing a semiconductor such as an integrated circuit, and a process for manufacture of a circuit board for a liquid crystal, a thermal head, or the like; and in other lithographic processes of photofabrication, can be used. In addition, an antireflection film may further be formed between the resist film and the substrate, as desired. As the antireflection film, a known organic or inorganic antireflection film can be appropriately used.

It is also preferable that the method includes a prebaking (PB) step before an exposing step which will be described later, after forming a film.

Furthermore, it is also preferable that the method includes a step of post-exposure baking (PEB) step after the exposing step and before the developing step.

For both of PB and PEB, heating is carried out at a heating temperature of preferably 70° C. to 130° C., and more preferably 80° C. to 120° C.

The heating time is preferably 30 to 300 seconds, more preferably 30 to 180 seconds, and still more preferably 30 to 90 seconds.

Heating may be carried out using a means comprised in ordinary exposure and development machines, or may also be carried out using a hot plate or the like.

Baking accelerates the reaction in the exposed areas, and thus, the sensitivity and the pattern profile are enhanced.

The light source wavelength used in the exposure device in the present invention is preferably 200 to 300 nm. Preferred examples of the light source include a KrF excimer laser (248 nm).

The developer used in the step of developing the film formed using the actinic ray-sensitive or radiation-sensitive composition is not particularly limited, but examples thereof include an alkali developer or a developer containing an organic solvent (the developer is hereinafter also referred to an organic developer). Among those, the alkali developer is preferably used.

As the alkali developer, for example, aqueous alkali solutions of inorganic alkalis such as sodium hydroxide, potassium hydroxide, sodium carbonate, sodium silicate, sodium metasilicate, and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetraalkylammonium hydroxides such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide, trimethylphenylammonium hydroxide, trimethylbenzylammonium hydroxide, and triethylbenzylammonium hydroxide, cyclic amines such as pyrrole and piperidine, or the like can be used. Further, alcohols and a surfactant can also be added to the aqueous alkali solution in an appropriate amount before use. The alkali concentration of the alkali developer is usually 0.1% to 20% by mass. The pH of the alkali developer is usually 10.0 to 15.0. It is possible to appropriately adjust and use the alkali concentration and the pH of the alkali developer. The alkali developer may also be used after adding a surfactant or an organic solvent thereto.

As the rinsing liquid in the rinsing treatment carried out after the alkali development, pure water is used, and the rinsing liquid can also be used after adding an appropriate amount of a surfactant thereto.

In addition, after the developing treatment or the rinsing treatment, a treatment of removing the developer or rinsing liquid adhering onto the pattern by a supercritical fluid can be carried out.

As the organic developer, a polar solvent such as a ketone-based solvent, an ester-based solvent, an alcohol-based solvent, an amide-based solvent, or an ether-based solvent, and a hydrocarbon-based solvent can be used, and specific examples thereof include the solvents described in paragraph <0507> of JP2013-218223A, and isoamyl acetate, butyl butanoate, butyl butyrate, and methyl 2-hydroxyisobutyrate.

The above-mentioned solvents can be used by mixing a plurality of the solvents or by mixing the solvents with solvents other than the solvents or water. However, in order to sufficiently exhibit the effects of the present invention, the moisture content in the entire developer is preferably less than 10% by mass, but a developer having substantially no moisture is more preferable.

That is, the amount of the organic solvent to be used with respect to the organic developer is preferably from 90% by mass to 100% by mass, and more preferably from 95% by mass to 100% by mass, with respect to the total amount of the developer.

In particular, the organic developer is preferably a developer containing at least one organic solvent selected from the group consisting of a ketone-based solvent, an ester-based solvent, an alcohol-based solvent, an amide-based solvent, and an ether-based solvent.

The vapor pressure of the organic developer is preferably 5 kPa or less, more preferably 3 kPa or less, and particularly preferably 2 kPa or less, at 20° C. By setting the vapor pressure of the organic developer to 5 kPa or less, the evaporation of the developer on the substrate or in a developing cup is suppressed, the uniformity of temperature within the wafer surface is improved, and as a result, the dimensional uniformity within the wafer surface is improved.

It is possible to add an appropriate amount of a surfactant to the organic developer, as desired.

The surfactant is not particularly limited, but it is possible to use, for example, ionic or non-ionic fluorine- and/or silicon-based surfactants, or the like. Examples of the fluorine- and/or silicon-based surfactant include the surfactants described in JP1987-036663A (JP-S62-036663A), JP1986-226746A (JP-S61-226746A), JP1986-226745A (JP-S61-226745A), JP1987-170950A (JP-S62-170950A), JP1988-034540A (JP-S63-034540A), JP1995-230165A (JP-H07-230165A), JP1996-062834A (JP-H08-062834A), JP1997-054432A (JP-H09-054432A), JP1997-005988A (JP-H09-005988A), US5405720A, US5360692A, US5529881A, US5296330A, US5436098A, US5576143A, US5294511A, and US5824451A, and non-ionic surfactants are preferable. The non-ionic surfactant is not particularly limited, but it is more preferable to use a fluorine-based surfactant or a silicon-based surfactant.

The amount of the surfactant to be used is usually 0.001% to 5% by mass, preferably 0.005% to 2% by mass, and more preferably 0.01% to 0.5% by mass, with respect to the total amount of the developer.

The organic developer may include a basic compound. Specific and preferred examples of the basic compound which can be included in the organic developer used in the present invention are the same ones as for the basic compound which can be included in the composition, as an acid diffusion control agent (D) which will be described later.

Examples of the developing method include a method in which a substrate is immersed in a tank filled with a developer for a certain period of time (a dip method), a method in which development is performed by heaping a developer up onto the surface of a substrate by surface tension, and then stopping it for a certain period of time (a puddle method), a method in which a developer is sprayed on the surface of a substrate (a spray method), and a method in which a developer is continuously discharged onto a substrate spun at a constant rate while scanning a developer discharging nozzle at a constant rate (a dynamic dispense method).

In a case where the various developing methods include a step of discharging a developer toward a resist film from a development nozzle of a developing device, the discharge pressure of the developer discharged (the flow rate per unit area of the developer discharged) is preferably 2 mL/sec/mm² or less, more preferably 1.5 mL/sec/mm² or less, and still more preferably 1 mL/sec/mm² or less. The flow rate has no particular lower limit, but is preferably 0.2 mL/sec/mm² or more in consideration of throughput.

By setting the discharge pressure of the discharged developer to the above-mentioned range, pattern defects resulting from the resist scum after development can be significantly reduced.

Details on the mechanism are not clear, but it is thought that it is due to the pressure imposed on the resist film by the developer being decreased by setting the discharge pressure to the above-described range so that the resist film and/or the resist pattern is suppressed from being inadvertently cut or collapsing.

In addition, the discharge pressure (mL/sec/mm²) of the developer is the value at the outlet of the development nozzle in the developing device.

Examples of the method for adjusting the discharge pressure of the developer include a method of adjusting the discharge pressure by a pump, and a method of supplying a developer from a pressurized tank and adjusting the pressure to change the discharge pressure.

In addition, after the step of performing development, using a developer including an organic solvent, a step of stopping the development while replacing the solvent with another solvent may be carried out.

In the pattern forming method of the embodiment of the present invention, a step of performing development by using a developer including an organic solvent (organic solvent developing step) and a step of carrying out development by using an aqueous alkali solution (alkali developing step) may be used in combination. Thus, a finer pattern can be formed.

In the present invention, an area with a low exposure intensity is removed in the organic solvent developing step, and by further carrying out the alkali developing step, an area with a high exposure intensity is also removed. By virtue of multiple development processes in which development is carried out in a plurality of times in such a manner, a pattern can be formed by keeping only a region with an intermediate exposure intensity from not being dissolved, so that a finer pattern than usual can be formed (the same mechanism as in <0077> of JP2008-292975A).

In the pattern forming method of the embodiment of the present invention, the order of the alkali developing step and the organic solvent developing step is not particularly limited, but it is more preferable that the alkali developing step is carried out before the organic solvent developing step.

It is preferable that a step of performing washing using a rinsing liquid is carried out after the step of performing development using a developer including an organic solvent.

The rinsing liquid used in the rinsing step after the step of performing development using a developer including an organic solvent is not particularly limited as long as the rinsing liquid does not dissolve the resist pattern, and a solution including a common organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent include the same solvents as those described for the developer including an organic solvent.

After the developing step using a developer including an organic solvent, it is more preferable to carry out a step of performing washing using a rinsing liquid containing at least one organic solvent selected from the group consisting of a ketone-based solvent, an ester-based solvent, an alcohol-based solvent, an amide-based solvent, and a hydrocarbon-based solvent, it is still more preferable to carry out a step of performing washing using a rinsing liquid containing an alcohol-based solvent or an ester-based solvent, it is particularly preferable to carry out a step of performing washing using a rinsing liquid containing a monohydric alcohol, and it is the most preferable to carry out a step of performing washing using a rinsing liquid containing a monohydric alcohol having 5 or more carbon atoms.

Here, examples of the monohydric alcohol used in the rinsing step include linear, branched, or cyclic monohydric alcohols, and specifically, 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol, or the like can be used. As a particularly preferred monohydric alcohol having 5 or more carbon atoms, 1-hexanol, 2-hexanol, 4-methyl-2-pentanol, 1-pentanol, 3-methyl-1-butanol, or the like can be used.

As the hydrocarbon-based solvent used in the rinsing step, a hydrocarbon compound having 6 to 30 carbon atoms is preferable, a hydrocarbon compound having 8 to 30 carbon atoms is more preferable, a hydrocarbon compound having 7 to 30 carbon atoms is still more preferable, and a hydrocarbon compound having 10 to 30 carbon atoms is particularly preferable. Among those, a rinsing liquid including decane and/or undecane is used to suppress pattern collapse.

The respective components in plural numbers may be mixed, or the components may be mixed with an organic solvent other than the above solvents, and used.

The moisture content of the rinsing liquid is preferably 10% by mass or less, more preferably 5% by mass or less, and still more preferably 3% by mass or less. By setting the moisture content to 10% by mass or less, good development characteristics can be obtained.

The vapor pressure at 20° C. of the rinsing liquid which is used after the step of carrying out development using a developer including an organic solvent is preferably from 0.05 kPa to 5 kPa, more preferably from 0.1 kPa to 5 kPa, and still more preferably from 0.12 kPa to 3 kPa. By setting the vapor pressure of the rinsing liquid to from 0.05 kPa to 5 kPa, the wafer uniformity of temperature within the surface is improved, and further, the dimensional uniformity within the wafer surface is enhanced by suppression of swelling due to the permeation of the rinsing liquid.

An appropriate amount of a surfactant can be added to the rinsing liquid before use.

In the rinsing step, a wafer which has been developed using a developer including an organic solvent is subjected to a washing treatment is performed using a rinsing liquid including the organic solvent. A method for the washing treatment is not particularly limited, and for example, a method in which a rinsing liquid is continuously discharged on a substrate spun at a constant rate (a rotation application method), a method in which a substrate is immersed in a tank filled with a rinsing liquid for a certain period of time (a dip method), a method in which a rinsing liquid is sprayed on a substrate surface (a spray method), or the like can be applied. Among these, a method in which a washing treatment is performed by a rotation application method, and a substrate is rotated at a rotation speed of 2,000 rpm to 4,000 rpm after washing, thereby removing the rinsing liquid from the substrate, is preferable. Further, it is preferable that a heating step (post-baking) is included after the rinsing step. The residual developer and the rinsing liquid between and inside the patterns are removed by the baking. The heating step after the rinsing step is carried out at usually 40° C. to 160° C., and preferably at 70° C. to 95° C., and usually for 10 seconds to 3 minutes, and preferably for 30 seconds to 90 seconds.

It is preferable that various materials (for example, a resist solvent, a developer, a rinsing liquid, a composition for forming an antireflection film, and a composition for forming an antireflection film) for use in the actinic ray-sensitive or radiation-sensitive composition of the embodiment of the present invention and the pattern forming method of the embodiment of the present invention do not include impurities such as metals. The content of the impurities included in these materials is preferably 1 ppm or less, more preferably 10 ppb or less, still more preferably 100 ppt or less, particularly preferably 10 ppt or less, and most preferably, the impurities are not substantially included (at a detection limit of a measurement apparatus or less).

Examples of a method for removing impurities such as metals from the various materials include filtration using a filter. As for the filter pore diameter, the pore size is preferably 10 nm or less, more preferably 5 nm or less, and still more preferably 3 nm or less. As for the materials of a filter, a polytetrafluoroethylene-made filter, a polyethylene-made filter, and a nylon-made filter are preferable. The filter may be formed of a composite material formed by combining these materials with an ion exchange medium. As the filter, a filter which had been washed with an organic solvent in advance may be used. In the step of filtration using a filter, plural kinds of filters may be connected in series or in parallel, and used. In a case of using plural kinds of filters, a combination of filters having different pore diameters and/or materials may be used. In addition, various materials may be filtered plural times, and a step of filtering plural times may be a circulatory filtration step.

Moreover, examples of the method for reducing the impurities such as metals included in the various materials include a method involving selecting raw materials having a small content of metals as raw materials constituting various materials, a method involving subjecting raw materials constituting various materials to filtration using a filter, and a method involving performing distillation under the condition with contamination being suppressed to the largest degree by, for example, lining the inside of a device with TEFLON (registered trademark). The preferred conditions for filtration using a filter, which is carried out for raw materials constituting various materials, are the same as described above.

In addition to the filtration using a filter, removal of impurities by an adsorbing material may be carried out, or a combination of filtration using a filter and an adsorbing material may be used. As the adsorbing material, known adsorbing materials can be used, and for example, inorganic adsorbing materials such as silica gel and zeolite, and organic adsorbing materials such as activated carbon can be used.

A method for improving the surface roughness of a pattern may be applied to a pattern formed by the pattern forming method of the embodiment of the present invention. Examples of the method for improving the surface roughness of a pattern include the method of treating a resist pattern by a plasma of a hydrogen-containing gas disclosed in WO2014/002808. In addition, known methods as described in JP2004-235468A, US2010/0020297A, JP2009-019969A, and Proc. of SPIE Vol. 8328 83280N-1 “EUV Resist Curing Technique for LWR Reduction and Etch Selectivity Enhancement” may be applied.

The pattern forming method of the embodiment of the present invention can also be used for a guide pattern formation in a directed self-assembly (DSA) (see, for example, ACS Nano Vol. 4, No. 8, Pages 4815 to 4823).

In addition, a resist pattern formed by the method can be used as a core material (core) of the spacer process disclosed in JP1991-270227A (JP-H03-270227A) and JP2013-164509A.

In addition, the present invention also relates to a method for manufacturing an electronic device, including the pattern forming method of the embodiment of the present invention as described above.

The electronic device of the present invention is suitably mounted on electric or electronic equipment (home electronics, office automation (OA)/media-related equipment, optical equipment, telecommunication equipment, and the like).

### EXAMPLES

Hereinafter, the present invention will be described with reference to Examples, but the present invention is not limited thereto.

<Preparation of Actinic Ray-Sensitive or Radiation-Sensitive Composition>

The components shown in Solid contents 1 to 3 in Table 1 below were dissolved in solvents (197 parts by mass) shown in Tables 2 and 5 below to prepare a resist solution for each component, which was filtered at a filtration pressure of 0.1 MPa through an ultra-high-molecular-weight polyethylene (UPE) filter having a pore size of 1.0 μm. Thus, an actinic ray-sensitive or radiation-sensitive composition (resist composition) having a concentration of the solid content of 34% by mass was prepared.

TABLE 1

| | | | | | Acid diffusion control | | | |
|---|---|---|---|---|---|---|---|---|
| | Resin (A) | | Acid generator (B) | | agent (D) | | Surfactant (E) | |
| | Type | Parts by mass | Type | Parts by mass | Type | Parts by mass | Type | Parts by mass |
| Solid content 1 | A-1 | 100 | B-1 | 1 | D-1 | 0.03 | E-1 | 0.05 |
| Solid content 2 | A-2 | 100 | B-1 | 1 | D-1 | 0.03 | E-1 | 0.05 |
| Solid content 3 | A-3 | 100 | B-1 | 1 | D-1 | 0.03 | E-1 | 0.05 |

TABLE 2

| | | Solvent (S-1) | | | | Solvent (S-2) | | | |
|---|---|---|---|---|---|---|---|---|---|
| | | | | | Boiling | | | | Boiling |
| | Type of solid | | Mass | Viscosity | point | | Mass | Viscosity | point |
| | content | Type | proportion | (mPa · s) | (° C.) | Type | proportion | (mPa · s) | (° C.) |
| Example 1 | 1 | PGMEA | 0.5 | 1.1 | 146 | EL | 0.5 | 2.7 | 155 |
| Example 2 | 1 | PGME | 0.5 | 1.8 | 120 | EL | 0.5 | 2.7 | 155 |
| Example 3 | 1 | PGME | 0.7 | 1.8 | 120 | EL | 0.3 | 2.7 | 155 |
| Example 4 | 1 | CyHx | 1 | 2.0 | 156 | — | — | — | — |
| Example 5 | 1 | nBA | 0.5 | 0.7 | 126 | EL | 0.5 | 2.7 | 155 |
| Example 6 | 1 | PGMEA | 0.7 | 1.1 | 146 | CyHx | 0.3 | 2.0 | 156 |
| Example 7 | 1 | PGME | 0.5 | 1.8 | 120 | EEP | 0.5 | 1.0 | 166 |
| Example 8 | 1 | PGME | 0.5 | 1.8 | 120 | CyHx | 0.5 | 2.0 | 156 |
| Example 9 | 1 | PGMEA | 0.5 | 1.1 | 146 | CyHx | 0.5 | 2.0 | 156 |
| Example 10 | 1 | nBA | 0.5 | 0.7 | 126 | CyHx | 0.5 | 2.0 | 156 |
| Example 11 | 1 | nBA | 0.5 | 0.7 | 126 | MIBC | 0.5 | 4.1 | 132 |
| Example 12 | 1 | PGME | 0.6 | 1.8 | 120 | MIBC | 0.4 | 4.1 | 132 |
| Example 13 | 1 | PGME | 0.9 | 1.8 | 120 | EL | 0.1 | 2.7 | 155 |
| Example 14 | 1 | PGMEA | 0.9 | 1.1 | 146 | GBL | 0.1 | 1.7 | 204 |
| Example 15 | 1 | MAK | 0.1 | 0.8 | 151 | EL | 0.9 | 2.7 | 155 |
| Example 16 | 1 | MAK | 0.3 | 0.8 | 151 | MIBC | 0.7 | 4.1 | 132 |
| Example 17 | 1 | MMP | 0.3 | 1.1 | 144 | EL | 0.7 | 2.7 | 155 |
| Example 18 | 1 | PGMEA | 0.4 | 1.1 | 146 | EEP | 0.6 | 1.0 | 166 |

TABLE 3

| | | Solvent (S-1) | | | | Solvent (S-2) | | | |
|---|---|---|---|---|---|---|---|---|---|
| | Type of | | | | Boiling | | | | Boiling |
| | solid | | Mass | Viscosity | point | | Mass | Viscosity | point |
| | content | Type | proportion | (mPa · s) | (° C.) | Type | proportion | (mPa · s) | (° C.) |
| Comparative | 1 | PGME | 1 | 1.8 | 120 | — | — | — | — |
| Example 1 | | | | | | | | | |
| Comparative | 1 | PGMEA | 0.5 | 1.1 | 146 | PGME | 0.5 | 1.8 | 120 |
| Example 2 | | | | | | | | | |
| Comparative | 1 | PGMEA | 0.6 | 1.1 | 146 | PGME | 0.4 | 1.8 | 120 |
| Example 3 | | | | | | | | | |
| Comparative | 1 | PGMEA | 1 | 1.1 | 146 | — | — | — | — |
| Example 4 | | | | | | | | | |
| Comparative | 1 | PGME | 0.5 | 1.8 | 120 | MIBC | 0.5 | 4.1 | 132 |
| Example 5 | | | | | | | | | |
| Comparative | 1 | MIBC | 1 | 4.1 | 132 | — | — | — | — |
| Example 6 | | | | | | | | | |
| Comparative | 1 | MAK | 1 | 0.8 | 151 | — | — | — | — |
| Example 7 | | | | | | | | | |
| Comparative | 1 | nBA | 1 | 0.7 | 126 | — | — | — | — |
| Example 8 | | | | | | | | | |
| Comparative | 1 | EEP | 1 | 1.0 | 166 | — | — | — | — |
| Example 9 | | | | | | | | | |
| Comparative | 1 | EL | 1 | 2.7 | 155 | — | — | — | — |
| Example 10 | | | | | | | | | |
| Comparative | 1 | GBL | 1 | 1.7 | 204 | — | — | — | — |
| Example 11 | | | | | | | | | |
| Comparative | 1 | MMP | 1 | 1.1 | 144 | — | — | — | — |
| Example 12 | | | | | | | | | |
| Comparative | 1 | 3-Methoxybutyl | 1 | 1.2 | 171 | — | — | — | — |
| Example 13 | | acetate | | | | | | | |
| Comparative | 1 | 3-Methoxybutanol | 1 | 1.7 | 161 | — | — | — | — |
| Example 14 | | | | | | | | | |
| Comparative | 1 | PGMEA | 0.3 | 1.1 | 146 | MIBC | 0.7 | 4.1 | 132 |
| Example 15 | | | | | | | | | |
| Comparative | 1 | CyHx | 0.1 | 2.0 | 156 | EL | 0.9 | 2.7 | 155 |
| Example 16 | | | | | | | | | |
| Comparative | 1 | CyHx | 0.9 | 2.0 | 156 | GBL | 0.1 | 1.7 | 204 |
| Example 17 | | | | | | | | | |

TABLE 4

| | | Solvent (S-1) | | | | Solvent (S-2) | | | |
|---|---|---|---|---|---|---|---|---|---|
| | | | | | Boiling | | | | Boiling |
| | Type of solid | | Mass | Viscosity | point | | Mass | Viscosity | point |
| | content | Type | proportion | (mPa · s) | (° C.) | Type | proportion | (mPa · s) | (° C.) |
| Example 19 | 2 | PGMEA | 0.5 | 1.1 | 146 | EL | 0.5 | 2.7 | 155 |
| Comparative | 2 | PGME | 1 | 1.8 | 120 | — | — | — | — |
| Example 18 | | | | | | | | | |

TABLE 5

| | | Solvent (S-1) | | | | Solvent (S-2) | | | |
|---|---|---|---|---|---|---|---|---|---|
| | | | | | Boiling | | | | Boiling |
| | Type of solid | | Mass | Viscosity | point | | Mass | Viscosity | point |
| | content | Type | proportion | (mPa · s) | (° C.) | Type | proportion | (mPa · s) | (° C.) |
| Example 20 | 3 | PGMEA | 0.5 | 1.1 | 146 | EL | 0.5 | 2.7 | 155 |
| Comparative | 3 | PGME | 1 | 1.8 | 120 | — | — | — | — |
| Example 19 | | | | | | | | | |

The components and the abbreviations in Tables 1 to 5 are as follows.

The structures of the resins are as follows.

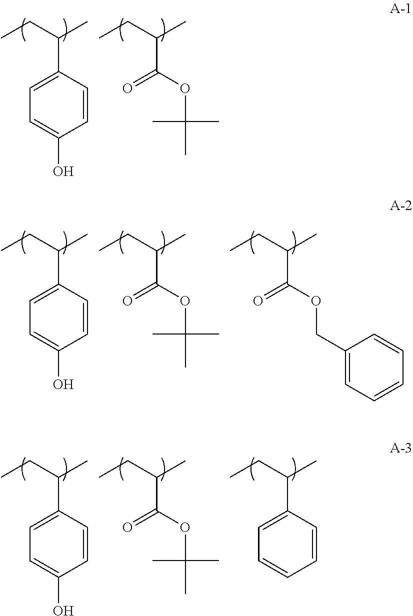

Hereinafter, the compositional ratios (the molar ratios), the weight-average molecular weight (Mw), and the dispersity (Mw/Mn) of the resins are shown in Table 6. Here, the molar ratios of the repeating units correspond in order from the left side of the repeating units.

TABLE 6

| | Composition | Mw | Mw/Mn |
|---|---|---|---|
| A-1 | 75/25 | 20,000 | 1.3 |
| A-2 | 65/25/10 | 20,000 | 1.4 |
| A-3 | 65/25/10 | 20,000 | 1.3 |

The structures of the acid generator (B-1), the acid diffusion control agent (D-1), and the surfactant (E-1) are as follows.

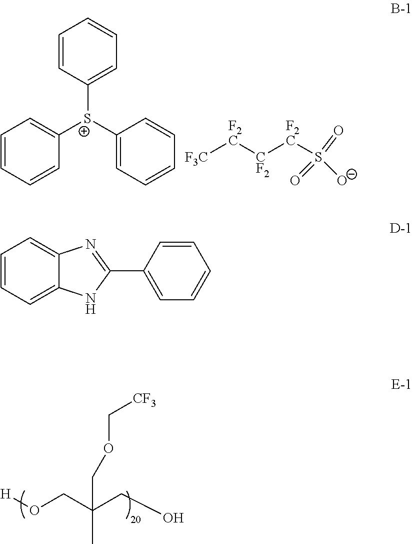

The abbreviations of the solvents are as follows.

PGMEA: Propylene glycol monomethyl ether acetate

PGME: Propylene glycol monomethyl ether

EL: Ethyl lactate

EEP: Ethyl 3-Ethoxypropionate

CyHx: Cyclohexanone

GBL: γ-Butyrolactone

nBA: Butyl n-acetate

MIBC: 4-Methyl-2-pentanol

MAK: 2-Heptanone

MMP: Methyl 3-methoxypropionate

With regard to the solvents used in Examples and Comparative Examples, the viscosity A (mPa·s) and the boiling point B (° C.) were calculated by the above-mentioned methods. The results are shown in Tables 7 to 10.

<Method for Preparing Resist Film>

The resist composition prepared above was applied onto a Si substrate (manufactured by Advanced Materials Technology) which had been subjected to a hexamethyldisilazane treatment, using a coater (ACT-8; manufactured by Tokyo Electron Limited), while not providing an antireflection layer, and baked (prebaked; PB) at 130° C. for 60 seconds to form an actinic ray-sensitive or radiation-sensitive film (resist film) having a film thickness of 10

<Evaluation>

(Method for Evaluating Plane Shape)

With regard to a wafer having a resist film formed thereon, the film thickness was measured at 150 points across the film using an optical film thickness meter (VM3100; manufactured by SCREEN Semiconductor Solutions Co., Ltd.), and a film thickness deviation within the surface (σ value; standard deviation) was calculated. The calculated σ value was evaluated in accordance with the following evaluation standard. Further, the σ value has a meaning as follows: as the value is smaller, the film thickness deviation within the surface was smaller, and thus, a resist film having high uniformity is obtained. The results are shown in Tables 7 to 10.

A (Very good): σ<1,000 nm

B (Good): 1,000 nm≤σ<2,000 nm

C (Poor): 2,000 nm≤σ

TABLE 7

| | A | B | |
|---|---|---|---|
| | (mPa · s) | (° C.) | Plane shape |
| Example 1 | 1.7 | 151 | A |
| Example 2 | 2.2 | 138 | A |
| Example 3 | 2.0 | 131 | B |
| Example 4 | 2.0 | 156 | A |
| Example 5 | 1.4 | 141 | A |
| Example 6 | 1.3 | 149 | A |
| Example 7 | 1.3 | 143 | A |
| Example 8 | 1.9 | 138 | A |
| Example 9 | 1.5 | 151 | A |
| Example 10 | 1.5 | 147 | A |
| Example 11 | 1.7 | 129 | B |
| Example 12 | 2.5 | 125 | B |
| Example 13 | 1.9 | 124 | B |
| Example 14 | 1.1 | 152 | A |
| Example 15 | 2.4 | 155 | A |
| Example 16 | 2.5 | 138 | A |
| Example 17 | 2.1 | 152 | A |
| Example 18 | 1.0 | 158 | A |

TABLE 8

| | A | B | |
|---|---|---|---|
| | (mPa · s) | (° C.) | Plane shape |
| Comparative Example 1 | 1.8 | 120 | C |
| Comparative Example 2 | 1.4 | 133 | C |
| Comparative Example 3 | 1.3 | 136 | C |
| Comparative Example 4 | 1.1 | 146 | C |
| Comparative Example 5 | 2.7 | 126 | C |
| Comparative Example 6 | 4.1 | 132 | C |
| Comparative Example 7 | 0.8 | 151 | C |
| Comparative Example 8 | 0.7 | 126 | C |
| Comparative Example 9 | 1.0 | 166 | C |
| Comparative Example 10 | 2.7 | 155 | C |
| Comparative Example 11 | 1.7 | 204 | C |
| Comparative Example 12 | 1.1 | 144 | C |
| Comparative Example 13 | 1.2 | 171 | C |
| Comparative Example 14 | 1.7 | 161 | C |
| Comparative Example 15 | 2.8 | 136 | C |
| Comparative Example 16 | 2.6 | 155 | C |
| Comparative Example 17 | 2.0 | 161 | C |

TABLE 9

| | A | B | |
|---|---|---|---|
| | (mPa · s) | (° C.) | Plane shape |
| Example 19 | 1.7 | 151 | A |
| Comparative Example 18 | 1.8 | 120 | C |

TABLE 10

| | A | B | |
|---|---|---|---|
| | (mPa · s) | (° C.) | Plane shape |
| Example 20 | 1.7 | 151 | A |
| Comparative Example 19 | 1.8 | 120 | C |

<Preparation of Actinic Ray-Sensitive or Radiation-Sensitive Composition>

The components shown in Solid content 1 in Table 1 were dissolved in the solvent (166 parts by mass) shown in Table 11 below to prepare a resist solution for each component, which was filtered at a filtration pressure of 0.1 MPa through an ultra-high-molecular-weight polyethylene (UPE) filter having a pore size of 1.0 μm. Thus, an actinic ray-sensitive or radiation-sensitive composition (resist composition) having a concentration of the solid content of 38% by mass was prepared.

TABLE 11

| | | Solvent (S-1) | | | | Solvent (S-2) | | | |
|---|---|---|---|---|---|---|---|---|---|
| | Type of | | | | Boiling | | | | Boiling |
| | solid | | Mass | Viscosity | point | | Mass | Viscosity | point |
| | content | Type | proportion | (mPa · s) | (° C.) | Type | proportion | (mPa · s) | (° C.) |
| Example 21 | 1 | PGMEA | 0.5 | 1.1 | 146 | EL | 0.5 | 2.7 | 155 |
| Comparative | 1 | PGME | 1 | 1.8 | 120 | — | — | — | — |
| Example 20 | | | | | | | | | |

<Method for Preparing Resist Film>

An actinic ray-sensitive or radiation-sensitive film (resist film) was formed in the same manner as in Example 1, except that the film thickness was changed to 12 μm.

<Evaluation>

(Method for Evaluating Plane Shape) Evaluation was carried out in the same manner as in Example 1.

TABLE 12

| | A | B | |
|---|---|---|---|
| | (mPa · s) | (° C.) | Plane shape |
| Example 21 | 1.7 | 151 | A |
| Comparative Example 20 | 1.8 | 120 | C |

<Preparation of Actinic Ray-Sensitive or Radiation-Sensitive Composition>

The components shown in Solid content 1 in Table 1 were dissolved in the solvent (134 parts by mass) shown in Table 13 below to prepare a resist solution for each component, which was filtered at a filtration pressure of 0.1 MPa through an ultra-high-molecular-weight polyethylene (UPE) filter having a pore size of 1.0 μm. Thus, an actinic ray-sensitive or radiation-sensitive composition (resist composition) having a concentration of the solid content of 43% by mass was prepared.

TABLE 13

| | Solvent (S-1) | | | | | Solvent (S-2) | | | |
|---|---|---|---|---|---|---|---|---|---|
| | | | | | Boiling | | | | Boiling |
| | Type of solid | | Mass | Viscosity | point | | Mass | Viscosity | point |
| | content | Type | proportion | (mPa · s) | (° C.) | Type | proportion | (mPa · s) | (° C.) |
| Example 22 | 1 | PGMEA | 0.5 | 1.1 | 146 | EL | 0.5 | 2.7 | 155 |
| Comparative | 1 | PGME | 1 | 1.8 | 120 | — | — | — | — |
| Example 21 | | | | | | | | | |

<Method for Preparing Resist Film>

An actinic ray-sensitive or radiation-sensitive film (resist film) was formed in the same manner as in Example 1, except that the film thickness was changed to 15 μm.

<Evaluation>

(Method for Evaluating Plane Shape)

Evaluation was carried out in the same manner as in Example 1.

TABLE 14

| | A | B | |
|---|---|---|---|
| | (mPa · s) | (° C.) | Plane shape |
| Example 22 | 1.7 | 151 | A |
| Comparative Example 21 | 1.8 | 120 | C |

From the results above, it was found that in Examples using an actinic ray-sensitive or radiation-sensitive composition including a solvent (S) satisfying the conditions (a) to (c), the plane shape was excellent, as compared with Comparative Examples.

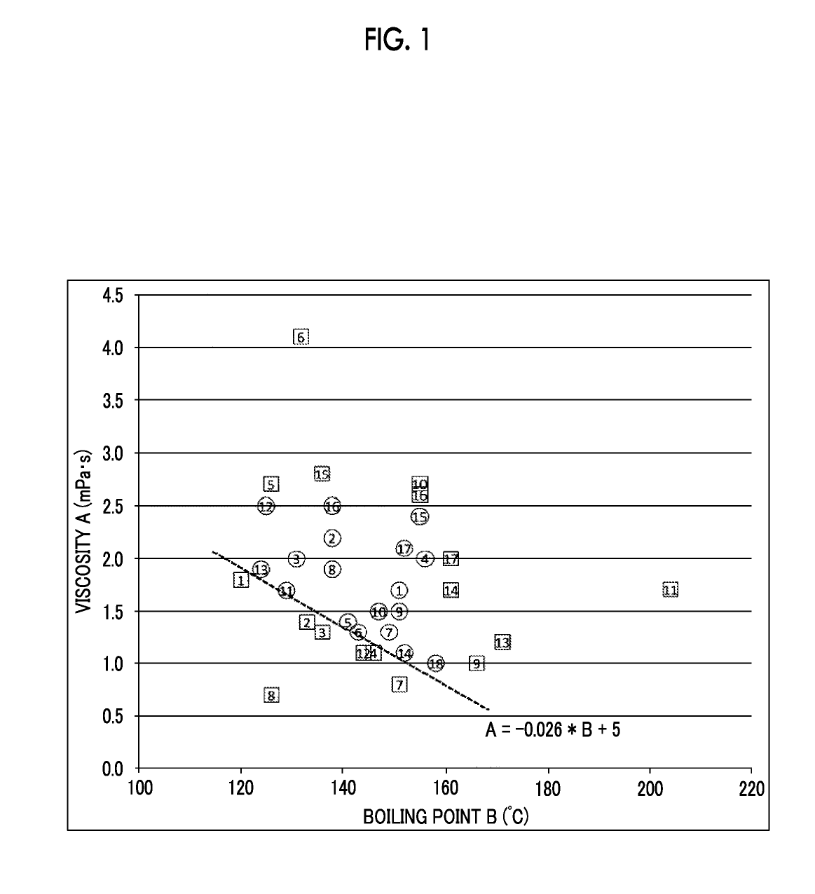

The relationship between the viscosity A (mPa·s) and the boiling point B (° C.) in Examples and Comparative Examples is shown in FIG. 1. In FIG. 1, the boiling point B (° C.) of a solvent is represented on the horizontal axis, and the viscosity A (mPa·s) of the solvent is represented on the vertical axis, obtained by plotting those from Examples 1 to 18 (denoted by o; the numerical values in the symbols represent Example Nos.) and Comparative Examples 1 to 17 (denoted by □; the numerical values in the symbols represent Comparative Example Nos.). From FIG. 1, it was found that an actinic ray-sensitive or radiation-sensitive film having an excellent plane shape is formed in a case where an actinic ray-sensitive or radiation-sensitive composition including a solvent (S) satisfying the conditions (a) to (c) is used.

(Exposing and Developing Methods)

A wafer having a resist film formed thereon was subjected to pattern exposure through an exposure mask, using a KrF excimer laser scanner (manufactured by ASML, PAS5500/850C, wavelength of 248 nm, NA0.80). Thereafter, the wafer was baked (post-exposure baked; PEB) at 130° C. for 60 seconds, then developed with an aqueous 2.38%-by-mass tetramethylammonium hydroxide solution (TMAHaq) for 60 seconds, rinsed with pure water for 15 seconds, and spin-dried. Thus, an isolated space pattern with a space of 3 um and a pitch of 33 μm was obtained.

The patterns of Examples, which were formed using an actinic ray-sensitive or radiation-sensitive composition including a solvent (S) satisfying the conditions (a) to (c), had an excellent plane shape, as compared with the patterns of Comparative Examples.

What is claimed is:

1. A pattern forming method comprising the following steps i), ii), and iii):
i) forming an actinic ray-sensitive or radiation-sensitive film having a film thickness of more than 9 um and 20 um or less, using an actinic ray-sensitive or radiation-sensitive composition including a solvent (S) satisfying the following conditions (a) to (c):
(a) A>-0.026*B+5
(b) 0.9<A<2.5
(c) 120<B<160,
where A represents a viscosity of the solvent (S), the unit of the viscosity is mPa·s, B represents a boiling point of the solvent (S), and the unit of the boiling point is ° C.,
in which in a case where the solvent (S) is formed of only one kind of solvent, A represents a viscosity of the solvent (S), the unit of the viscosity is mPa·s, B represents a boiling point of the solvent (S), and the unit of the boiling point is ° C.,
in a case where the solvent (S) is a mixed solvent formed of two kinds of solvents, A is calculated by Formula (al) and B is calculated by Formula (1)1):
A=μ1̂X1*μ2̂X2 (a1)
B=T1*X1+T2*X2 (b1),
where μ1 represents a viscosity of a first kind of the solvent, the unit of the viscosity is mPa·s, T1 represents a boiling point of the first kind of the solvent, the unit of the boiling point is ° C., and X1 represents a mass proportion of the first kind of the solvent with respect to the total mass of the mixed solvent, and
μ2 represents a viscosity of a second kind of the solvent, the unit of the viscosity is mPa·s, T2 represents a boiling point of the second kind of the solvent, the unit of the boiling point is ° C., and X2 represents a mass proportion of the second kind of the solvent with respect to the total mass of the mixed solvent, and
in a case where the solvent (S) is a mixed solvent formed of n kinds of solvents, A is calculated by Formula (a2) and B is calculated by Formula (b2):
A=μ1̂X1*μ2̂X2* . . . μn̂Xn (a2)
B=T1*X1+T2*X2+ . . . Tn*Xn (b2),
where μ1 represents a viscosity of a first kind of the solvent, the unit of the viscosity is mPa·s, T1 represents a boiling point of the first kind of the solvent, the unit of the boiling point is ° C., and X1 represents a mass proportion of the first kind of the solvent with respect to the total mass of the mixed solvent,
μ2 represents a viscosity of a second kind of the solvent, the unit of the viscosity is mPa·s, T2 represents a boiling point of the second kind of the solvent, the unit of the boiling point is ° C., and X2 represents a mass proportion of the second kind of the solvent with respect to the total mass of the mixed solvent,
μn represents a viscosity of an n^{th} kind of the solvent, the unit of the viscosity is mPa·s, Tn represents a boiling point of the n^{th} kind of the solvent, the unit of the boiling point is ° C., and Xn represents a mass proportion of the n^{th} kind of the solvent with respect to the total mass of the mixed solvent, and
n represents an integer of 3 or more;
ii) irradiating the actinic ray-sensitive or radiation-sensitive film with actinic rays or radiation; and
iii) developing the actinic ray-sensitive or radiation-sensitive film irradiated with actinic rays or radiation, using a developer.

2. The pattern forming method according to claim 1,
wherein B satisfies:
(c′) 136<B<160.

3. The pattern forming method according to claim 1,
wherein in the step ii), the wavelength of the actinic rays or radiation to be irradiated is 248 nm.

4. The pattern forming method according to claim 1,
wherein the solvent (S) includes at least one of an ether-based solvent, an ester-based solvent, or a ketone-based solvent.

5. The pattern forming method according to claim 1,
wherein the solvent (S) includes at least one of propylene glycol monomethyl ether acetate, propylene glycol monomethyl ether, ethyl lactate, ethyl ethoxypropionate, cyclohexanone, or methyl methoxypropionate.

6. The pattern forming method according to claim 1,
wherein the actinic ray-sensitive or radiation-sensitive composition further includes a resin having a repeating unit represented by General Formula (AI), 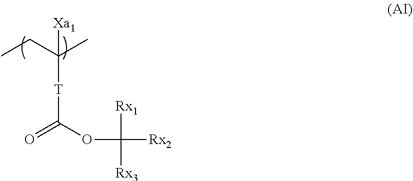
in the formula, Xa₁ represents a hydrogen atom or an alkyl group,
T represents a single bond or a divalent linking group,
Rx₁ to Rx₃ each independently represent an alkyl group or a cycloalkyl group, and
two of Rx₁ to Rx₃ may be bonded to each other to form a cycloalkyl group.

7. The pattern forming method according to claim 3,
wherein the solvent (S) includes at least one of an ether-based solvent, an ester-based solvent, or a ketone-based solvent.

8. The pattern forming method according to claim 3,
wherein the solvent (S) includes at least one of propylene glycol monomethyl ether acetate, propylene glycol monomethyl ether, ethyl lactate, ethyl ethoxypropionate, cyclohexanone, or methyl methoxypropionate.

9. The pattern forming method according to claim 3,
wherein the actinic ray-sensitive or radiation-sensitive composition further includes a resin having a repeating unit represented by General Formula (AI), 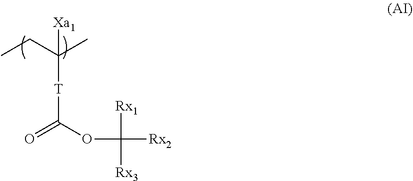
in the formula, Xa₁ represents a hydrogen atom or an alkyl group,
T represents a single bond or a divalent linking group,
Rx₁ to Rx₃ each independently represent an alkyl group or a cycloalkyl group, and
two of Rx₁ to Rx₃ may be bonded to each other to form a cycloalkyl group.

10. A method for manufacturing an electronic device, comprising the pattern forming method according to claim 1.

11. An actinic ray-sensitive or radiation-sensitive composition for forming an actinic ray-sensitive or radiation-sensitive film having a film thickness of more than 9 μm and 20 μm or less, the actinic ray-sensitive or radiation-sensitive composition comprising a solvent (S) satisfying the following conditions (a) to (c):
(a) A>-0.026*B+5
(b) 0.9<A<2.5
(c) 120<B<160,
where A represents a viscosity of the solvent (S), the unit of the viscosity is mPa·s, B represents a boiling point of the solvent (S), and the unit of the boiling point is ° C.,
wherein in a case where the solvent (S) is formed of only one kind of solvent, A represents a viscosity of the solvent (S), the unit of the viscosity is mPa·s, B represents a boiling point of the solvent (S), and the unit of the boiling point is ° C.,
in a case where the solvent (S) is a mixed solvent formed of two kinds of solvents, A is calculated by Formula (al) and B is calculated by Formula (1)1):
A=μ1̂X1*μ2̂X2 (a1)
B=T1*X1+T2*X2 (b1),
where μ1 represents a viscosity of a first kind of the solvent, the unit of the viscosity is mPa·s, T1 represents a boiling point of the first kind of the solvent, the unit of the boiling point is ° C., and X1 represents a mass proportion of the first kind of the solvent with respect to the total mass of the mixed solvent, and
μ2 represents a viscosity of a second kind of the solvent, the unit of the viscosity is mPa·s, T2 represents a boiling point of the second kind of the solvent, the unit of the boiling point is ° C., and X2 represents a mass proportion of the second kind of the solvent with respect to the total mass of the mixed solvent, and
in a case where the solvent (S) is a mixed solvent formed of n kinds of solvents, A is calculated by Formula (a2) and B is calculated by Formula (b2):
A=μ1̂X1*μ2̂X2* . . . μn̂Xn (a2)
B=T1*X1+T2*X2+ . . . Tn*Xn (b2),
where μ1 represents a viscosity of a first kind of the solvent, the unit of the viscosity is mPa·s, T1 represents a boiling point of the first kind of the solvent, the unit of the boiling point is ° C., and X1 represents a mass proportion of the first kind of the solvent with respect to the total mass of the mixed solvent,
μ2 represents a viscosity of a second kind of the solvent, the unit of the viscosity is mPa·s, T2 represents a boiling point of the second kind of the solvent, the unit of the boiling point is ° C., and X2 represents a mass proportion of the second kind of the solvent with respect to the total mass of the mixed solvent,
μn represents a viscosity of an n^{th} kind of the solvent, the unit of the viscosity is mPa·s, Tn represents a boiling point of the n^{th} kind of the solvent, the unit of the boiling point is ° C., and Xn represents a mass proportion of the n^{th} kind of the solvent with respect to the total mass of the mixed solvent, and
n represents an integer of 3 or more.
